(19) United States
(12) Patent Application Publication
(10) Pub. No.: US 2022/0190303 A1
(43) Pub. Date: Jun. 16, 2022

(54) ORGANIC ELECTROLUMINESCENT DISPLAY DEVICE

(71) Applicant: FUJIFILM Corporation, Tokyo (JP)

(72) Inventors: Naoya SHIBATA, Kanagawa (JP); Yoshinori MAEDA, Kanagawa (JP); Yoshihiko MOCHIZUKI, Kanagawa (JP)

(73) Assignee: FUJIFILM Corporation, Tokyo (JP)

(21) Appl. No.: 17/668,792

(22) Filed: Feb. 10, 2022

Related U.S. Application Data
(63) Continuation of application No. PCT/JP2020/031603, filed on Aug. 21, 2020.

(30) Foreign Application Priority Data
Aug. 28, 2019 (JP) 2019-155816

(51) Int. Cl. H01L 51/52; G02B 5/30; C09K 19/04

(52) U.S. Cl. CPC H01L 51/5293; G02B 5/305; C09K 2019/0448; C09K 19/04; G02B 5/3016

(57) ABSTRACT

Provided is an organic electroluminescent display device having excellent thermal durability including, in order from a visual recognition side, at least a circularly polarizing plate, and an organic electroluminescent display element having a pair of electrodes and an organic light emitting layer sandwiched therebetween, in which the circularly polarizing plate has a polarizer and an optically anisotropic layer, the polarizer having a thickness of 10 μm or less and containing a polyvinyl alcohol-based resin, or having a dichroic organic coloring agent, the optically anisotropic layer being formed of a composition containing a polymerizable liquid crystal compound exhibiting reverse wavelength dispersibility, a silicon nitride layer being included between the circularly polarizing plate and the organic electroluminescent display element, and the circularly polarizing plate being disposed between two substrates having a moisture permeability of 1 g/m2·day or less, and one of the low moisture permeability substrates is the silicon nitride layer.

### CROSS-REFERENCE TO RELATED APPLICATIONS

This application is a Continuation of PCT International Application No. PCT/JP2020/031603 filed on Aug. 21, 2020, which claims priority under 35 U.S.C. § 119(a) to Japanese Patent Application No. 2019-155816 filed on Aug. 28, 2019. The above application is hereby expressly incorporated by reference, in its entirety, into the present application.

### BACKGROUND OF THE INVENTION

### 1. Field of the Invention

The present invention relates to an organic electroluminescent (hereinafter, also simply referred to as “EL”) display device.

### 2. Description of the Related Art

Conventionally, a polarizing plate having an optically anisotropic layer and a polarizer has been used in an organic electroluminescent display device for the purpose of antireflection or the like.

In recent years, the development of a polarizing plate (so-called broadband polarizing plate) capable of giving the same effect for rays of all wavelengths with respect to white light, which is a combined wave in which rays in a visible light range are mixed, has been promoted. In particular, due to the demand for thinning of the apparatus to which the polarizing plate is applied, the optically anisotropic layer contained in the polarizing plate is also required to be thinned.

In response to such demands, for example, WO2014/010325A and JP2011-207765A propose the use of a polymerizable liquid crystal compound having reverse wavelength dispersibility as a polymerizable compound used for forming an optically anisotropic layer.

### SUMMARY OF THE INVENTION

In an organic electroluminescent display device, an organic light emitting element is vulnerable to oxygen and moisture, and a silicon nitride layer is often installed to block oxygen and moisture.

Therefore, the present inventors have clarified that unevenness occurs in an in-plane central portion of an optically anisotropic layer constituting a laminate in a case where a polarizing plate having an optically anisotropic layer formed of the polymerizable liquid crystal (polymerizable compound) having reverse wavelength dispersibility described in WO2014/010325A and JP2011-207765A is prepared, the polarizing plate is disposed on a silicon nitride layer, the polarizing plate is further sandwiched between substrates having low moisture permeability (for example, a glass substrate), and then the obtained laminate is exposed to high temperature conditions for a long period of time. In addition, the present inventors have clarified that an in-plane retardation (Re) fluctuates significantly in the region where unevenness occurs, causing a change in tint. That is, the present inventors have found that even in a case where a circularly polarizing plate is sandwiched between substrates having low moisture permeability, the in-plane retardation fluctuates significantly in a case of being exposed to a high temperature.

Hereinafter, suppressing changes in the in-plane retardation in a case where the laminate is exposed to a high temperature is expressed as having excellent thermal durability.

An object of the present invention is to provide an organic electroluminescent display device having excellent thermal durability.

The present inventors have found that the foregoing object can be achieved by the following configuration.

[1] An organic electroluminescent display device including, in order from a visual recognition side, at least a circularly polarizing plate, and an organic electroluminescent display element having a pair of electrodes and an organic light emitting layer sandwiched therebetween, in which the circularly polarizing plate has a polarizer and an optically anisotropic layer, the polarizer is a polarizer having a thickness of 10 μm or less and containing a polyvinyl alcohol-based resin, or a polarizer having a dichroic organic coloring agent, the optically anisotropic layer is a layer formed of a composition containing a polymerizable liquid crystal compound exhibiting reverse wavelength dispersibility, a silicon nitride layer is included between the circularly polarizing plate and the organic electroluminescent display element, and the circularly polarizing plate is disposed between two low moisture permeability substrates, the low moisture permeability substrates have a moisture permeability of 1 g/m²·day or less, and one of the low moisture permeability substrates is the silicon nitride layer.

[2] The organic electroluminescent display device according to [1], in which the polarizer is a polarizer having a thickness of 5 μm or less and containing a polyvinyl alcohol-based resin.

[3] The organic electroluminescent display device according to [1] or [2], in which a moisture permeability of a layer existing between the circularly polarizing plate and the silicon nitride layer is 100 g/m²·day or more.

[4] The organic electroluminescent display device according to any one of [1] to [3], in which a thickness of the layer existing between the circularly polarizing plate and the silicon nitride layer is less than 40 μm.

[5] The organic electroluminescent display device according to any one of [1] to [4], in which the polymerizable liquid crystal compound contains a polymerizable liquid crystal compound having a partial structure represented by Formula (II) which will be described later.

[6] The organic electroluminescent display device according to any one of [1] to [5], in which Re(450), which is an in-plane retardation value of the optically anisotropic layer measured at a wavelength of 450 nm, Re(550), which is an in-plane retardation value of the optically anisotropic layer measured at a wavelength of 550 nm, and Re(650), which is an in-plane retardation value of the optically anisotropic layer measured at a wavelength of 650 nm, satisfy a relationship of Re(450)≤Re(550)≤Re(650).

[7] The organic electroluminescent display device according to any one of [1] to [6], in which the optically anisotropic layer is a positive A plate.

[8] The organic electroluminescent display device according to any one of [1] to [7], in which the optically anisotropic layer is a λ/4 plate.

[9] The organic electroluminescent display device according to any one of [1] to [8], in which an angle formed by a slow axis of the optically anisotropic layer and an absorption axis of the polarizer is 45°±10°.

[10] The organic electroluminescent display device according to any one of [1] to [9], in which the polarizer is formed of a composition containing a dichroic organic coloring agent and a polymerizable liquid crystal compound, and the polymerizable liquid crystal compound is in amount of 50% by mass or more of a solid content mass of the composition.

[11] The organic electroluminescent display device according to any one of [1] to [10], in which a luminosity corrected single body transmittance of the polarizer is 47% or more.

[12] The organic electroluminescent display device according to any one of [1] to [11], in which a polarizer protective film is provided between the polarizer and the optically anisotropic layer, and an equilibrium moisture content of the polarizer protective film at 25° C. and 80% RH is 2% or less.

[13] The organic electroluminescent display device according to [12], in which the polarizer protective film contains a norbornene-based resin.

[14] The organic electroluminescent display device according to any one of [1] to [13], in which the other one of the low moisture permeability substrates is a glass substrate.

[15] The organic electroluminescent display device according to any one of [1] to [13], in which the other one of the low moisture permeability substrates is a glass substrate having a thickness of 100 μm or less.

[16] The organic electroluminescent display device according to any one of [1] to [13], in which the other one of the low moisture permeability substrates is a metal oxide film having a thickness of 1 μm or less.

According to an aspect of the present invention, it is possible to provide an organic electroluminescent display device having excellent thermal durability.

### BRIEF DESCRIPTION OF THE DRAWINGS

FIG. 1 is a schematic cross-sectional view showing an example of an embodiment of an organic electroluminescent display device of the present invention.

FIG. 2 is a schematic cross-sectional view showing an example of an embodiment of an organic electroluminescent display device of the present invention.

FIG. 3 is a schematic cross-sectional view showing an example of an embodiment of an organic electroluminescent display device of the present invention.

### DESCRIPTION OF THE PREFERRED EMBODIMENTS

Hereinafter, the present invention will be described in more detail.

The description of configuration requirements described below may be made based on representative embodiments of the present invention, but the present invention is not limited to such embodiments.

In the present specification, any numerical range expressed by using “to” means a range including the numerical values before and after the “to” as a lower limit value and an upper limit value, respectively.

In addition, in the present specification, with regard to each component, a substance corresponding to each component may be used alone or in combination of two or more thereof. Here, in a case where two or more substances are used in combination for each component, the content of the component refers to a total content of the substances used in combination unless otherwise specified.

In addition, in the present specification, a bonding direction of a divalent group (for example, —O—CO—) described is not particularly limited unless a bonding position is specified. For example, in a case where D¹ in Formula (III) which will be described later is —CO—O—, D¹ may be *1-CO—O—*2 or may be *1-O—CO—*2 assuming that the position bonded to the G¹ side is defined as *1 and the position bonded to the Ar side is defined as *2.

In addition, in the present specification, “(meth)acrylate” is a general term for “acrylate” and “methacrylate”, “(meth)acrylic” is a general term for “acrylic” and “methacrylic”, and “(meth)acryloyl” is a general term for “acryloyl” and “methacryloyl”.

In addition, in the present specification, “orthogonal” and “parallel” with respect to an angle shall mean a range of an exact angle ±10°, and “same” and “different” with respect to an angle can be determined based on whether or not the difference is less than 5°.

In addition, in the present specification, “visible light” refers to light having a wavelength of 380 to 780 nm.

In addition, in the present specification, the measurement wavelength is 550 nm unless otherwise specified.

In the present specification, the term “moisture content” means an initial mass of a cut-out sample and a mass obtained by converting the amount of change in dry mass after drying at 120° C. for 2 hours into a value per unit area.

In the present specification, the term “slow axis” means the direction in which an in-plane refractive index is maximized. The slow axis of an optically anisotropic layer is intended to mean a slow axis of the entire optically anisotropic layer.

In the present specification, “Re(λ)” and “Rth(λ)” represent an in-plane retardation at wavelength λ and a thickness direction retardation at wavelength λ, respectively.

Here, the values of in-plane retardation and thickness direction retardation refer to values measured using light of a measurement wavelength and using AxoScan OPMF-1 (manufactured by Opto Science, Inc.).

Specifically, by inputting an average refractive index ((nx+ny+nz)/3) and a film thickness (d (μm)) in AxoScan OPMF-1,

slow axis direction (°)

Re(λ)=R0(λ)

Rth(λ)=((nx+ny)/2−nz)×d

are calculated.

Although R0(λ) is displayed as a numerical value calculated by AxoScan OPMF-1, it means Re(λ).

The organic EL display device according to the embodiment of the present invention is an organic electroluminescent display device including, in order from a visual recognition side, at least a circularly polarizing plate, and an organic EL display element having a pair of electrodes and an organic light emitting layer sandwiched therebetween.

In addition, in the organic EL display device according to the embodiment of the present invention, the circularly polarizing plate has a polarizer and an optically anisotropic layer, the polarizer is a polarizer having a thickness of 10 μm or less and containing a polyvinyl alcohol-based resin, or a polarizer having a dichroic organic coloring agent, and the optically anisotropic layer is a layer formed of a composition containing a polymerizable liquid crystal compound exhibiting reverse wavelength dispersibility (hereinafter, also simply referred to as “specific liquid crystal compound”).

In addition, the organic EL display device according to the embodiment of the present invention includes a silicon nitride layer (hereinafter, also simply referred to as “SiN layer”) between the circularly polarizing plate and the organic electroluminescent display element.

In addition, in the organic EL display device according to the embodiment of the present invention, the circularly polarizing plate is disposed between two low moisture permeability substrates, the low moisture permeability substrates have a moisture permeability of 1 g/m² day or less, and one of the low moisture permeability substrates is an SiN layer.

That is, the layer configuration of the organic EL display device according to the embodiment of the present invention includes a low moisture permeability substrate, a circularly polarizing plate, an SiN layer, and an organic EL display element in this order from a visual recognition side.

The organic electroluminescent display device according to the embodiment of the present invention having a predetermined optically anisotropic layer, a predetermined polarizer, and a predetermined low moisture permeability substrate has excellent thermal durability.

Although the reason for such an effect is not clear in detail, the present inventors speculate as follows.

It is known that the SiN layer, which is usually used as a barrier layer of an organic light emitting element in an organic electroluminescent display device, reacts with water to generate ammonia depending on the preparation method.

In addition, it has been clarified by the studies of the present inventors that the polymerizable liquid crystal compound exhibiting reverse wavelength dispersibility is susceptible to decomposition by nucleophiles such as ammonia.

Specifically, the present inventors have found that, in a case where an optically anisotropic layer prepared using the specific liquid crystal compound is exposed to ammonia gas, decomposition of the structure derived from the specific liquid crystal compound contained in the optically anisotropic layer occurs rapidly, the fluctuation of the in-plane retardation value becomes large, and the reverse wavelength dispersibility decreases. The reason for this is presumed to be the following phenomenon.

One method for making the specific liquid crystal compound to exhibit reverse wavelength dispersibility is to give it an electron-attracting property. On the other hand, it is presumed that such a molecular design increases the positive polarization of the carbon atoms that make up the specific liquid crystal compound, making it more susceptible to attack by nucleophiles (ammonia).

On the other hand, as described above, the present inventors have found that even in a case where a polarizing plate is sandwiched between low moisture permeability substrates, the in-plane retardation fluctuates significantly in a case of being exposed to a high temperature.

Then, focusing on the fact that a polyvinyl alcohol-based resin having a high moisture content is used for a general polarizer, the present inventors presume that the polarizer is a supply source of moisture in an organic EL display device.

Therefore, in the present invention, it is considered that moisture in the system can be reduced by limiting the film thickness of the polarizer containing a polyvinyl alcohol-based resin or by adopting the polarizer having a dichroic organic coloring agent, and as a result, the generation of ammonia is suppressed and therefore the decomposition reaction of the structure derived from the specific liquid crystal compound is suppressed, whereby an improvement effect is obtained.

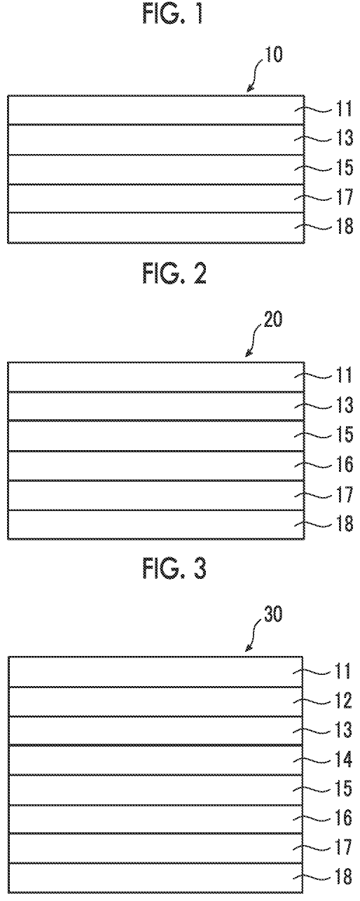

FIG. 1, FIG. 2, and FIG. 3 show a schematic cross-sectional view showing an example of the organic EL display device according to the embodiment of the present invention.

Here, an organic EL display device 10 shown in FIG. 1 is an organic EL display device having a layer configuration having a low moisture permeability substrate 1 (cover glass) 11, a polarizer 13, a positive A plate 15, a low moisture permeability substrate 2 (silicon nitride layer) 17, and an organic EL display element 18 in this order.

In addition, an organic EL display device 20 shown in FIG. 2 is an organic EL display device having a layer configuration having a low moisture permeability substrate 1 (cover glass) 11, a polarizer 13, a positive A plate 15, a positive C plate 16, a low moisture permeability substrate 2 (silicon nitride layer) 17, and an organic EL display element 18 in this order.

In addition, an organic EL display device 30 shown in FIG. 3 is an organic EL display device having a layer configuration having a low moisture permeability substrate 1 (cover glass) 11, a polarizer protective film 12, a polarizer 13, a polarizer protective film 14, a positive A plate 15, a positive C plate 16, a low moisture permeability substrate 2 (silicon nitride layer) 17, and an organic EL display element 18 in this order.

In FIGS. 1 to 3, the positive A plate 15 corresponds to the optically anisotropic layer included in the organic EL display device according to the embodiment of the present invention.

In the present invention, at least a polarizer, an optically anisotropic layer, and a silicon nitride layer are included.

Hereinafter, individual layers and components of the organic EL display device according to the embodiment of the present invention will be described in detail.

<Optically Anisotropic Layer>

The optically anisotropic layer is a layer formed of a composition containing a specific liquid crystal compound (hereinafter, also simply referred to as “polymerizable liquid crystal composition”).

The specific liquid crystal compound is a polymerizable liquid crystal compound, and is a compound exhibiting “reverse wavelength dispersibility”.

Here, the compound exhibiting “reverse wavelength dispersibility” in the present specification refers to a compound in which an in-plane retardation (Re) value corresponds to or becomes higher than an increase in a measurement wavelength in a case where the Re value at a specific wavelength (visible light range) of an optically anisotropic layer prepared using such a compound is measured, and refers to a compound which satisfies a relationship of Re(450)≤Re(550)≤Re(650) which will be described later.

The polymerizable liquid crystal compound exhibiting reverse wavelength dispersibility is not particularly limited as long as it can form a film exhibiting reverse wavelength dispersibility as described above, and examples thereof include the compounds represented by General Formula (I) described in JP2008-297210A (particularly, the compounds described in paragraphs [0034] to [0039]), the compounds represented by General Formula (1) described in JP2010-084032A (particularly, the compounds described in paragraphs [0067] to [0073]), the compounds represented by General Formula (1) described in JP2019-73496A (particularly, the compounds described in paragraphs [0117] to [0124]), and the compounds represented by General Formula (1) described in JP2016-081035A (particularly, the compounds described in paragraphs [0043] to [0055]).

The polymerizable liquid crystal compound is preferably a polymerizable liquid crystal compound having a partial structure represented by Formula (II), from the viewpoint that the effect of the present invention is more excellent.

*-D₁-Ar-D₂* (II)

In Formula (II), D¹ and D² each independently represent a single bond, —O—, —CO—, —CO—O—, —C(═S)O—, —CR¹R²—, —CR¹R²—CR³R⁴—, —O—CR¹R²—, —CR¹R²—O—CR³R⁴—, —CO—O—CR¹R²—, —O—CO—CR¹R²—, —CR¹R²—CR³R⁴—O—CO—, —CR¹R²—O—CO—CR³R⁴—, —CR¹R²—CO—O—CR³R⁴—, —NR¹—CR²R³—, or —CO—NR¹—.

R¹, R², R³, and R⁴ each independently represent a hydrogen atom, a fluorine atom, or an alkyl group having 1 to 4 carbon atoms. In a case where there are a plurality of each of R¹'s, R²'s, R³'s, and R⁴'s, the plurality of R¹'s, the plurality of R²'s, the plurality of R³'s, and the plurality of R⁴'s each may be the same as or different from each other.

Ar represents any aromatic ring selected from the group consisting of groups represented by Formulae (Ar-1) to (Ar-7). In Formulae (Ar-1) to (Ar-7), * represents a bonding position with D¹ or D², and the description of the reference numerals in Formulae (Ar-1) to (Ar-7) is the same as that described by Ar in Formulae (III) which will be described later.

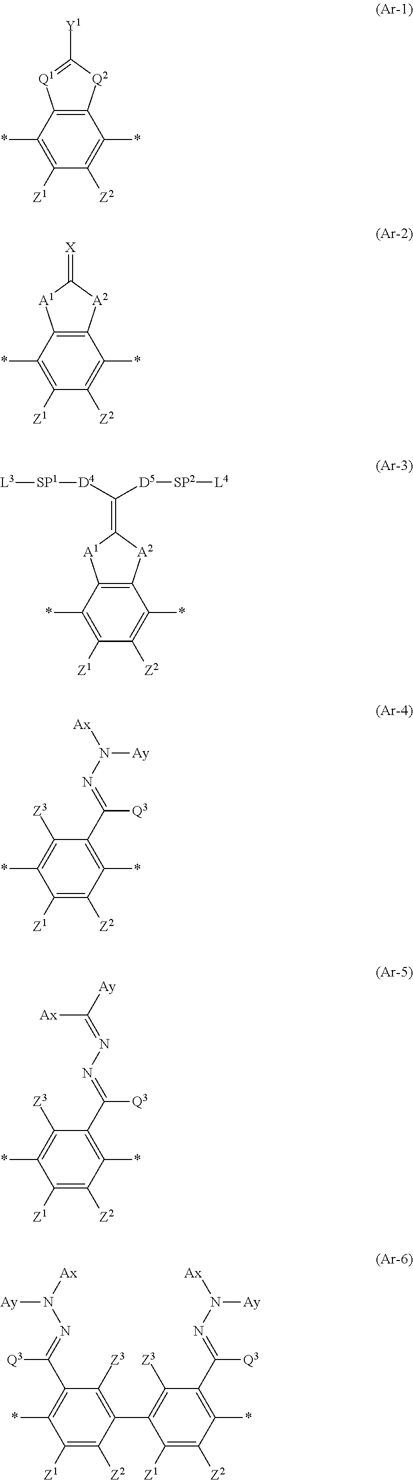

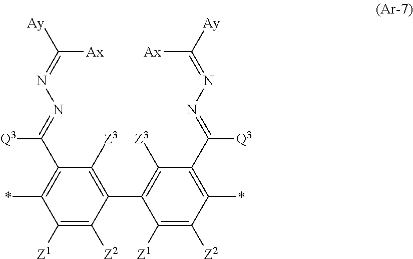

The polymerizable liquid crystal compound having the partial structure represented by Formula (II) is preferably a polymerizable liquid crystal compound represented by Formula (III).

The polymerizable liquid crystal compound represented by Formula (III) is a compound exhibiting liquid crystallinity.

L¹-G¹-D¹-Ar-D²-G²-L² (III)

In Formula (III), D¹ and D² each independently represent a single bond, —O—, —CO—, —CO—O—, —C(═S)O—, —CR¹R²—, —CR¹R²—CR³R⁴—, —O—CR¹R²—, —CR¹R²—O—CR³R⁴—, —CO—O—CR¹R²—, —O—CO—CR¹R²—, —CR¹R²—CR³R⁴—O—CO—, —CR¹R²—O—CO—CR³R⁴—, —CR¹R²—CO—O—CR³R⁴—, —NR¹—CR²R³—, or —CO—NR¹—.

R¹, R², R³, and R⁴ each independently represent a hydrogen atom, a fluorine atom, or an alkyl group having 1 to 4 carbon atoms. In a case where there are a plurality of each of R¹'s, R²'s, R³'s, and R⁴'s, the plurality of R¹'s, the plurality of R²'s, the plurality of R³'s, and the plurality of R⁴'s each may be the same as or different from each other.

G¹ and G² each independently represent a divalent alicyclic hydrocarbon group having 5 to 8 carbon atoms or an aromatic hydrocarbon group, and the methylene group contained in the alicyclic hydrocarbon group may be substituted with —O—, —S—, or —NH—.

L¹ and L² each independently represent a monovalent organic group, and at least one selected from the group consisting of L¹ and L² represents a monovalent group having a polymerizable group.

Ar represents any aromatic ring selected from the group consisting of groups represented by Formulae (Ar-1) to (Ar-7). In Formulae (Ar-1) to (Ar-7), * represents a bonding position with D¹ or D².

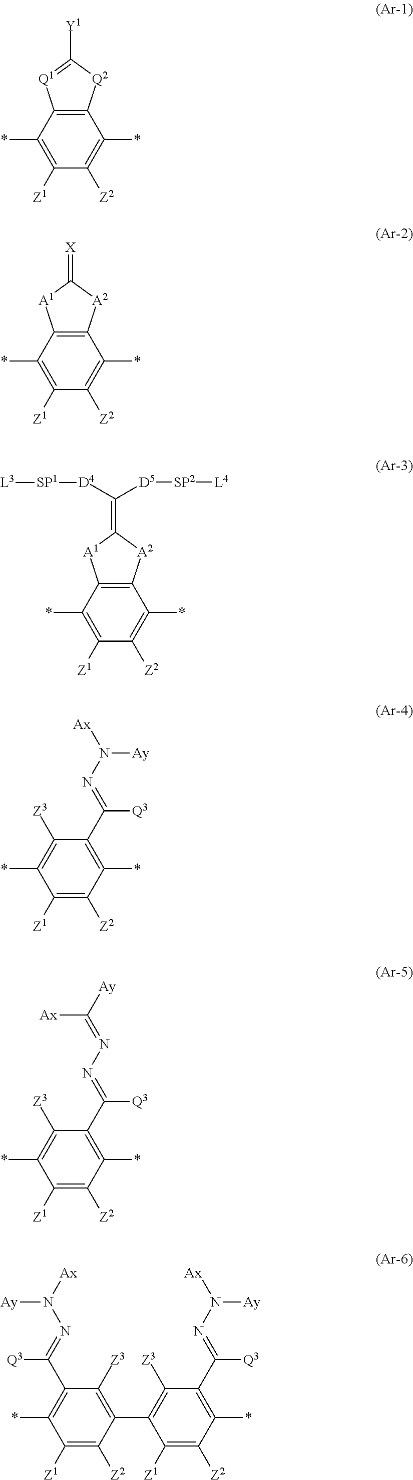

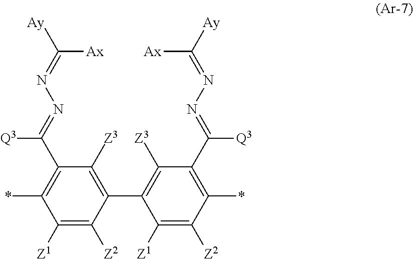

In Formula (Ar-1), Q¹ represents N or CH, Q² represents —S—, —O—, or —N(R′)—, R represents a hydrogen atom or an alkyl group having 1 to 6 carbon atoms, and Y¹ represents an aromatic hydrocarbon group having 6 to 12 carbon atoms or an aromatic heterocyclic group having 3 to 12 carbon atoms, each of which may have a substituent.

Examples of the alkyl group having 1 to 6 carbon atoms represented by R⁷ include a methyl group, an ethyl group, a propyl group, an isopropyl group, an n-butyl group, an isobutyl group, a sec-butyl group, a tert-butyl group, an n-pentyl group, and an n-hexyl group.

Examples of the aromatic hydrocarbon group having 6 to 12 carbon atoms represented by Y¹ include aryl groups of a phenyl group, a 2,6-diethylphenyl group, and a naphthyl group.

Examples of the aromatic heterocyclic group having 3 to 12 carbon atoms represented by Y¹ include heteroaryl groups of a thienyl group, a thiazolyl group, a furyl group, and a pyridyl group.

In addition, examples of the substituent that Y¹ may have include an alkyl group, an alkoxy group, and a halogen atom.

The alkyl group is preferably an alkyl group having 1 to 18 carbon atoms, more preferably an alkyl group having 1 to 8 carbon atoms (for example, a methyl group, an ethyl group, a propyl group, an isopropyl group, an n-butyl group, an isobutyl group, a sec-butyl group, a t-butyl group, or a cyclohexyl group), still more preferably an alkyl group having 1 to 4 carbon atoms, and particularly preferably a methyl group or an ethyl group. The alkyl group may be linear, branched, or cyclic.

The alkoxy group is, for example, preferably an alkoxy group having 1 to 18 carbon atoms, more preferably an alkoxy group having 1 to 8 carbon atoms (for example, a methoxy group, an ethoxy group, an n-butoxy group, or a methoxyethoxy group), still more preferably an alkoxy group having 1 to 4 carbon atoms, and particularly preferably a methoxy group or an ethoxy group.

Examples of the halogen atom include a fluorine atom, a chlorine atom, a bromine atom, and an iodine atom, among which a fluorine atom or a chlorine atom is preferable.

In addition, in Formulae (Ar-1) to (Ar-7), Z¹, Z², and Z³ each independently represent a hydrogen atom, a monovalent aliphatic hydrocarbon group having 1 to 20 carbon atoms, a monovalent alicyclic hydrocarbon group having 3 to 20 carbon atoms, a monovalent aromatic hydrocarbon group having 6 to 20 carbon atoms, a halogen atom, a cyano group, a nitro group, —OR⁸, —NR⁹R¹⁰, or —SR¹¹, R⁸ to R¹¹ each independently represent a hydrogen atom or an alkyl group having 1 to 6 carbon atoms, and Z¹ and Z² may be bonded to each other to form an aromatic ring.

The monovalent aliphatic hydrocarbon group having 1 to 20 carbon atoms is preferably an alkyl group having 1 to 15 carbon atoms, more preferably an alkyl group having 1 to 8 carbon atoms, still more preferably a methyl group, an ethyl group, an isopropyl group, a tert-pentyl group (1,1-dimethylpropyl group), a tert-butyl group, or a 1,1-dimethyl-3,3-dimethyl-butyl group, and particularly preferably a methyl group, an ethyl group, or a tert-butyl group.

Examples of the monovalent alicyclic hydrocarbon group having 3 to 20 carbon atoms include monocyclic saturated hydrocarbon groups such as a cyclopropyl group, a cyclobutyl group, a cyclopentyl group, a cyclohexyl group, a cycloheptyl group, a cyclooctyl group, a cyclodecyl group, a methylcyclohexyl group, and an ethylcyclohexyl group; monocyclic unsaturated hydrocarbon groups such as a cyclobutenyl group, a cyclopentenyl group, a cyclohexenyl group, a cycloheptenyl group, a cyclooctenyl group, a cyclodecenyl group, a cyclopentadienyl group, a cyclohexadienyl group, a cyclooctadienyl group, and cyclodecadiene; and polycyclic saturated hydrocarbon groups such as a bicyclo[2.2.1]heptyl group, a bicyclo[2.2.2]octyl group, a tricyclo[5.2.1.0^{2,6}]decyl group, a tricyclo[3.3.1.1^{3,7}]decyl group, a tetracyclo[6.2.1.1^{3,6}.0^{2,7}]dodecyl group, and an adamantyl group.

Examples of the monovalent aromatic hydrocarbon group having 6 to 20 carbon atoms include a phenyl group, a 2,6-diethylphenyl group, a naphthyl group, and a biphenyl group, among which an aryl group having 6 to 12 carbon atoms (particularly, a phenyl group) is preferable.

Examples of the halogen atom include a fluorine atom, a chlorine atom, a bromine atom, and an iodine atom, among which a fluorine atom, a chlorine atom, or a bromine atom is preferable.

Examples of the alkyl group having 1 to 6 carbon atoms represented by R⁸ to R¹¹ include a methyl group, an ethyl group, a propyl group, an isopropyl group, an n-butyl group, an isobutyl group, a sec-butyl group, a tert-butyl group, an n-pentyl group, and an n-hexyl group.

In addition, in Formulae (Ar-2) and (Ar-3), A¹ and A² each independently represent a group selected from the group consisting of —O—, —N(R¹²)—, —S—, and —CO—, and R¹² represents a hydrogen atom or a substituent.

Examples of the substituent represented by R¹² include the same substituents that Y¹ in Formula (Ar-1) may have.

In addition, in Formula (Ar-2), X represents a non-metal atom of Groups 14 to 16 to which a hydrogen atom or a substituent may be bonded.

In addition, examples of the non-metal atom of Groups 14 to 16 represented by X include an oxygen atom, a sulfur atom, a nitrogen atom to which a hydrogen atom or a substituent is bonded [═N—R^{N1} where R^{N1} represents a hydrogen atom or a substituent], and a carbon atom to which a hydrogen atom or a substituent is bonded [═C—(R^{C1})₂ where R^{C1} represents a hydrogen atom or a substituent].

Specific examples of the substituent include an alkyl group, an alkoxy group, an alkyl-substituted alkoxy group, a cyclic alkyl group, an aryl group (for example, a phenyl group or a naphthyl group), a cyano group, an amino group, a nitro group, an alkylcarbonyl group, a sulfo group, and a hydroxyl group.

In addition, in Formula (Ar-3), D⁴ and D⁵ each independently represent a single bond, or —CO—, —O—, —S—, —C(═S)—, —CR^{1a}R^{2a}—, —CR^{3a}═CR^{4a}—, —NR^{5a}— or a divalent linking group consisting of a combination of two or more thereof, and R^{1a} to R^{5a} each independently represent a hydrogen atom, a fluorine atom, or an alkyl group having 1 to 4 carbon atoms.

Here, examples of the divalent linking group include —CO—, —O—, —CO—O—, —C(═S)O—, —CR^{1b}R^{2b}—, —CR^{1b}R^{2b}—CR^{1b}R^{2b}—, —O—CR^{1b}R^{2b}—, —CR^{1b}R^{2b}—O—CR^{1b}R^{1b}—, —CO—O—CR^{1b}R^{2b}—, —O—CO—CR^{1b}R^{2b}—, —CR^{1b}R^{2b}—O—CO—CR^{1b}R^{2b}—, —CR^{1b}R^{2b}—CO—O—CR^{1b}R^{2b}—, —NR^{3b}—CR^{1b}R^{2b}—, and —CO—NR^{3b}. R^{1b}, R^{2b}, and R^{3b} each independently represent a hydrogen atom, a fluorine atom, or an alkyl group having 1 to 4 carbon atoms.

In addition, in Formula (Ar-3), SP¹ and SP² each independently represent a single bond, a linear or branched alkylene group having 1 to 12 carbon atoms, or a divalent linking group in which one or more of —CH₂— constituting a linear or branched alkylene group having 1 to 12 carbon atoms are substituted with —O—, —S—, —NH—, —N(Q)-, or —CO—, and Q represents a substituent. Examples of the substituent include the same substituents that Y¹ in Formula (Ar-1) may have.

Here, the linear or branched alkylene group having 1 to 12 carbon atoms is preferably, for example, a methylene group, an ethylene group, a propylene group, a butylene group, a pentylene group, a hexylene group, a methylhexylene group, or a heptylene group.

In addition, in Formula (Ar-3), L³ and L⁴ each independently represent a monovalent organic group.

Examples of the monovalent organic group include an alkyl group, an aryl group, and a heteroaryl group. The alkyl group may be linear, branched, or cyclic and is preferably linear. The number of carbon atoms in the alkyl group is preferably 1 to 30, more preferably 1 to 20, and still more preferably 1 to 10. In addition, the aryl group may be monocyclic or polycyclic and is preferably monocyclic. The number of carbon atoms in the aryl group is preferably 6 to 25 and more preferably 6 to 10. In addition, the heteroaryl group may be monocyclic or polycyclic. The number of heteroatoms constituting the heteroaryl group is preferably 1 to 3. The heteroatom constituting the heteroaryl group is preferably a nitrogen atom, a sulfur atom, or an oxygen atom. The number of carbon atoms in the heteroaryl group is preferably 6 to 18 and more preferably 6 to 12. In addition, the alkyl group, the aryl group, and the heteroaryl group may be unsubstituted or may have a substituent. Examples of the substituent include the same substituents that Y¹ in Formula (Ar-1) may have.

In addition, in Formulae (Ar-4) to (Ar-7), Ax represents an organic group having 2 to 30 carbon atoms which has at least one aromatic ring selected from the group consisting of an aromatic hydrocarbon ring and an aromatic heterocyclic ring.

In addition, in Formulae (Ar-4) to (Ar-7), Ay represents a hydrogen atom, an alkyl group having 1 to 12 carbon atoms which may have a substituent, or an organic group having 2 to 30 carbon atoms which has at least one aromatic ring selected from the group consisting of an aromatic hydrocarbon ring and an aromatic heterocyclic ring.

Here, the aromatic rings in Ax and Ay may have a substituent, and Ax and Ay may be bonded to each other to form a ring.

In addition, Q³ represents a hydrogen atom or an alkyl group having 1 to 6 carbon atoms which may have a substituent.

Examples of Ax and Ay include those described in paragraphs [0039] to [0095] of WO2014/010325A.

In addition, specific examples of the alkyl group having 1 to 6 carbon atoms represented by Q³ include a methyl group, an ethyl group, a propyl group, an isopropyl group, an n-butyl group, an isobutyl group, a sec-butyl group, a tert-butyl group, an n-pentyl group, and an n-hexyl group, and examples of the substituent include the same substituents that Y¹ in Formula (Ar-1) may have.

With regard to the definition and preferred range of each substituent of the liquid crystal compound represented by Formula (III), the descriptions regarding D¹, D², G¹, G², L¹, L², R⁴, R⁵, R⁶, R⁷, X¹, Y¹, Q¹, and Q² for Compound (A) described in JP2012-021068A can be referred to for D₁, D₂, G₁, G₂, L₁, L₂, R¹, R², R³, R⁴, Q₁, Y₁, Z₁, and Z₂, respectively; the descriptions regarding A₁, A₂, and X for the compound represented by General Formula (I) described in JP2008-107767A can be referred to for A₁, A₂, and X, respectively; and the descriptions regarding Ax, Ay, and Q¹ for the compound represented by General Formula (I) described in WO 2013/018526A can be referred to for Ax, Ay, and Q₂, respectively. The description of Q¹ for Compound (A) described in JP2012-21068A can be referred to for Z₃.

In particular, the organic groups represented by L¹ and L² are each preferably a group represented by -D³-G³-Sp-P³.

D³ has the same definition as in D¹.

G³ represents a single bond, a divalent aromatic ring group or heterocyclic group having 6 to 12 carbon atoms, or a divalent alicyclic hydrocarbon group having 5 to 8 carbon atoms, and the methylene group contained in the alicyclic hydrocarbon group may be substituted with —O—, —S—, or —NR⁷—, and R⁷ represents a hydrogen atom or an alkyl group having 1 to 6 carbon atoms.

Sp represents a spacer group represented by a single bond, —(CH₂)ₙ—, —(CH₂)ₙ—O—, —(CH₂—O—)ₙ—, —(CH₂CH₂—O—)ₘ, —O—(CH₂)ₙ—, —O—(CH₂)ₙ—O—, —O(CH₂—O—)ₙ—, —O—(CH₂CH₂—O—)ₘ, —C(═O)—O—(CH₂)ₙ—, —C(═O)—O—(CH₂)ₙ—O—, —C(═O)—O—(CH₂—O—)ₙ—, —C(═O)—O—(CH₂CH₂—O—)ₘ, —C(═O)—N(R⁸)—(CH₂)ₙ—, —C(—O)—N(R⁸)—(CH₂)ₙ—O—, —C(═O)—N(R⁸)—(CH₂—O—)ₙ—, —C(═O)—N(R⁸)—(CH₂CH₂—O—)ₘ, or —(CH₂)ₙ—O—(C═O)—(CH₂)ₙ—C(═O)—O—(CH₂)₆—. Here, n represents an integer of 2 to 12, m represents an integer of 2 to 6, and R⁸ represents a hydrogen atom or an alkyl group having 1 to 6 carbon atoms. In addition, the hydrogen atom of —CH₂— in each of the above groups may be substituted with a methyl group.

P³ represents a polymerizable group.

The polymerizable group is not particularly limited and is preferably a polymerizable group capable of radical polymerization or cationic polymerization.

Examples of the radically polymerizable group include known radically polymerizable groups, among which an acryloyl group or a methacryloyl group is preferable. The acryloyl group is generally known to have a high polymerization rate and therefore the acryloyl group is preferable from the viewpoint of improving productivity; whereas the methacryloyl group can also be used as the polymerizable group of a highly birefringent liquid crystal.

Examples of the cationically polymerizable group include known cationically polymerizable groups, examples of which include an alicyclic ether group, a cyclic acetal group, a cyclic lactone group, a cyclic thioether group, a spiroorthoester group, and a vinyloxy group. Of these, an alicyclic ether group or a vinyloxy group is preferable, and an epoxy group, an oxetanyl group, or a vinyloxy group is more preferable.

Particularly preferred examples of the polymerizable group include the following.

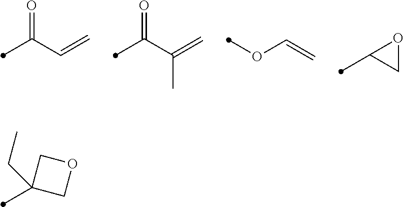

In the present specification, the “alkyl group” may be linear, branched, or cyclic, and examples thereof include a methyl group, an ethyl group, an n-propyl group, an isopropyl group, an n-butyl group, an isobutyl group, a sec-butyl group, a tert-butyl group, an n-pentyl group, an isopentyl group, a neopentyl group, a 1,1-dimethylpropyl group, an n-hexyl group, an isohexyl group, a cyclopropyl group, a cyclobutyl group, a cyclopentyl group, and a cyclohexyl group.

Preferred examples of the polymerizable liquid crystal compound represented by Formula (II) are shown below, but the present invention is not limited to these liquid crystal compounds.

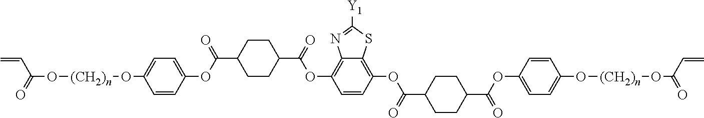

| No | Y1 | n |
|---|---|---|
| II-1-1 | 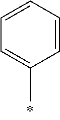 | 6 |
| II-1-2 | 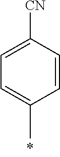 | 6 |
| II-1-3 | 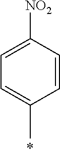 | 6 |
| II-1-4 | 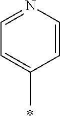 | 6 |
| II-1-5 | 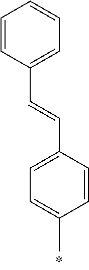 | 6 |
| II-1-6 | 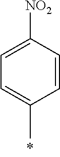 | 11 |
| II-1-7 | 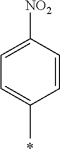 | 8 |
| II-1-8 | 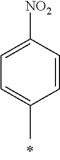 | 4 |
| II-1-9 | 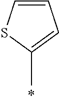 | 6 |
| II-1-10 | 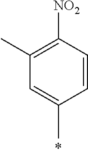 | 6 |
| II-1-11 | 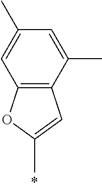 | 6 |
| II-1-12 | 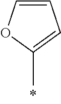 | 6 |
| II-1-13 | 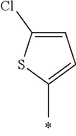 | 6 |
| II-1-14 | 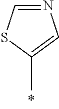 | 6 |
| II-1-15 | 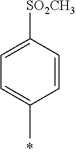 | 6 |

| | |
|---|---|
| 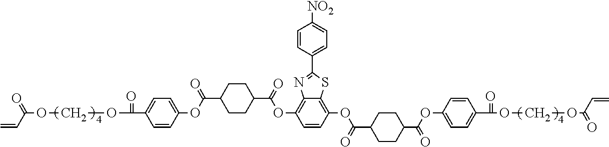 [SMILES: C=CC(=O)OCOC(=O)c1ccc(OC(=O)C2CCC(C(=O)Oc3ccc(OC(=O)C4CCC(C(=O)Oc5ccc(C(=O)OCOC(=O)C=C)cc5)CC4)c4sc(-c5ccc([N+](=O)[O-])cc5)nc34)CC2)cc1] | II-1-16 |
| 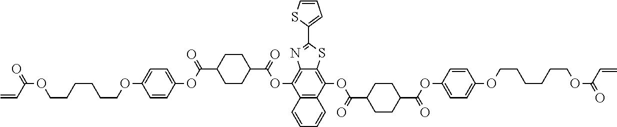 [SMILES: C=CC(=O)OCCCCCCOc1ccc(OC(=O)C2CCC(C(=O)Oc3c4ccccc4c(OC(=O)C4CCC(C(=O)Oc5ccc(OCCCCCCOC(=O)C=C)cc5)CC4)c4sc(-c5cccs5)nc34)CC2)cc1] | II-1-17 |
| 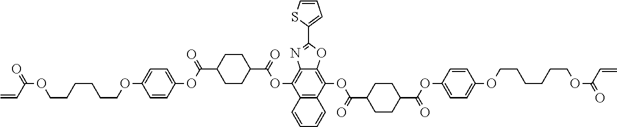 [SMILES: C=CC(=O)OCCCCCCOc1ccc(OC(=O)C2CCC(C(=O)Oc3c4ccccc4c(OC(=O)C4CCC(C(=O)Oc5ccc(OCCCCCCOC(=O)C=C)cc5)CC4)c4oc(-c5cccs5)nc34)CC2)cc1] | II-1-18 |

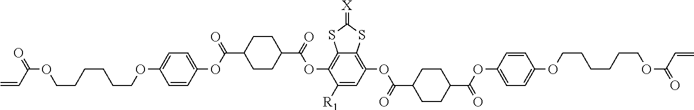

| No | X | R1 |
|---|---|---|
| II-2-1 | 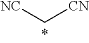 | H |
| II-2-2 | 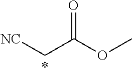 | H |
| II-2-3 | 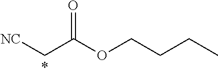 | H |
| II-2-4 | 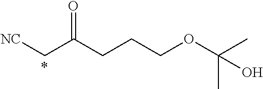 | H |
| II-2-5 | 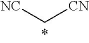 | CH₃ |
| II-2-6 | 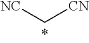 | 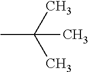 |
| II-2-7 | S | H |

In the above formulae, “*” represents a bonding position.

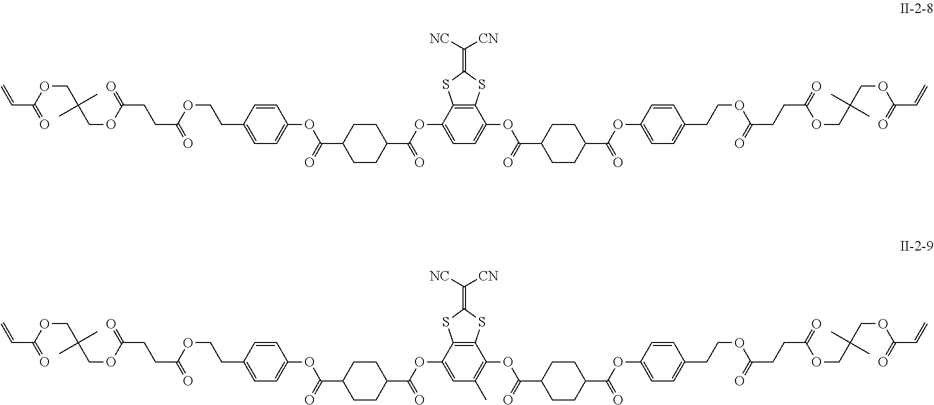

The group adjacent to the acryloyloxy group in Formulae II-2-8 and II-2-9 represents a propylene group (a group in which a methyl group is substituted with an ethylene group), which represents a mixture of regioisomers with different methyl group positions.

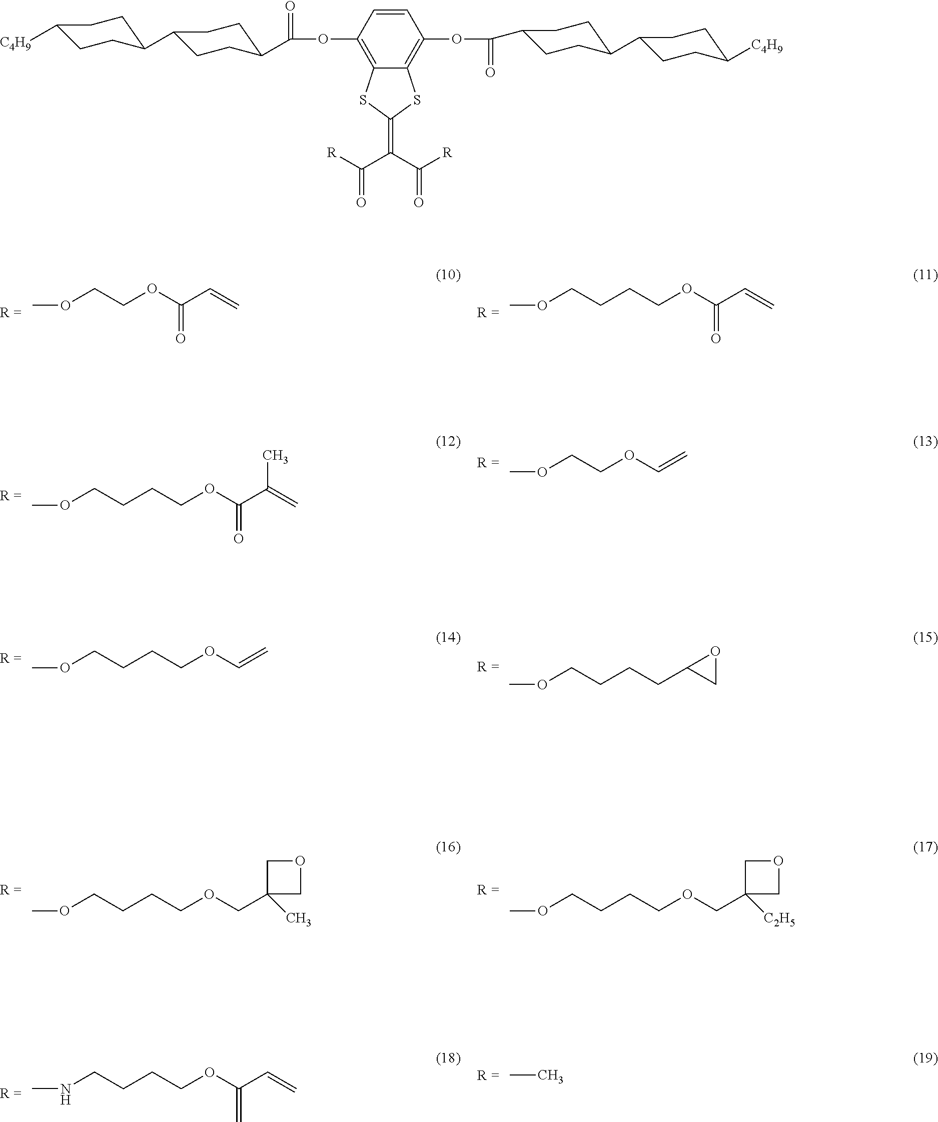

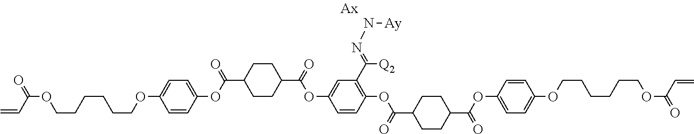

| No | Ax | Ay | Q2 |
|---|---|---|---|
| II-3-1 | 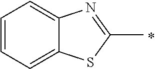 | H | H |
| II-3-2 | 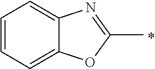 | H | H |
| II-3-3 | 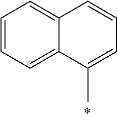 | H | H |
| II-3-4 | Ph | Ph | H |
| II-3-5 | 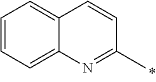 | H | H |
| II-3-6 | 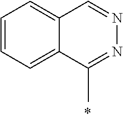 | H | H |
| II-3-7 | 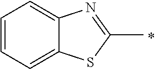 | CH₃ | H |
| II-3-8 | 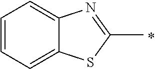 | C₄H₉ | H |
| II-3-9 | 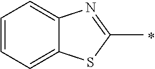 | C₆H₁₃ | H |
| II-3-10 | 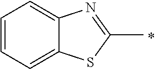 | 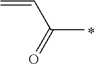 | H |
| II-3-11 | 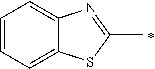 | 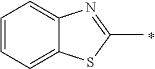 | H |
| II-3-12 | 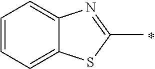 | CH₂CN | H |
| II-3-13 | 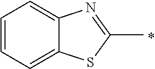 | 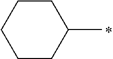 | H |
| II-3-14 | 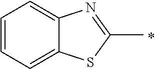 | 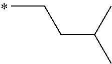 | H |
| II-3-15 | 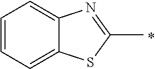 | CH₂CH₂OH | H |
| II-3-16 | 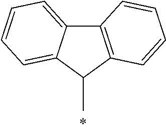 | H | H |
| II-3-17 | 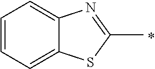 | CH₂CF₃ | H |
| II-3-18 | 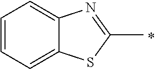 | H | CH₃ |
| II-3-19 | 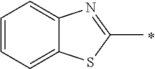 | 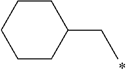 | H |
| II-3-20 | 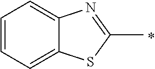 | 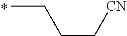 | H |
| II-3-21 | 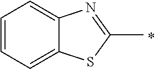 | 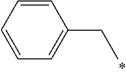 | H |
| II-3-22 | 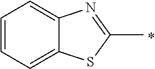 | 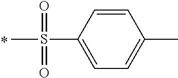 | H |
| II-3-23 | 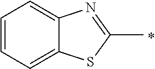 | 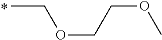 | H |
| II-3-24 | 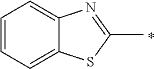 | 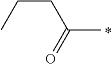 | H |
| II-3-25 | 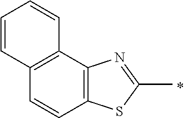 | C₆C₁₃ | H |

| | |
|---|---|
| 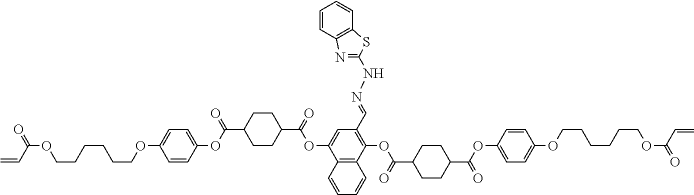 [SMILES: C=CC(=O)OCCCCCCOc1ccc(OC(=O)C2CCC(C(=O)Oc3cc(/C=N/Nc4nc5ccccc5s4)c(OC(=O)C4CCC(C(=O)Oc5ccc(OCCCCCCOC(=O)C=C)cc5)CC4)c4ccccc34)CC2)cc1] | II-3-26 |
| 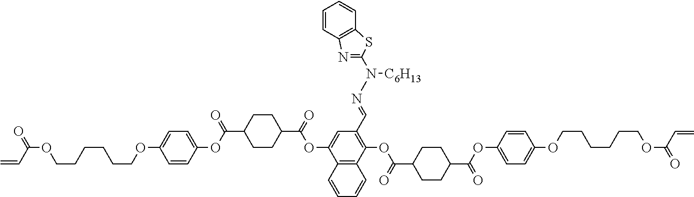 | II-3-27 |
| 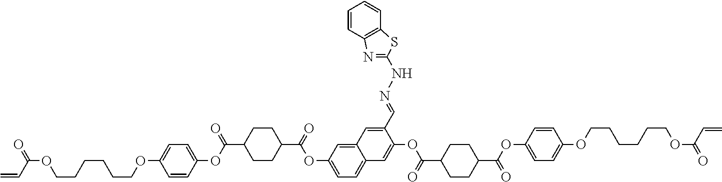 [SMILES: C=CC(=O)OCCCCCCOc1ccc(OC(=O)C2CCC(C(=O)Oc3ccc4cc(OC(=O)C5CCC(C(=O)Oc6ccc(OCCCCCCOC(=O)C=C)cc6)CC5)c(/C=N/Nc5nc6ccccc6s5)cc4c3)CC2)cc1] | II-3-28 |
| 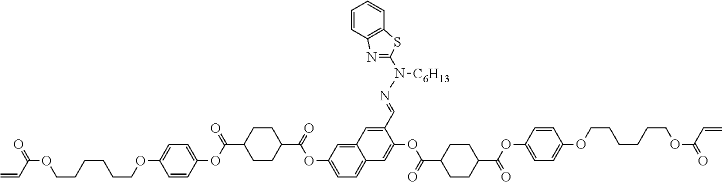 | II-3-29 |

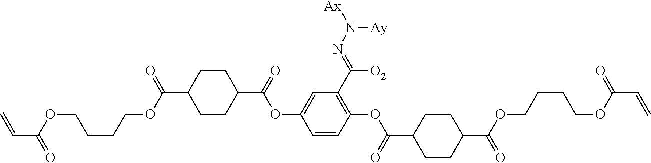

| No | Ax | Ay | Q2 |
|---|---|---|---|
| II-3-30 | 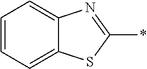 [SMILES: *c1nc2ccccc2s1] | H | H |
| II-3-31 | 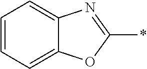 [SMILES: *c1nc2ccccc2o1] | H | H |
| II-3-32 | 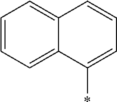 [SMILES: *c1cccc2ccccc12] | H | H |
| II-3-33 | Ph | Ph | H |
| II-3-34 | 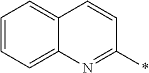 [SMILES: *c1ccc2ccccc2n1] | H | H |
| II-3-35 | 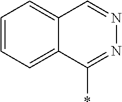 [SMILES: *c1nncc2ccccc12] | H | H |
| II-3-36 | 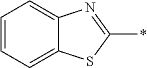 [SMILES: *c1nc2ccccc2s1] | CH₃ | H |
| II-3-37 | 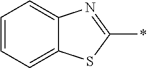 [SMILES: *c1nc2ccccc2s1] | C₄H₉ | H |
| II-3-38 | 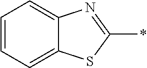 [SMILES: *c1nc2ccccc2s1] | C₆H₁₃ | H |
| II-3-39 | 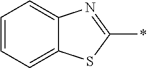 [SMILES: *c1nc2ccccc2s1] | 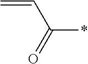 [SMILES: *C(=O)C=C] | H |
| II-3-40 | 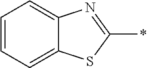 [SMILES: *c1nc2ccccc2s1] | 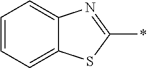 [SMILES: *c1nc2ccccc2s1] | H |
| II-3-41 | 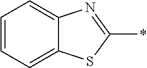 [SMILES: *c1nc2ccccc2s1] | CH₂CN | H |
| II-3-42 | 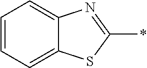 [SMILES: *c1nc2ccccc2s1] | 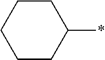 [SMILES: *C1CCCCC1] | H |
| II-3-43 | 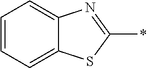 [SMILES: *c1nc2ccccc2s1] | 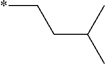 [SMILES: *CCC(C)C] | H |
| II-3-46 | 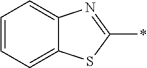 [SMILES: *c1nc2ccccc2s1] | CH₂CH₂OH | H |
| II-3-45 | 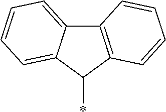 [SMILES: *C1c2ccccc2-c2ccccc21] | H | H |
| II-3-46 | 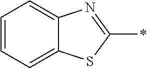 [SMILES: *c1nc2ccccc2s1] | CH₂CF₃ | H |
| II-3-47 | 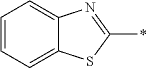 [SMILES: *c1nc2ccccc2s1] | H | CH₃ |
| II -3-48 | 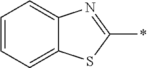 [SMILES: *c1nc2ccccc2s1] | 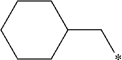 [SMILES: *CC1CCCCC1] | H |
| II-3-49 | 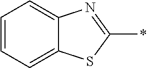 [SMILES: *c1nc2ccccc2s1] | 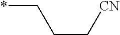 [SMILES: *CCCC#N] | H |
| II-3-50 | 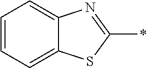 [SMILES: *c1nc2ccccc2s1] | 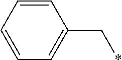 [SMILES: *Cc1ccccc1] | H |
| II-3-51 | 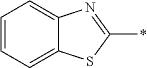 [SMILES: *c1nc2ccccc2s1] | 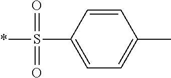 [SMILES: *S(=O)(=O)c1ccc(C)cc1] | H |
| II-3-52 | 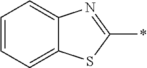 [SMILES: *c1nc2ccccc2s1] | 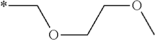 [SMILES: *COCCOC] | H |
| II-3-53 | 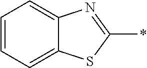 [SMILES: *c1nc2ccccc2s1] | 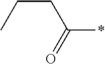 [SMILES: *C(=O)CCC] | H |
| II-3-54 | 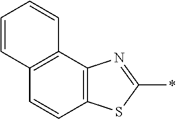 [SMILES: *c1nc2c(ccc3ccccc32)s1] | C₆H₁₃ | H |

II-3-55

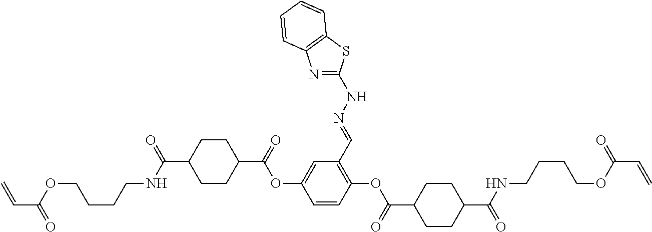 [SMILES: C=CC(=O)OCCCCNC(=O)C1CCC(C(=O)Oc2ccc(OC(=O)C3CCC(C(=O)NCCCCOC(=O)C=C)CC3)c(/C=N/Nc3nc4ccccc4s3)c2)CC1]

II-4-1

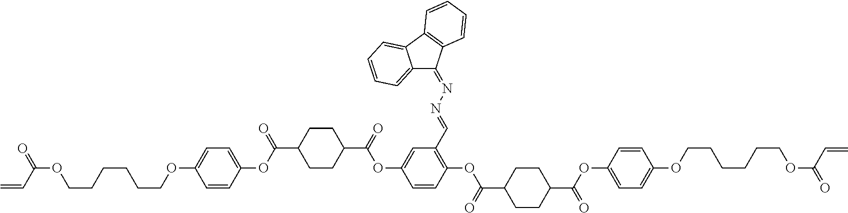 [SMILES: C=CC(=O)OCCCCCCOc1ccc(OC(=O)C2CCC(C(=O)Oc3ccc(OC(=O)C4CCC(C(=O)Oc5ccc(OCCCCCCOC(=O)C=C)cc5)CC4)c(/C=N/N=C4c5ccccc5-c5ccccc54)c3)CC2)cc1]

II-4-2

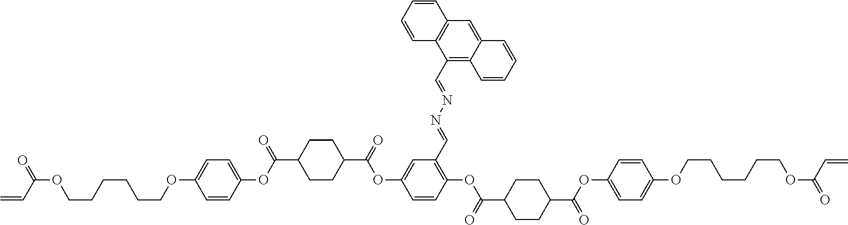 [SMILES: C=CC(=O)OCCCCCCOc1ccc(OC(=O)C2CCC(C(=O)Oc3ccc(OC(=O)C4CCC(C(=O)Oc5ccc(OCCCCCCOC(=O)C=C)cc5)CC4)c(/C=N/N=C/c4c5ccccc5cc5ccccc45)c3)CC2)cc1]

II-4-3

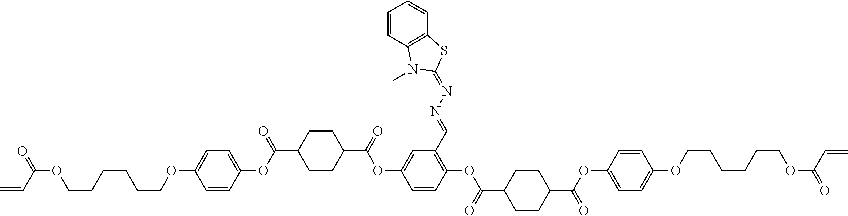 [SMILES: C=CC(=O)OCCCCCCOc1ccc(OC(=O)C2CCC(C(=O)Oc3ccc(OC(=O)C4CCC(C(=O)Oc5ccc(OCCCCCCOC(=O)C=C)cc5)CC4)c(/C=N/N=c4/sc5ccccc5n4C)c3)CC2)cc1]

III-1-1

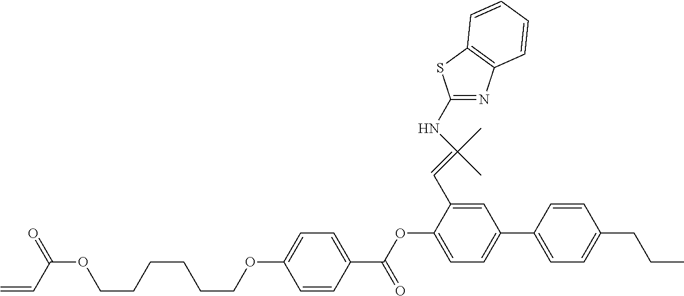

III-1-2

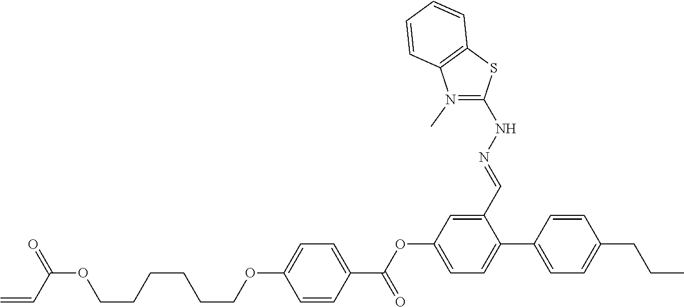

III-2-1

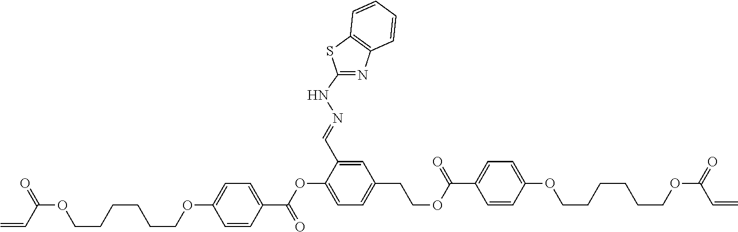 [SMILES: C=CC(=O)OCCCCCCOc1ccc(C(=O)OCCc2ccc(OC(=O)c3ccc(OCCCCCCOC(=O)C=C)cc3)c(/C=N/Nc3nc4ccccc4s3)c2)cc1]

III-2-2

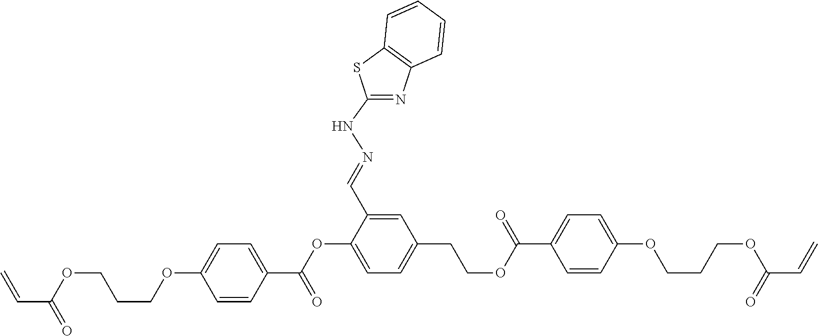 [SMILES: C=CC(=O)OCCCOc1ccc(C(=O)OCCc2ccc(OC(=O)c3ccc(OCCCOC(=O)C=C)cc3)c(/C=N/Nc3nc4ccccc4s3)c2)cc1]

III-2-3

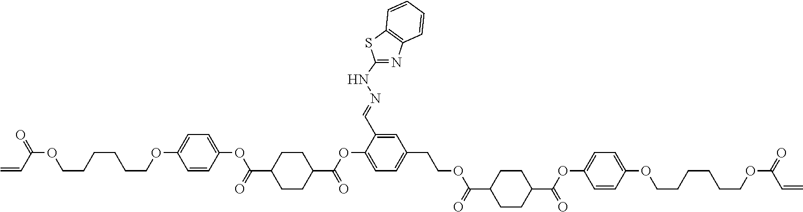 [SMILES: C=CC(=O)OCCCCCCOc1ccc(OC(=O)C2CCC(C(=O)OCCc3ccc(OC(=O)C4CCC(C(=O)Oc5ccc(OCCCCCCOC(=O)C=C)cc5)CC4)c(/C=N/Nc4nc5ccccc5s4)c3)CC2)cc1]

III-3-1

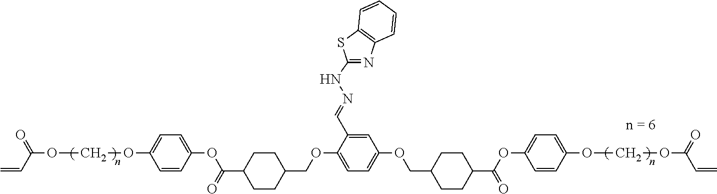 [SMILES: C=CC(=O)OCOc1ccc(OC(=O)C2CCC(COc3ccc(OCC4CCC(C(=O)Oc5ccc(OCOC(=O)C=C)cc5)CC4)c(/C=N/Nc4nc5ccccc5s4)c3)CC2)cc1]

III-3-2

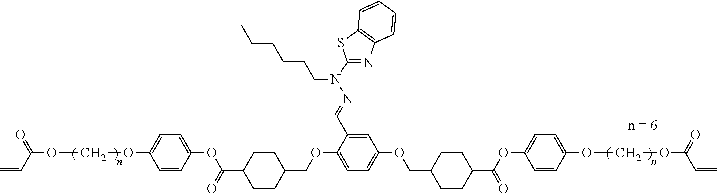 [SMILES: C=CC(=O)OCOc1ccc(OC(=O)C2CCC(COc3ccc(OCC4CCC(C(=O)Oc5ccc(OCOC(=O)C=C)cc5)CC4)c(/C=N/N(CCCCCC)c4nc5ccccc5s4)c3)CC2)cc1]

III-3-3

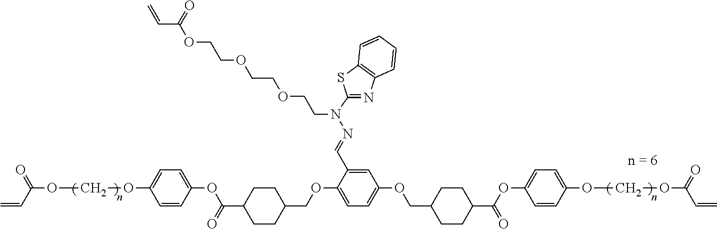 [SMILES: C=CC(=O)OCCOCCOCCN(/N=C/c1cc(OCC2CCC(C(=O)Oc3ccc(OCOC(=O)C=C)cc3)CC2)ccc1OCC1CCC(C(=O)Oc2ccc(OCOC(=O)C=C)cc2)CC1)c1nc2ccccc2s1]

III-3-4

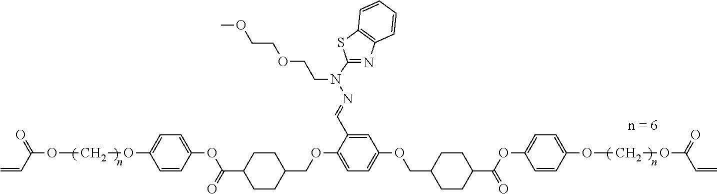 [SMILES: C=CC(=O)OCOc1ccc(OC(=O)C2CCC(COc3ccc(OCC4CCC(C(=O)Oc5ccc(OCOC(=O)C=C)cc5)CC4)c(/C=N/N(CCOCCOC)c4nc5ccccc5s4)c3)CC2)cc1]

In addition to the above preferred examples, other preferred examples of the side chain structure are shown below.

TABLE 1

| | K (side chain structure) |
|---|---|
| 1-1 | 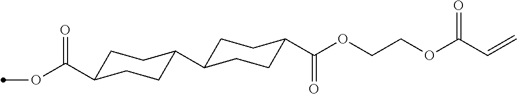 |
| 1-2 | 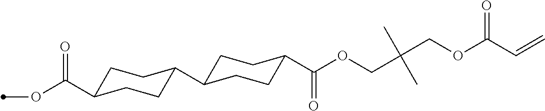 |
| 1-3 | 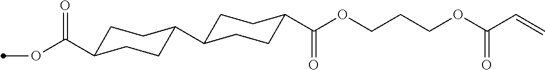 |
| 1-4 | 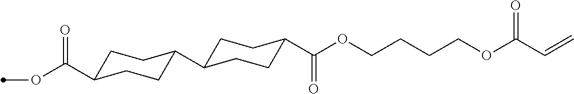 |
| 1-5 | 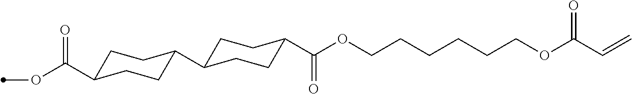 |
| 1-6 | 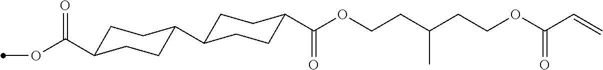 |
| 1-7 | 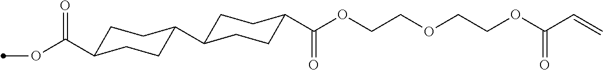 |
| 1-8 | 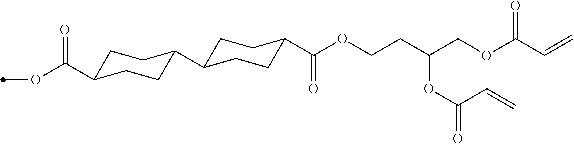 |
| 1-9 | 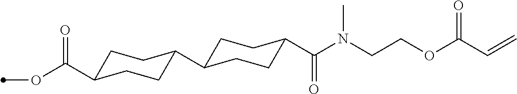 |
| 1-10 | 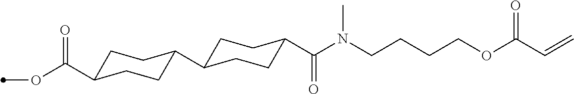 |
| 1-11 | 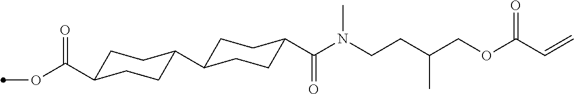 |
| 1-12 | 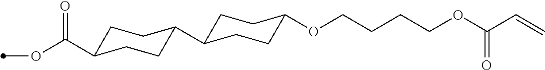 |
| 1-13 | 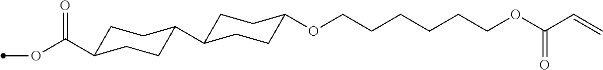 |
| 1-14 | 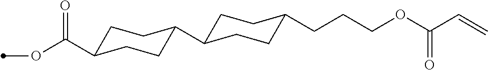 |

TABLE 2

| | K (side chain structure) |
|---|---|
| 2-1 | 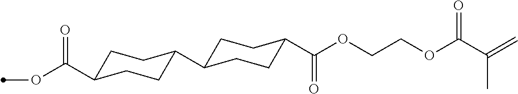 |
| 2-2 | 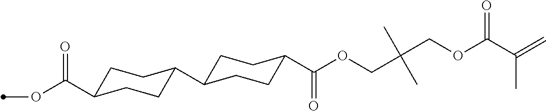 |
| 2-3 | 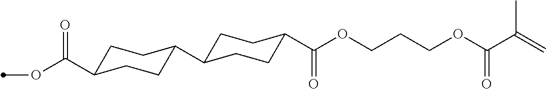 |
| 2-4 | 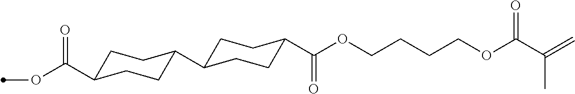 |
| 2-5 | 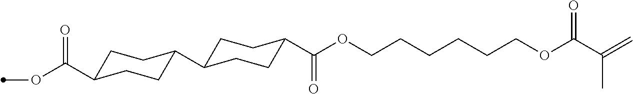 |
| 2-6 | 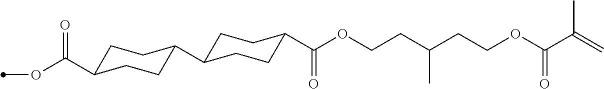 |
| 2-7 | 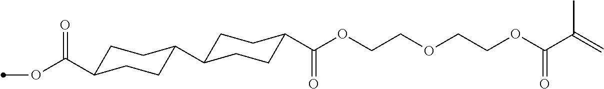 |
| 2-8 | 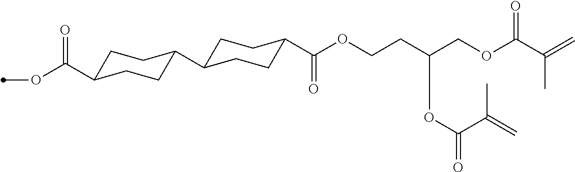 |
| 2-9 | 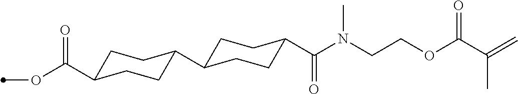 |
| 2-10 | 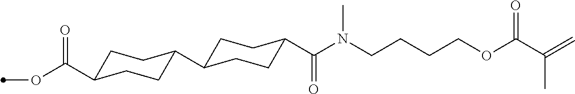 |
| 2-11 | 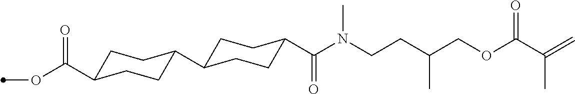 |
| 2-12 | 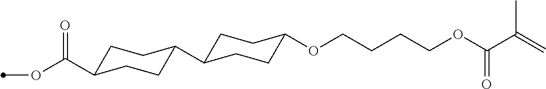 |
| 2-13 | 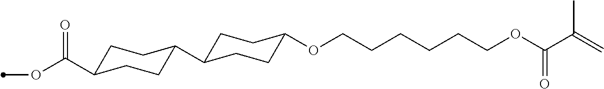 |
| 2-14 | 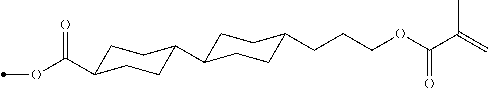 |

In addition, another preferred aspect of the specific liquid crystal compound may be, for example, a compound represented by Formula (V).

L¹-[D¹-G¹]ₘ-E¹-A-E²-[G²-D²]ₙ-L² (V)

In Formula (V),

A is a non-aromatic carbocyclic group or heterocyclic group having 5 to 8 carbon atoms, or an aromatic group or heteroaromatic group having 6 to 20 carbon atoms;

E¹, E², D¹, and D² are each independently a single bond or a divalent linking group;

L¹ and L² are each independently —H, —F, —Cl, —Br, —I, —CN, —NC, —NCO, —OCN, —SCN, —C(═O)NR¹R², —C(═O)R¹, —O—C(═O)R¹, —NH₂, —SH, —SR¹, —SO₃H, —SO₂R¹, —OH, —NO₂, —CF₃, —SF₃, substituted or unsubstituted silyl, a substituted or unsubstituted carbyl group or hydrocarbyl group having 1 to 40 carbon atoms, or -Sp-P, at least one of L¹ or L² is -Sp-P, P is a polymerizable group, Sp is a spacer group or a single bond, and R¹ and R² are each independently —H or alkyl having 1 to 12 carbon atoms;

m and n are each independently an integer of 1 to 5; in a case where m or n is 2 or more, the repeating units of each of -(D¹-G¹)- or -(G²-D²)- which are repeated 2 or more may be the same as or different from each other;

G¹ and G² are each independently a non-aromatic carbocyclic group or heterocyclic group having 5 to 8 carbon atoms or an aromatic group or heteroaromatic group having 6 to 20 carbon atoms, at least one of G¹ or G² is the carbocyclic group or the heterocyclic group, and any one hydrogen atom contained in the carbocyclic or heterocyclic group is substituted with a group represented by Formula (VI):

*-[Q¹]ₚ-B¹ (VI)

In Formula (VI),

p is an integer of 1 to 10, and in a case where p is 2 or more, repeating units of -(Q¹)- which is repeated 2 or more may be the same as or different from each other,

Q¹'s are each independently a divalent group selected from the group consisting of —C≡C—, —CY¹ ═CY²—, and a substituted or unsubstituted aromatic group or heteroaromatic group having 6 to 20 carbon atoms, and Y¹ and Y² are each independently —H, —F, —Cl, —CN, or —R¹,

B¹ is —H, —F, —Cl, —Br, —I, —CN, —NC, —NCO, —OCN, —SCN, —C(═O)NR¹R², —C(═O)R¹, —NH₂, —SH, —SR¹, —SO₃H, —SO₂R¹, —OH, —NO₂, —CF₃, —SF₃, a polymerizable group, an alkenyl group having 2 to 6 carbon atoms, an alkynyl group having 2 to 6 carbon atoms, an acyl group having 2 to 4 carbon atoms, an alkynylene group having 2 to 6 carbon atoms with an acyl group having 2 to 4 carbon atoms bonded to a terminal thereof, an alcohol group having 1 to 5 carbon atoms, or an alkoxy group having 1 to 12 carbon atoms, and

R¹ and R² are each independently —H or alkyl having 1 to 12 carbon atoms.

Preferred specific examples of Formula (V) are shown below.

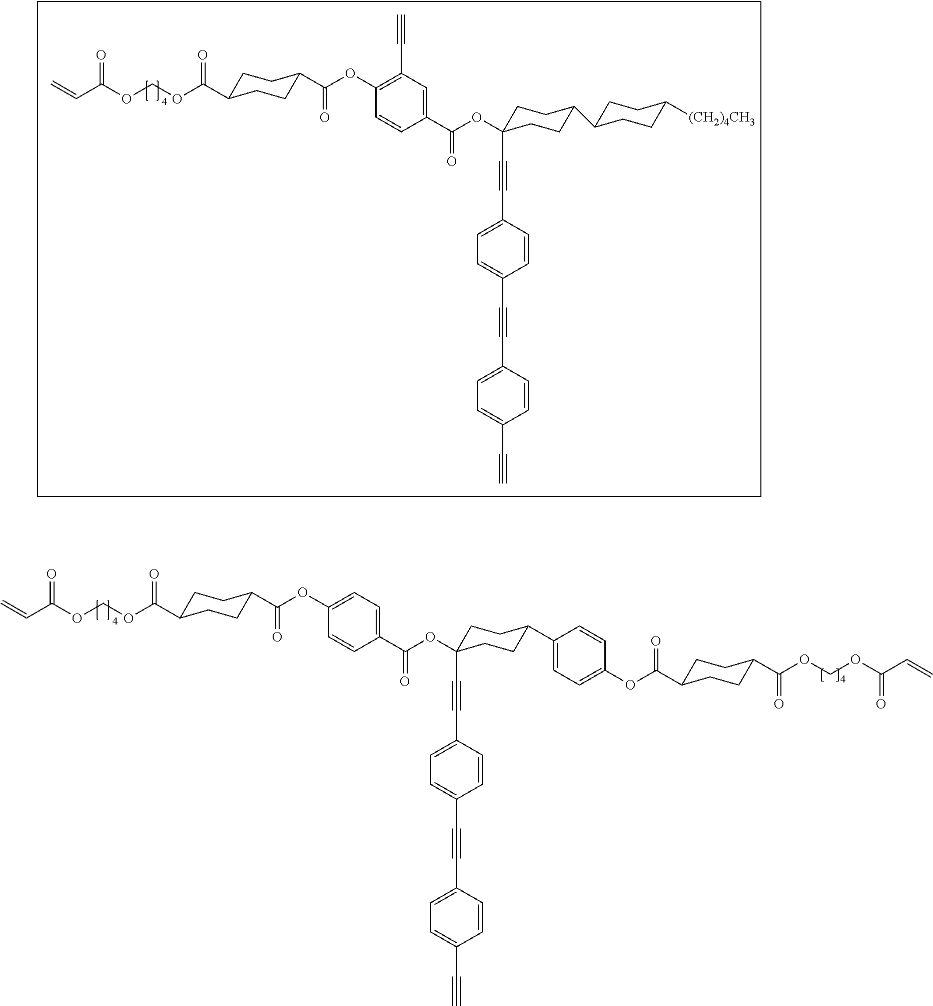

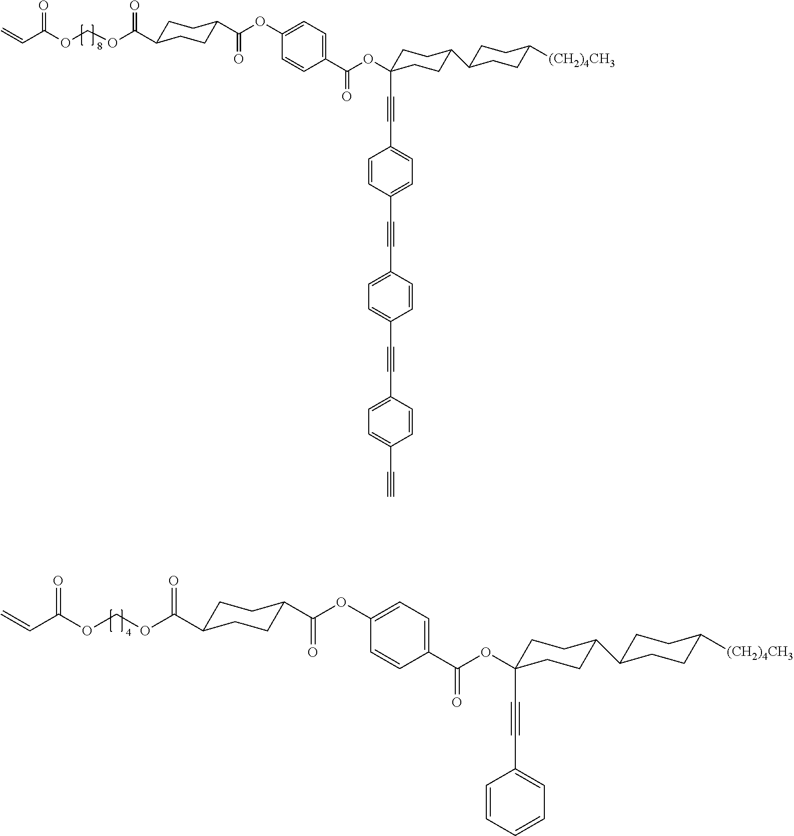

The content of the specific liquid crystal compound in the polymerizable liquid crystal composition is not particularly limited, and is preferably 50% to 100% by mass and more preferably 70% to 99% by mass with respect to the total solid content in the polymerizable liquid crystal composition.

The specific liquid crystal compound may be used alone or in combination of two or more thereof.

The solid content means other components in the polymerizable liquid crystal composition excluding a solvent, and the components are calculated as the solid content even in a case where the properties thereof are liquid.

From the viewpoint of controlling the liquid crystal alignment properties, the polymerizable liquid crystal composition may contain a polymerizable rod-like compound in addition to the above-mentioned specific liquid crystal compound.

The polymerizable rod-like compound may or may not be liquid crystalline.

From the viewpoint of compatibility with the above-mentioned specific liquid crystal compound, the polymerizable rod-like compound is preferably a compound having, in part, a cyclohexane ring in which one hydrogen atom is substituted with a linear alkyl group (hereinafter, also simply referred to as “alkylcyclohexane ring-containing compound”).

Here, the “cyclohexane ring in which one hydrogen atom is substituted with a linear alkyl group” refers to a cyclohexane ring in which one hydrogen atom of a cyclohexane ring present on a molecular terminal side is substituted with a linear alkyl group, for example, in a case of having two cyclohexane rings, as shown in Formula (2).

Examples of the alkylcyclohexane ring-containing compound include compounds having a group represented by Formula (2), among which a compound represented by Formula (3) having a (meth)acryloyl group is preferable from the viewpoint of imparting moisture-heat resistance to an optically anisotropic layer.

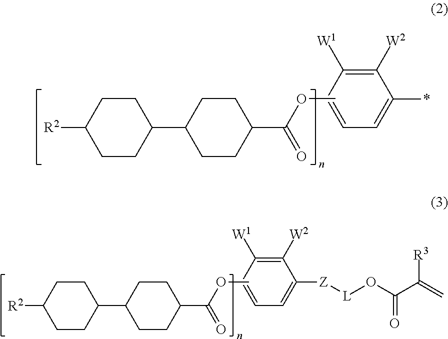

Here, in Formula (2), * represents a bonding position.

In addition, in Formulae (2) and (3), R² represents an alkyl group having 1 to 10 carbon atoms, n represents 1 or 2, W¹ and W² each independently represent an alkyl group, an alkoxy group, or a halogen atom, and W¹ and W² may be bonded to each other to form a ring structure which may have a substituent.

In addition, in Formula (3), Z represents —COO—, L represents an alkylene group having 1 to 6 carbon atoms, and R³ represents a hydrogen atom or a methyl group.

Specific examples of such an alkylcyclohexane ring-containing compound include compounds represented by Formulae A-1 to A-5. R⁴ in Formula A-3 represents an ethyl group or a butyl group.

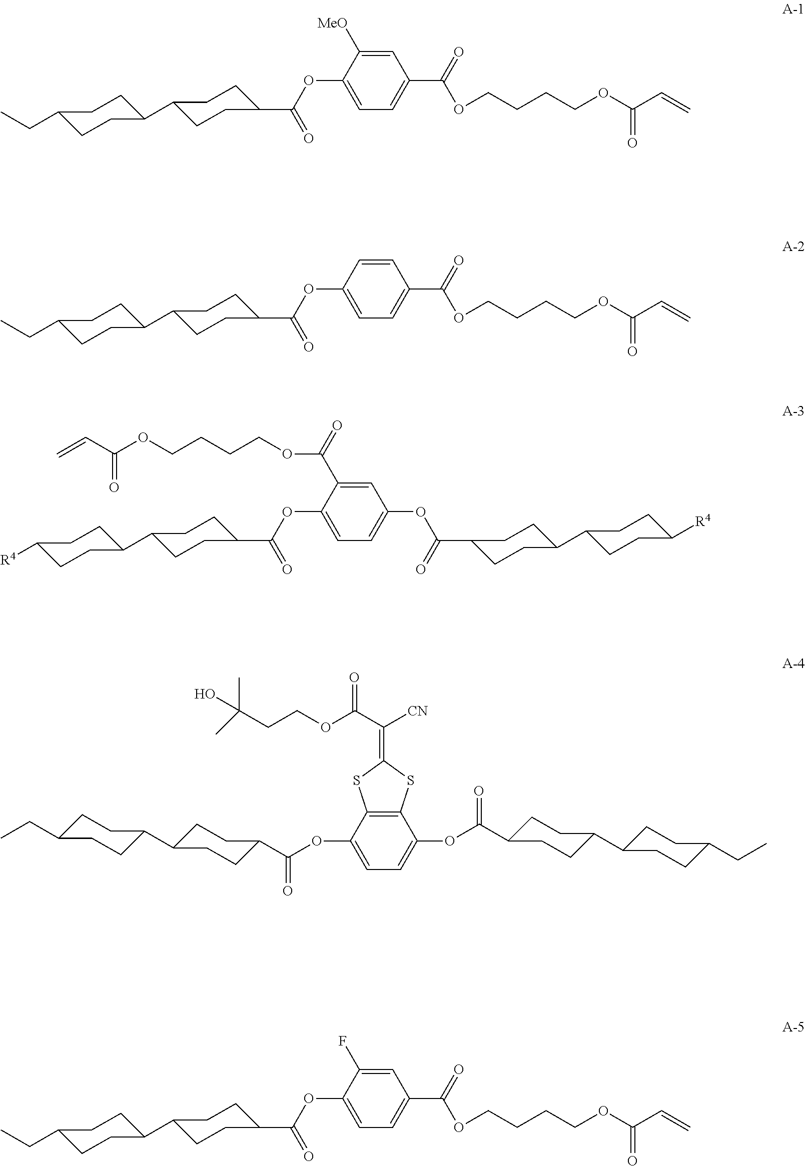

In a case where the polymerizable liquid crystal composition contains the polymerizable rod-like compound, the content of the polymerizable rod-like compound is preferably 1% to 30% by mass and more preferably 1% to 20% by mass with respect to the total mass of the above-mentioned specific liquid crystal compound and the polymerizable rod-like compound.

The polymerizable liquid crystal composition may contain a polymerizable liquid crystal compound (hereinafter, also simply referred to as “another polymerizable liquid crystal compound”) other than the above-mentioned specific liquid crystal compound and the polymerizable rod-like compound.

Here, the polymerizable group contained in the other polymerizable liquid crystal compound is not particularly limited, and examples thereof include a (meth)acryloyl group, a vinyl group, a styryl group, and an allyl group. Of these, a (meth)acryloyl group is preferable.

From the viewpoint of improving the durability of an optically anisotropic layer, the other polymerizable liquid crystal compound is preferably a polymerizable compound having two to four polymerizable groups and more preferably a polymerizable compound having two polymerizable groups.

Examples of such other polymerizable liquid crystal compound include compounds represented by the Formulae (M1), (M2), and (M3) described in paragraphs [0030] to [0033] of JP2014-077068A. More specifically, specific examples described in paragraphs [0046] to [0055] of the same publication can be mentioned.

The other polymerizable liquid crystal compound may be used alone or in combination of two or more thereof.

In a case where the polymerizable liquid crystal composition contains another polymerizable liquid crystal compound, the content of the other polymerizable liquid crystal compound is preferably 1% to 40% by mass and more preferably 1% to 10% by mass with respect to the total mass of the specific liquid crystal compound, the polymerizable rod-like compound, and the other polymerizable liquid crystal compound described above.

The polymerizable liquid crystal composition preferably contains a non-liquid crystal polyfunctional polymerizable compound, from the viewpoint of further improving the durability of a polarizing plate having an optically anisotropic layer to be formed.

It is presumed that this is because an increase in the crosslinking point density suppresses the movement of a compound that serves as a catalyst of a hydrolysis reaction (presumed to be a liquid crystal decomposition product), and as a result, the rate of the hydrolysis reaction slows down and the diffusion of moisture to the end parts progresses during that time.

The non-liquid crystal polyfunctional polymerizable compound is preferably a compound having a low acrylic equivalent, from the viewpoint of the aligning properties of the specific liquid crystal compound described above.

Specifically, the non-liquid crystal polyfunctional polymerizable compound is preferably a compound having a (meth)acrylic equivalent of 120 g/eq. or less, more preferably a compound having a (meth)acrylic equivalent of 100 g/eq. or less, and still more preferably a compound having a (meth)acrylic equivalent of 90 g/eq. or less.

Examples of the non-liquid crystal polyfunctional polymerizable compound include an ester of a polyhydric alcohol and a (meth)acrylic acid (for example, ethylene glycol di(meth)acrylate, 1,4-cyclohexanediacrylate, pentaerythritol tetra(meth)acrylate, pentaerythritol tri(meth)acrylate, trimethylolpropane tri(meth)acrylate, trimethylolethane tri(meth)acrylate, dipentaerythritol tetra(meth)acrylate, dipentaerythritol penta(meth)acrylate, dipentaerythritol hexa(meth)acrylate, 1,2,3-cyclohexanetetramethacrylate, polyurethane polyacrylate, or polyester polyacrylate), vinylbenzene and a derivative thereof (for example, 1,4-divinylbenzene, 4-vinylbenzoic acid-2-acryloylethyl ester, or 1,4-divinylcyclohexanone), vinyl sulfone (for example, divinyl sulfone), acrylamide (for example, methylenebisacrylamide), and methacrylamide.

In a case where the polymerizable liquid crystal composition contains a non-liquid crystal polyfunctional polymerizable compound, the content of the non-liquid crystal polyfunctional polymerizable compound is preferably 0.1% to 20% by mass, more preferably 0.1% to 10% by mass, and still more preferably 1% to 6% by mass with respect to the total solid content in the polymerizable liquid crystal composition, from the viewpoint of expressing the phase difference of an optically anisotropic layer to be formed.

The polymerizable liquid crystal composition preferably contains a polymerization initiator.

The polymerization initiator is preferably a photopolymerization initiator capable of initiating a polymerization reaction upon irradiation with ultraviolet rays.

Examples of the photopolymerization initiator include α-carbonyl compounds (as described in U.S. Pat. Nos. 2,367,661A and 2,367,670A), acyloin ethers (as described in U.S. Pat. No. 2,448,828A), α-hydrocarbon-substituted aromatic acyloin compounds (as described in U.S. Pat. No. 2,722,512A), polynuclear quinone compounds (as described in U.S. Pat. Nos. 3,046,127A and 2,951,758A), combinations of triarylimidazole dimers with p-aminophenyl ketones (as described in U.S. Pat. No. 3,549,367A), acridine and phenazine compounds (as described in JP1985-105667A (JP-S60-105667A) and U.S. Pat. No. 4,239,850A), oxadiazole compounds (as described in U.S. Pat. No. 4,212,970A), and acylphosphine oxide compounds (as described in JP1988-40799B (JP-S63-40799B), JP1993-29234B (JP-H05-29234B), JP1998-95788A (JP-H10-95788A), and JP1998-29997A (JP-H10-29997A)).

From the viewpoint of improving the durability of an optically anisotropic layer, the polymerization initiator is preferably an oxime type polymerization initiator and more preferably a polymerization initiator represented by Formula (III).

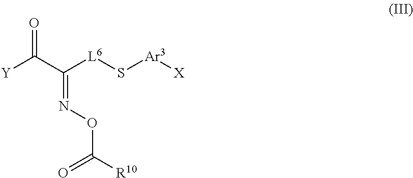

In Formula (III), X represents a hydrogen atom or a halogen atom, and Y represents a monovalent organic group.

In addition, Ar³ represents a divalent aromatic group, L⁶ represents a divalent organic group having 1 to 12 carbon atoms, and R¹⁰ represents an alkyl group having 1 to 12 carbon atoms.

Examples of the halogen atom represented by X in Formula (III) include a fluorine atom, a chlorine atom, a bromine atom, and an iodine atom, among which a chlorine atom is preferable.

In addition, examples of the divalent aromatic group represented by Ar³ in Formula (II) include divalent groups which have an aromatic hydrocarbon ring such as a benzene ring, a naphthalene ring, an anthracene ring, or a phenanthroline ring; or an aromatic heterocyclic ring such as a furan ring, a pyrrole ring, a thiophene ring, a pyridine ring, a thiazole ring, or a benzothiazole ring.

In addition, examples of the divalent organic group having 1 to 12 carbon atoms represented by L⁶ in Formula (III) include a linear or branched alkylene group having 1 to 12 carbon atoms, specific examples of which include a methylene group, an ethylene group, and a propylene group.

In addition, examples of the alkyl group having 1 to 12 carbon atoms represented by R¹⁰ in Formula (III) include a methyl group, an ethyl group, and a propyl group.

In addition, examples of the monovalent organic group represented by Y in Formula (III) include a functional group containing a benzophenone skeleton ((C₆H₅)₂CO). Specifically, a functional group containing a benzophenone skeleton in which the terminal benzene ring is unsubstituted or monosubstituted is preferable such as a group represented by Formula (3a) or Formula (3b).

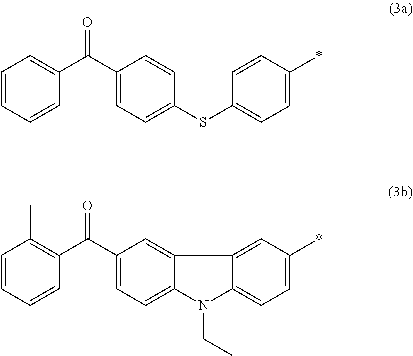 [SMILES: *c1ccc(Sc2ccc(C(=O)c3ccccc3)cc2)cc1 ; *c1ccc2c(c1)c1cc(C(=O)c3ccccc3C)ccc1n2CC]

Here, in Formula (3a) and Formula (3b), * represents a bonding position, that is, a bonding position with the carbon atom of the carbonyl group in Formula (III).

Examples of the oxime type polymerization initiator represented by Formula (III) include a compound represented by Formula S-1 and a compound represented by Formula S-2.

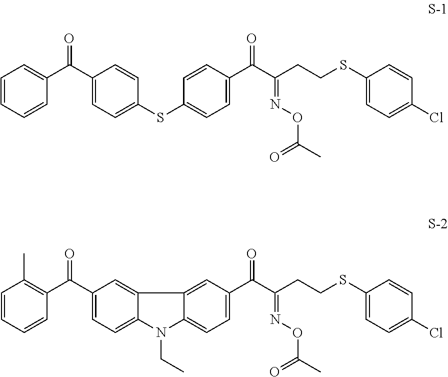 [SMILES: CC(=O)O/N=C(\CCSc1ccc(Cl)cc1)C(=O)c1ccc(Sc2ccc(C(=O)c3ccccc3)cc2)cc1 ; CCn1c2ccc(C(=O)/C(CCSc3ccc(Cl)cc3)=N/OC(C)=O)cc2c2cc(C(=O)c3ccccc3C)ccc21]

The content of the polymerization initiator is not particularly limited, and the content of the polymerization initiator is preferably 0.5 to 10 parts by mass and more preferably 1 to 5 parts by mass with respect to 100 parts by mass of the specific liquid crystal compound contained in the polymerizable liquid crystal composition.

The polymerizable liquid crystal composition may contain an alignment control agent, if necessary.

Examples of the alignment control agent include a low molecular weight alignment control agent and a high molecular weight alignment control agent. For the low molecular weight alignment control agent, for example, reference can be made to the description in paragraphs [00091 to [0083] of JP2002-020363A, paragraphs [0111] to [0120] of JP2006-106662A, and paragraphs [0021] to [0029] of JP2012-211306A, the contents of which are incorporated herein by reference. In addition, for the high molecular weight alignment control agent, for example, reference can be made to the description in paragraphs [0021] to

of JP2004-198511A, and paragraphs [0121] to [0167] of JP2006-106662A, the contents of which are incorporated herein by reference.

The amount of the alignment control agent used is preferably 0.01% to 10% by mass and more preferably 0.05% to 5% by mass with respect to the total solid content of the polymerizable liquid crystal composition. By using the alignment control agent, for example, a homogeneous alignment state aligned parallel to the surface of an optically anisotropic layer can be formed.

The polymerizable liquid crystal composition preferably contains an organic solvent from the viewpoint of workability for forming an optically anisotropic layer.

Examples of the organic solvent include ketones (for example, acetone, 2-butanone, methyl ethyl ketone, methyl isobutyl ketone, cyclohexanone, and cyclopentanone), ethers (for example, dioxane and tetrahydrofuran), aliphatic hydrocarbons (for example, hexane), alicyclic hydrocarbons (for example, cyclohexane), aromatic hydrocarbons (for example, toluene, xylene, and trimethylbenzene), halogenated carbons (for example, dichloromethane, dichloroethane, dichlorobenzene, and chlorotoluene), esters (for example, methyl acetate, ethyl acetate, and butyl acetate), water, alcohols (for example, ethanol, isopropanol, butanol, and cyclohexanol), cellosolves (for example, methyl cellosolve and ethyl cellosolve), cellosolve acetates, sulfoxides (for example, dimethyl sulfoxide), and amides (for example, dimethyl formamide and dimethyl acetamide). These solvent compounds may be used alone or in combination of two or more thereof.

The polymerizable liquid crystal composition may contain components other than the above-mentioned components, examples of which include a liquid crystal compound other than the above-mentioned specific liquid crystal compound, a surfactant, a tilt angle control agent, an alignment assistant, a plasticizer, and a crosslinking agent.

The optically anisotropic layer is formed of the above-mentioned polymerizable liquid crystal composition.

The method for producing an optically anisotropic layer is not particularly limited, and may be, for example, a method in which the polymerizable liquid crystal composition is coated on a predetermined substrate (for example, a polarizer which will be described later, a support which will be described later, or a support having an alignment film) to form a coating film, the coating film is subjected to an alignment treatment to bring the specific liquid crystal compound into a predetermined alignment state, and then the coating film is subjected to a curing treatment.

The coating can be carried out by a known method (for example, a wire bar coating method, an extrusion coating method, a direct gravure coating method, a reverse gravure coating method, or a die-coating method).

The alignment treatment can be carried out by drying or heating at room temperature (for example, 20° C. to 25° C.). In a case of a thermotropic liquid crystal compound, the liquid crystal phase formed by the alignment treatment can generally be transferred by a change in temperature or pressure. In a case of a liquid crystal compound having lyotropic properties, the liquid crystal phase formed by the alignment treatment can also be transferred by a compositional ratio of an amount of solvent.

In a case where the alignment treatment is carried out at a heating temperature, the heating time (heat aging time) is preferably 10 seconds to 5 minutes, more preferably 10 seconds to 3 minutes, and still more preferably 10 seconds to 2 minutes.

The curing treatment (irradiation with active energy rays (light irradiation treatment) and/or heat treatment) on the coating film can also be said to be an immobilization treatment for fixing the alignment of the specific liquid crystal compound.

Above all, it is preferable to carry out the light irradiation treatment. In the polymerization by light irradiation, it is preferable to use ultraviolet rays.

The irradiation amount is preferably 10 mJ/cm² to 50 J/cm², more preferably 20 mJ/cm² to 5 J/cm², still more preferably 30 mJ/cm² to 3 J/cm², and particularly preferably 50 to 1,000 mJ/cm²

In addition, the light irradiation treatment may be carried out under heating conditions, in order to promote the polymerization reaction.

As described above, the optically anisotropic layer can be formed on a support which will be described later and on a polarizer which will be described later.

The thickness of the optically anisotropic layer is not particularly limited, and is preferably 1 to 5 μm, more preferably 1 to 4 μm, and still more preferably 1 to 3 μm.

The optically anisotropic layer preferably satisfies Expression (IV).

Re(450)≤Re(550)≤Re(650) (IV)

Here, in Expression (IV), Re(450) represents an in-plane retardation of the optically anisotropic film at a wavelength of 450 nm, Re(550) represents an in-plane retardation of the optically anisotropic film at a wavelength of 550 nm, and Re(650) represents an in-plane retardation of the optically anisotropic film at a wavelength of 650 nm.

The optically anisotropic layer is preferably a positive A plate.

In the present specification, the positive A plate is defined as follows. The positive A plate (A plate which is positive) satisfies the relationship of Expression (A1) in a case where a refractive index in a film in-plane slow axis direction (in a direction in which an in-plane refractive index is maximum) is defined as nx, a refractive index in an in-plane direction orthogonal to the in-plane slow axis is defined as ny, and a refractive index in a thickness direction is defined as nz. In addition, the positive A plate has an Rth showing a positive value.

nx>ny≈nz Expression (A1)

Furthermore, the symbol “≈” encompasses not only a case where the both sides are completely the same as each other but also a case where the both sides are substantially the same as each other. The expression “substantially the same” means that, for example, a case where (ny−nz)×d (in which d is a thickness of a film) is −10 to 10 nm and preferably −5 to 5 nm is also included in “ny≈nz”.

The positive A plate can be obtained by horizontal alignment of a rod-like polymerizable liquid crystal compound. For details of the method for producing the positive A plate, for example, reference can be made to the description in JP2008-225281A, JP2008-026730A, and the like.

The optically anisotropic layer (positive A plate) preferably functions as a λ/4 plate.

The λ/4 plate is a plate having a function of converting linearly polarized light having a certain specific wavelength into circularly polarized light (or converting circularly polarized light into linearly polarized light), and refers to a plate in which an in-plane retardation Re(λ) at a specific wavelength λ nm satisfies Re(λ)=9λ/4.

This expression may be achieved at any wavelength in a visible light range (for example, 550 nm), but the in-plane retardation Re(550) at a wavelength of 550 nm preferably satisfies a relationship of 110 nm≤Re(550)≤160 nm, and more preferably a relationship of 110 nm≤Re(550)≤150 nm.

In addition, the optically anisotropic layer may have a positive C plate in addition to the positive A plate.

In the present specification, the positive C plate is defined as follows. The positive C plate (C plate which is positive) satisfies the relationship of Expression (A2) in a case where a refractive index in a film in-plane slow axis direction (in a direction in which an in-plane refractive index is maximum) is defined as nx, a refractive index in an in-plane direction orthogonal to the in-plane slow axis is defined as ny, and a refractive index in a thickness direction is defined as nz. The positive C plate has an Rth showing a negative value.

nx≈ny<nz Expression (A2)

Furthermore, the symbol “≈” encompasses not only a case where the both sides are completely the same as each other but also a case where the both sides are substantially the same as each other. The expression “substantially the same” means that, for example, a case where (nx−ny)×d (in which d is a thickness of a film) is −10 to 10 nm and preferably −5 to 5 nm is also included in “nx≈ny”.

In addition, in the positive C plate, Re≈0 according to the above definition.

The positive C plate can be obtained by vertical alignment of a rod-like polymerizable liquid crystal compound. For details of the method for producing the positive C plate, for example, reference can be made to the description in JP2017-187732A, JP2016-53709A, and JP2015-200861A.

<Polarizer>

The polarizer is a so-called linear polarizer having a function of converting light into specific linearly polarized light. The polarizer is not particularly limited, and an absorption type polarizer can be used.

The type of the polarizer is not particularly limited, and may be, for example, a polarizer containing a polyvinyl alcohol (PVA)-based resin commonly used as a main component (PVA polarizer). For example, the polarizer is prepared by adsorbing iodine or a dichroic dye on a polyvinyl alcohol-based resin and then stretching the resin. The fact that the polyvinyl alcohol-based resin is the main component means that the content of the polyvinyl alcohol-based resin with respect to the total mass of the polarizer is 50% by mass or more.

The polyvinyl alcohol-based resin is a resin containing a repeating unit of —CH₂—CHOH—, and examples thereof include a polyvinyl alcohol and an ethylene-vinyl alcohol copolymer.

On the other hand, the polyvinyl alcohol-based resin is very hydrophilic, exhibits high moisture absorption properties, and have a very large contribution to the moisture content of the entire polarizing plate. The moisture content can be adjusted by reducing the film thickness of the polarizer. In addition, as described in JP2015-129826A, it is disclosed that a laminate having a 9 μm-thick polyvinyl alcohol layer formed on a non-liquid crystal PET (polyethylene terephthalate) substrate is dyed and stretched to obtain a polyvinyl alcohol layer having a thickness of 4 μm, and it is also preferable to use such a method.

In the present invention, in a case where the PVA polarizer is used, the thickness of the polyvinyl alcohol-based resin layer needs to be 10 μm or less and is preferably 8 μm or less and more preferably 5 μm or less. By reducing the thickness of the polarizer, not only the display device can be made thinner, but also the moisture content can be further reduced and therefore the thermal durability of the display device can be improved. In addition, the thickness of the polyvinyl alcohol-based resin layer is preferably 1 μm or more, in order to obtain the absorbance required as the polarizer.

In addition, as described in WO2017/195833A and JP2017-83843A, a coating type polarizer prepared by using and coating a liquid crystal compound and a dichroic organic coloring agent (for example, a dichroic azo coloring agent used for a light-absorbing anisotropic film described in WO2017/195833A) without using a polyvinyl alcohol as a binder is also preferable as the polarizer.

Since this coating type polarizer does not require a polyvinyl alcohol-based resin layer, it is possible to further reduce the moisture content as compared with the PVA polarizer and therefore it is possible to further improve the thermal durability of the display device.

The liquid crystal compound preferably has a polymerizable group from the viewpoint of film hardness, and the solid content ratio with respect to the coating composition is preferably 50% by mass or more.

In addition, in a case where the liquid crystal compound exhibits smectic properties, it is preferable from the viewpoint of increasing the alignment degree.

The thickness of the coating type polarizer is preferably 0.1 to 3 μm, more preferably 0.3 to 2 μm, and still more preferably 0.3 to 1 μm. The display device can be made thinner by reducing the thickness of the polarizer. In addition, it is also preferable to laminate and coat the optically anisotropic layer and the coating type polarizer, and to coat the optically anisotropic layer and the coating type polarizer on both surfaces of the same support, from the viewpoint of omitting a pressure-sensitive adhesive layer, and achieving thickness reduction and improved production efficiency.

The coating type polarizer has excellent durability even with a high transmittance as compared with the PVA polarizer, which is advantageous for power saving, and the luminosity corrected single body transmittance of the polarizer is preferably 47% or more and more preferably 50% or more.

In addition, the relationship between the transmission axis of the polarizer and the slow axis of the optically anisotropic layer in the circularly polarizing plate is not particularly limited.

In a case where the polarizing plate is applied to antireflection applications, it is preferable that the optically anisotropic layer is a λ/4 plate and the angle formed by the transmission axis of the polarizer and the slow axis of the optically anisotropic layer is in a range of 45°±10° (35° to 55°).

<Silicon Nitride Layer>

The organic electroluminescent display device according to the embodiment of the present invention has a silicon nitride layer between the circularly polarizing plate consisting of an optically anisotropic layer and a polarizer and the organic electroluminescent element. Since the organic electroluminescent element is sensitive to the influence of moisture and oxygen, a silicon nitride layer is used as a barrier layer (low moisture permeability substrate) that blocks moisture and oxygen.

The moisture permeability of the silicon nitride layer needs to be 1 g/m²·day or less and is preferably 10⁻³ g/m²·day or less. Above all, from the viewpoint of the durability of the organic electroluminescent display element, the moisture permeability of the silicon nitride layer is more preferably 10⁻⁴ g/m²·day or less and still more preferably 10⁻⁵ g/m²·day or less. The lower limit of the moisture permeability of the silicon nitride layer is not particularly limited, and is often 10⁻¹⁰ g/m²·day or more.

Here, the term “moisture permeability” refers to an amount (g/m²·day) of water vapor that has passed for 24 hours under the conditions of a temperature of 40° C. and a relative humidity of 90%, according to the method described in JIS Z 0208: 1976 “Test method for moisture permeability of moisture-proof packaging material (cup method)”

The method for measuring the moisture permeability of the substrate is as follows. The moisture permeability of the substrate measured using a water vapor transmission rate measuring device (AQUATRAN 2 (registered trademark) manufactured by MOCON, Inc.) under the conditions of a measurement temperature of 40° C. and a relative humidity of 90%.

The thickness of the silicon nitride layer is preferably 10 nm or more and more preferably 20 nm or more, from the viewpoint of gas barrier ability. The thickness of the silicon nitride layer is preferably 150 nm or less and more preferably 80 nm or less, from the viewpoint of preventing breakage of a film.

The silicon nitride layer preferably contains a silicon atom, a nitrogen atom, and a hydrogen atom. Specifically, the silicon nitride layer more preferably contains SiNH (element ratio of Si:N:H=1:1:1).

Any conventionally known method can be used as the method for forming the silicon nitride layer. For example, a sputtering method, a vacuum vapor deposition method, an ion plating method, a plasma chemical vapor deposition (CVD) method, or the like is suitable. Specifically, the forming method described in each of JP3400324B, JP2002-322561A, and JP2002-361774A can be adopted.

The silicon nitride layer may generate ammonia gas due to a hydrolysis reaction. The hydrolysis reaction is promoted in the following cases, and the effect of the present invention is significantly exhibited.

The silicon nitride layer has a peak of Si—N bond located at 800 to 900 cm⁻¹ (peak (peak intensity) of absorption due to stretching vibration of Si—N), a peak of Si—H bond located at 2100 to 2200 cm⁻¹ (peak of absorption due to stretching vibration of Si—H), and a peak of N—H bond located at 3300 to 3400 cm⁻¹ (peak of absorption due to stretching vibration of NH), as measured by FT-IR (Fourier-transform infrared spectroscopy). From the viewpoint that the effect of the present invention is more significantly exhibited, N—H/Si—N, which is an intensity ratio of the peak of N—H bond to the peak of Si—N bond, is preferably 0.04 or more, more preferably 0.06 or more, still more preferably 0.08 or more, and most preferably 0.10 or more. From the viewpoint of the barrier ability of the film, the N—H/Si—N is preferably 0.3 or less, more preferably 0.2 or less, and still more preferably 0.15 or less.

In addition, regarding a film density of the silicon nitride layer, the film density [g/cm³] can be measured by an X-ray reflectivity measurement method using a thin film X-ray diffractometer (ATX-E, manufactured by Rigaku Corporation). The film density is preferably 2.4 g/cm³ or less and more preferably 2.3 g/cm³ or less, from the viewpoint that the effect of the present invention is more significantly exhibited. The film density is preferably 1.8 g/cm³ or more, more preferably 2.0 g/cm³ or more, and still more preferably 2.2 g/cm³ or more, from the viewpoint of the barrier ability of the film.

<Low Moisture Permeability Substrate>

In the organic electroluminescent display device according to the embodiment of the present invention, the circularly polarizing plate consisting of an optically anisotropic layer and a polarizer is disposed between two low moisture permeability substrates.

Here, the moisture permeability of the two low moisture permeability substrates is 1 g/m²·day or less, one of the low moisture permeability substrates is the above-mentioned silicon nitride layer, and the other is a low moisture permeability substrate provided on the visual recognition side of the circularly polarizing plate.

The moisture permeability of the low moisture permeability substrate is preferably 101 g/m²·day or less from the viewpoint that the effect of the present invention is more significantly exhibited.

The material constituting the low moisture permeability substrate on the visual recognition side is not particularly limited, and may be an inorganic substance or an organic substance. Examples of the substrate include a glass substrate and a metal oxide film. More specific examples of the substrate include a glass substrate such as a surface cover glass, and a multilayer sputtered metal oxide film used for antireflection.

The substrate may have a monolayer structure or a polylayer structure.

The substrate is preferably transparent, and is preferably a so-called transparent substrate.

In the present specification, “transparent” refers to having a visible light transmittance of 60% or more, which is preferably 80% or more and more preferably 90% or more. The upper limit of the visible light transmittance is not particularly limited, and is often less than 100%.

The thickness of the substrate is not particularly limited and is preferably 800 μm or less and more preferably 100 μm or less from the viewpoint of thinning. The lower limit of the thickness of the substrate is not particularly limited, and is preferably 0.1 μm or more.

For example, a bendable glass substrate having a thickness of 100 μm or less makes it possible to take advantage of the flexible characteristics of an organic electroluminescent display device, which is thus preferable.

Further, for a glass substrate having a thickness of 100 μm or less, it is also preferable to bond a resin film of a (meth)acrylic resin, a polyester-based resin such as polyethylene terephthalate (PET), a cellulose-based resin such as triacetyl cellulose (TAC), or a cycloolefin-based resin such as a norbornene-based resin, as a protective film, to the glass substrate with an adhesive or the like, from the viewpoint of impact resistance. In particular, from the viewpoint of flexibility, polyethylene terephthalate (PET) is preferably bonded, and from the viewpoint of visibility, polyethylene terephthalate (PET) having an Re of 3,000 nm or more and 10,000 nm or less is preferable.

The multilayer sputtered metal oxide film used for low antireflection is usually 1 μm or less in many cases.

<Other Layers>

The organic electroluminescent display device according to the embodiment of the present invention may have other members other than the optically anisotropic layer, the polarizer, and the low moisture permeability substrate (silicon nitride layer) described above.

(Support)

Although the organic electroluminescent display device according to the embodiment of the present invention may have a support for supporting the optically anisotropic layer or the coating type polarizer, it is also preferable to peel off the support for thinning.

The support is preferably transparent. Specifically, the support preferably has a light transmittance of 80% or more.

The support may be, for example, a polymer film.

Examples of the polymer film material include cellulose-based polymers; (meth)acrylic polymers having an acrylic acid ester polymer such as polymethylmethacrylate and a lactone ring-containing polymer; thermoplastic norbornene-based polymers; polycarbonate-based polymers; polyester-based polymers such as polyethylene terephthalate and polyethylene naphthalate; styrene-based polymers such as polystyrene and acrylonitrile-styrene copolymer (AS resin); polyolefin-based polymers such as polyethylene, polypropylene, and ethylene-propylene copolymer; vinyl chloride-based polymers; amide-based polymers such as nylon and aromatic polyamide; imide-based polymers; sulfone-based polymers; polyether sulfone-based polymers; polyether ether ketone-based polymers; polyphenylene sulfide-based polymers; vinylidene chloride-based polymers; vinyl alcohol-based polymers; vinyl butyral-based polymers; arylate-based polymers; polyoxymethylene-based polymers; epoxy-based polymers; and polymers in which these polymers are mixed.

In addition, it may be an aspect in which the above-mentioned polarizer also serves as such a support.

The thickness of the support is not particularly limited, and is preferably 5 to 80 μm and more preferably 10 to 40 μm.

(Alignment Film)

Although the organic electroluminescent display device according to the embodiment of the present invention preferably has an alignment film in order to promote the alignment of the optically anisotropic layer and the coating type polarizer, it is also preferable to peel off the alignment film for thinning. It may be an aspect in which the above-mentioned support also serves as the alignment film.

In order to form the positive A plate which is one aspect of the optically anisotropic layer, a technique for bringing a molecule of a specific liquid crystal compound into a desired alignment state is used. For example, a technique for aligning a specific liquid crystal compound in a desired direction by using an alignment film is common.

Examples of the alignment film include a rubbing-treated film of a layer containing an organic compound such as a polymer, an oblique vapor-deposited film of an inorganic compound, a film having microgrooves, and a film in which a Langmuir-Blodgett (LB) film obtained by the LB method of an organic compound such as w-tricosanoic acid, dioctadecylmethylammonium chloride, or methyl stearate is accumulated.

Further, the alignment film is also preferably a photo-alignment film in which an alignment function is generated upon irradiation with light.

A film formed by subjecting the surface of a layer containing an organic compound such as a polymer (polymer layer) to a rubbing treatment can be preferably used as the alignment film. The rubbing treatment is carried out by rubbing the surface of the polymer layer with paper or cloth several times in a certain direction (preferably in the longitudinal direction of the support). Preferred examples of the polymer used for forming the alignment film include polyimides, polyvinyl alcohols, the modified polyvinyl alcohols described in paragraphs [0071] to [0095] of JP3907735B, and the polymers having a polymerizable group described in JP1997-152509A (JP-H09-152509A).

The thickness of the alignment film is not particularly limited as long as it can exhibit the alignment function, and is preferably 0.01 to 5 μm and more preferably 0.05 to 2 μm.

As the alignment film, it is also preferable to use a so-called photo-alignment film (photo-alignment layer) in which a photo-alignment material is irradiated with polarized light or non-polarized light to form an alignment layer.

It is preferable to apply an alignment regulating force to the photo-alignment film by a step of irradiating the photo-alignment film with polarized light from a vertical direction or an oblique direction or a step of irradiating the photo-alignment film with non-polarized light from an oblique direction.

Using the photo-alignment film makes it possible to bring the specific liquid crystal compound into horizontal alignment with excellent symmetry. Therefore, the positive A plate formed by using the photo-alignment film is particularly useful for optical compensation in a liquid crystal display device that does not require a pre-tilt angle of a driving liquid crystal, such as an in-plane switching (IPS) mode liquid crystal display device.

Examples of the photo-alignment material used for the photo-alignment film include the azo compounds described in JP2006-285197A, JP2007-076839A, JP2007-138138A, JP2007-094071A, JP2007-121721A, JP2007-140465A, JP2007-156439A, JP2007-133184A, JP2009-109831A, JP3883848B, and JP4151746B; aromatic ester compounds described in JP2002-229039A; maleimide and/or alkenyl-substituted nadiimide compounds having a photo-alignment unit described in JP2002-265541A and JP2002-317013A; photocrosslinkable silane derivatives described in JP4205195B and JP4205198B; photocrosslinkable polyimides, polyamides, or esters described in JP2003-520878A, JP2004-529220A, and JP4162850B; and photodimerizable compounds, particularly cinnamate compounds, chalcone compounds, and coumarin compounds described in JP1997-118717A (JP-H09-118717A), JP1998-506420A (JP-H10-506420A), JP2003-505561A, WO2010/150748A, JP2013-177561A, and JP2014-12823A.

Particularly preferred examples of the photo-alignment material include azo compounds, photocrosslinkable polyimides, polyamides, polyesters, cinnamate compounds, and chalcone compounds.

The thickness of the alignment film is not particularly limited, and is preferably 0.01 to 10 μm, more preferably 0.01 to 1 μm, and still more preferably 0.01 to 0.5 μm, from the viewpoint of alleviating the surface irregularities that may exist on the support to form an optically anisotropic layer having a uniform film thickness.

(Trap Layer)

The organic electroluminescent display device according to the embodiment of the present invention may have a base trap layer containing a compound having a carboxylic acid group for the purpose of trapping ammonia.

It is also possible to include a compound having a carboxylic acid group in a pressure-sensitive adhesive layer and a barrier layer or a layer such as a positive C plate to form a base trap layer.

(Polarizer Protective Film)

The organic electroluminescent display device according to the embodiment of the present invention may have a polarizer protective film on the surface of the polarizer.

The polarizer protective film may be disposed only on one surface of the polarizer (on the surface opposite to the optically anisotropic layer side), or may be disposed on both surfaces of the polarizer.

The configuration of the polarizer protective film is not particularly limited, and may be, for example, a so-called transparent support or hard coat layer, or a laminate of the transparent support and the hard coat layer.

A known layer can be used as the hard coat layer, and for example, a layer obtained by polymerizing and curing a polyfunctional monomer may be used.

In addition, a known transparent support can be used as the transparent support. Examples of the material for forming the transparent support include a cellulose-based polymer (hereinafter, referred to as “cellulose acylate”) represented by triacetyl cellulose, a norbornene-based resin (ZEONEX or ZEONOR manufactured by Zeon Corporation; or ARTON manufactured by JSR Corporation), an acrylic resin, a polyester-based resin, and a polystyrene-based resin. A resin that is difficult to contain water, such as an acrylic resin, a thermoplastic norbornene-based resin, and a polystyrene-based resin, is preferable for suppressing the total moisture content of the polarizing plate, and a norbornene-based resin is particularly preferable.

The resin has an equilibrium moisture content at 25° C. and 80% RH of preferably 2% or less, more preferably 0.5% or less, and still more preferably 0.2% or less.

The thickness of the polarizer protective film is not particularly limited, and is preferably 40 μm or less, more preferably 25 μm or less, still more preferably 10 μm or less, and particularly preferably 5 μm or less, from the viewpoint that the thickness of the polarizing plate can be reduced. The lower limit of the thickness of the polarizer protective film is not particularly limited, and is often 1 μm or more.

A pressure-sensitive adhesive layer or an adhesive layer may be disposed between the layers to ensure the adhesiveness therebetween. Further, a transparent support may be disposed between the layers.

The polarizing plate may have another optically anisotropic layer other than the optically anisotropic layer formed of the above-mentioned polymerizable liquid crystal composition containing a specific liquid crystal compound.

The other optically anisotropic layer may be an A plate or a C plate.

The moisture content of the polarizing plate is not particularly limited, and is preferably 5.0 g/m² or less, more preferably 3.0 g/m² or less, still more preferably 1.5 g/m² or less, and particularly preferably 0.8 g/m² or less.

(Touch Sensor)

There are two types of touch sensors: an on-cell type in which metal mesh electrodes are formed directly on a silicon nitride layer that barriers an organic electroluminescent element, and an out-cell type in which a film sensor with electrodes formed on a film is externally attached, any one of which may be selected. The on-cell type is preferable from the viewpoint of thinning and from the viewpoint that the effect of the present invention is significantly exhibited.

(Pressure-Sensitive Adhesive Layer)

The organic electroluminescent display device according to the embodiment of the present invention may have a pressure-sensitive adhesive layer.

Examples of the pressure sensitive adhesive contained in the pressure-sensitive adhesive layer include a rubber-based pressure sensitive adhesive, an acrylic pressure sensitive adhesive, a silicone-based pressure sensitive adhesive, an urethane-based pressure sensitive adhesive, a vinyl alkyl ether-based pressure sensitive adhesive, a polyvinyl alcohol-based pressure sensitive adhesive, a polyvinyl pyrrolidone-based pressure sensitive adhesive, a polyacrylamide-based pressure sensitive adhesive, and a cellulose-based pressure sensitive adhesive.

Of these, an acrylic pressure sensitive adhesive (pressure sensitive adhesive) is preferable from the viewpoint of transparency, weather fastness, heat resistance, and the like.

The pressure-sensitive adhesive layer can be formed by, for example, a method in which a solution of a pressure sensitive adhesive is coated and dried on a release sheet, and then transferred to a surface of a transparent resin layer; or a method in which a solution of a pressure sensitive adhesive is directly coated and dried on a surface of a transparent resin layer.

The solution of a pressure sensitive adhesive is prepared as a solution of about 10% to 40% by mass of the pressure sensitive adhesive in which the pressure sensitive adhesive is dissolved or dispersed in a solvent such as toluene or ethyl acetate.

For example, a roll coating method such as reverse coating or gravure coating, a spin coating method, a screen coating method, a fountain coating method, a dipping method, or a spray method can be adopted as the coating method.

In addition, examples of the constituent material of the release sheet include appropriate thin sheet bodies, for example, a synthetic resin film such as polyethylene, polypropylene, or polyethylene terephthalate; a rubber sheet; paper; cloth; a nonwoven fabric; a network; a foamed sheet; and a metal foil.

In the present invention, the thickness of the optional pressure-sensitive adhesive layer is not particularly limited, and is preferably 3 μm to 50 μm, more preferably 4 μm to 40 μm, and still more preferably 5 μm to 30 μm.

(Adhesive Layer)

The organic electroluminescent display device according to the embodiment of the present invention may have an adhesive layer.

The adhesive is not particularly limited as long as it develops adhesiveness by drying or reaction after bonding.

A polyvinyl alcohol-based adhesive (PVA-based adhesive) develops adhesiveness by drying, and makes it possible to bond the materials together.

Specific examples of the curable adhesive that develops adhesiveness by the reaction include an active energy ray-curable adhesive such as a (meth)acrylate-based adhesive and a cationic polymerization curable adhesive. Examples of the curable component in the (meth)acrylate-based adhesive include a compound having a (meth)acryloyl group and a compound having a vinyl group.

In addition, a compound having an epoxy group or an oxetanyl group can also be used as the cationic polymerization curable adhesive. The compound having an epoxy group is not particularly limited as long as it is a compound having at least two epoxy groups in a molecule thereof, and various generally known curable epoxy compounds can be used. Preferred examples of the epoxy compound include a compound having at least two epoxy groups and at least one aromatic ring in a molecule thereof (aromatic epoxy compound), and a compound having at least two epoxy groups in a molecule thereof, at least one of which being formed between two adjacent carbon atoms constituting an alicyclic ring (alicyclic epoxy compound).

(Functional Layer)

It is preferable to have a functional layer having a function of reducing short wavelength light on the visual recognition side of the optically anisotropic layer. By reducing short wavelength light, it is possible to provide an organic electroluminescent display device which suppresses photodecomposition of a coloring agent compound and has excellent light resistance.

As one aspect, it is preferable that the above-mentioned pressure-sensitive adhesive layer, support, polarizer protective film, and the like have a function of reducing short wavelength light.

As another aspect, it is also preferable to newly provide a layer having a function of reducing short wavelength light on the visual recognition side of the optically anisotropic layer.

The method for reducing short wavelength light is not particularly limited, and examples thereof include a method using light absorption by an absorbent or the like and a method using wavelength selective reflection by a multilayer film.

The above-mentioned short wavelength light refers to light having a wavelength of 430 nm or less. By reducing the light having a wavelength of 430 nm or less, it is possible to suppress the photodecomposition of a liquid crystal compound by sunlight or the light source light used in the light resistance test of JIS B 7751 and JIS B 7754.

In addition, the functional layer is preferably transparent in a wavelength range of 450 nm or more so as not to affect the performance of a polarizer in visible light.

The transmittance is preferably 0.1% or less in a wavelength range of 350 to 390 nm, 20% to 70% at a wavelength of 410 nm, and 90% or more in a wavelength range of 450 nm or more.

The transmittance at a wavelength of 410 nm is more preferably 40% to 50%.

The merocyanine compound described in JP2017-119700A and WO2018/123267A is preferably used as the compound that absorbs short wavelength light.

In addition, it is also preferable to use a conventionally known ultraviolet absorber in combination. Examples of the ultraviolet absorber include organic ultraviolet absorbers such as an oxybenzophenone-based ultraviolet absorber, a benzotriazole-based ultraviolet absorber, a salicylate ester-based ultraviolet absorber, a benzophenone-based ultraviolet absorber, a cyanoacrylate-based ultraviolet absorber, and a triazine-based ultraviolet absorber.

(Layer Configuration)

In the organic electroluminescent display device according to the embodiment of the present invention, the presence of a pressure-sensitive adhesive layer between the circularly polarizing plate and the silicon nitride layer is one of the preferred aspects, but another layer, for example, a metal mesh electrode may also be provided.

The moisture permeability of the layer present between the circularly polarizing plate and the silicon nitride layer (in a case where there are a plurality of layers, it means a total moisture permeability of the plurality of layers; the same applies hereinafter) is preferably 100 g/m²·day or more, from the viewpoint that the effect of the present invention is significantly exhibited. In other words, it is preferable not to have a layer having a moisture permeability of less than 100 g/m²·day between the circularly polarizing plate and the silicon nitride layer.

Similarly, the thickness of the layer present between the circularly polarizing plate and the silicon nitride layer is preferably less than 40 μm and more preferably 1 to 30 μm, from the viewpoint that the effect of the present invention is significantly exhibited.

### EXAMPLES

Hereinafter, the present invention will be described in more detail with reference to Examples. The materials, amounts used, proportions, treatment details, treatment procedure, and the like shown in the following Examples can be appropriately changed without departing from the spirit and scope of the present invention. Accordingly, the scope of the present invention should not be construed as being limited to the Examples given below.

(Preparation of PVA Adhesive)

20 parts of methylol melamine was dissolved in pure water under a temperature condition of 30° C. with respect to 100 parts of a polyvinyl alcohol-based resin containing an acetoacetyl group (average degree of polymerization: 1200, saponification degree: 98.5 mol %, acetoacetylation degree: 5 mol %) to prepare an aqueous solution adjusted to a concentration of solid contents of 3.7%.

<Preparation of Polarizer 1 with Protective Film on One Surface Thereof>

The surface of a support of a cellulose triacetate film TJ25 (manufactured by Fujifilm Corporation, thickness: 25 μm) was subjected to an alkali saponification treatment. Specifically, the support was immersed in a 1.5 N sodium hydroxide aqueous solution at 55° C. for 2 minutes, washed in a water bath at room temperature, and further neutralized with 0.1 N sulfuric acid at 30° C. After neutralization, the support was washed in a water bath at room temperature and further dried with hot air at 100° C. to obtain a polarizer protective film 1 (equilibrium moisture content at 25° C. and 80% RH: 3.4%).

A polyvinyl alcohol film having a thickness of 75 μm was stretched in an iodine aqueous solution in a machine direction (MD) and dried to obtain a polarizer 1 having a thickness of 20 μm.

The polarizer protective film 1 was bonded to one surface of the polarizer 1 using the PVA adhesive to prepare a polarizer 1 with a protective film on one surface thereof.

<Preparation of Polarizer 2 with Protective Film on One Surface Thereof>

A polarizer protective film 1 was obtained according to the same procedure as in the section of <Preparation of polarizer 1 with protective film on one surface thereof>.

A polarizer (polarizing film) having a thickness of 9 μm was obtained in the same manner as in the section of <Preparation of polarizer 1 with protective film on one surface thereof>, except that the thickness and stretching ratio of the polyvinyl alcohol film were adjusted.

The polarizer protective film 1 was bonded to one surface of the obtained polarizer using the PVA adhesive to prepare a polarizer 2 with a protective film on one surface thereof.

<Preparation of Polarizer 3 with Protective Film on One Surface Thereof>

A laminated film (substrate film/primer layer/polarizer) containing a polyvinyl alcohol-based polarizer having a thickness of 4 μm was obtained with reference to the description of Example 1 of JP2017-194710A. Next, the polarizer protective film 1 prepared in section of <Preparation of polarizer 1 with protective film on one surface thereof> was bonded onto the polarizer using the PVA adhesive, and the substrate film and the primer layer were peeled off from the obtained laminated film to prepare a polarizer 3 with a protective film on one surface thereof.

<Preparation of Polarizer 4 Using Dichroic Coloring Agent>

A composition E1 for forming a photo-alignment layer was prepared with the following composition, dissolved for 1 hour with stirring, and filtered through a 0.45 μm filter.

Composition E1 for forming a photo-alignment layer

| | |
|---|---|
| Photoactive compound E-4 shown below | 5.0 parts by mass |
| Cyclopentanone | 95.0 parts by mass |

Photoactive compound E-4 (weight-average molecular weight: 51,000)

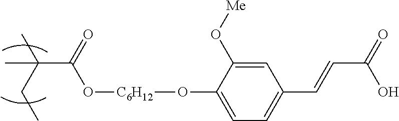

A composition P1 for forming a light absorption anisotropic layer was prepared with the following composition, dissolved by heating at 80° C. for 2 hours with stirring, and filtered through a 0.45 μm filter.

Composition P1 for forming a light absorption anisotropic layer

| | | |
|---|---|---|
| Dichroic coloring agent D1 shown below | 2.7 | parts by mass |
| Dichroic coloring agent D2 shown below | 2.7 | parts by mass |
| Dichroic coloring agent D3 shown below | 2.7 | parts by mass |
| Liquid crystal compound M1 shown below | 73.0 | parts by mass |
| Polymerization initiator IRGACURE 369 (manufactured by BASF SE) | 3.0 | parts by mass |
| BYK361N (manufactured by BYK-Chemie Japan KK) | 0.9 | parts by mass |
| Cyclopentanone | 925.0 | parts by mass |

Dichroic coloring agent D1 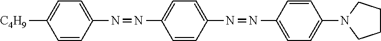
Dichroic coloring agent D2 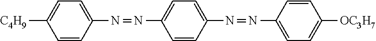
Dichroic coloring agent D3 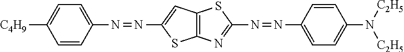
Liquid crystal compound M1 (a mixture of the following compound A/the following compound B = 75/25)
(Compound A) 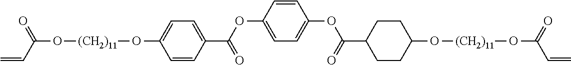
(Compound B)

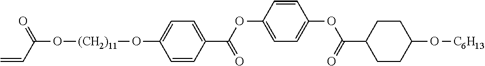

The composition E1 for forming a photo-alignment laver was coated on a cellulose triacetate film TJ40 (manufactured by Fujifilm Corporation, thickness: 40 μm) and dried at 60° C. for 2 minutes. Then, the obtained coating film was irradiated with linearly polarized ultraviolet rays (100 mJ/cm²) using a polarized ultraviolet exposure device to prepare a photo-alignment layer E1.

The composition P1 for forming a light absorption anisotropic layer was coated on the obtained photo-alignment layer E1 with a wire bar. Next, the obtained coating film was heated at 120° C. for 60 seconds and cooled to room temperature.

Then, a light absorption anisotropic layer P1 having a thickness of 1.7 μm was formed by irradiation with ultraviolet rays at an exposure amount of 2,000 mJ/cm² using a high-pressure mercury lamp.

It was confirmed that the liquid crystal of the light absorption anisotropic layer exhibited a smectic B phase.

(Formation of Protective Layer)

A solution (composition for forming a protective layer), which was prepared by dissolving dipentaerythritol hexaacrylate (ARONIX M-403, manufactured by Toagosei Co., Ltd.) (50 parts by mass), an acrylate resin (EBECRYL 4858, manufactured by Daicel-UCB Co., Ltd.) (50 parts by mass), and 2-[4-(methylthio)benzoyl]-2-(4-morpholinyl)propane (IRGACURE 907, manufactured by BASF SE) (3 parts by mass) in isopropanol (250 parts by mass), was coated on the formed light absorption anisotropic layer P1 by a bar coating method, and heated and dried in a drying oven at 50° C. for 1 minute.

The obtained coating film was irradiated with ultraviolet rays using an ultraviolet (UV) irradiation device (SPOT CURE SP-7, manufactured by Ushio Inc.) at an exposure amount of 400 mJ/cm² (365 nm standard) to form a protective layer (3 μm) on the light absorption anisotropic layer P1 to prepare a polarizing film 4 containing the light absorption anisotropic layer P1.

<Preparation of Polarizer 5 Using Dichroic Coloring Agent>

A coating liquid PA1 for forming an alignment layer, which will be described later, was continuously coated on a cellulose triacetate film TJ40 (manufactured by Fujifilm Corporation, thickness: 40 μm) with a wire bar. The support on which the coating film was formed was dried with hot air at 140° C. for 120 seconds, and then the coating film was irradiated with polarized ultraviolet rays (10 mJ/cm², using an ultra-high pressure mercury lamp) to form a photo-alignment layer PA1, thereby obtaining a TAC film with the photo-alignment layer PA1.

The film thickness of the photo-alignment layer PA1 was 1.0 μm.

Coating liquid PA1 for forming an alignment layer

| | | |
|---|---|---|
| Polymer PA-1 shown below | 100.00 | parts by mass |
| Acid generator PAG-1 shown below | 5.00 | parts by mass |
| Acid generator CPI-110TF shown below | 0.005 | parts by mass |
| Xylene | 1220.00 | parts by mass |
| Methyl isobutyl ketone | 122.00 | parts by mass |

Polymer PA-1 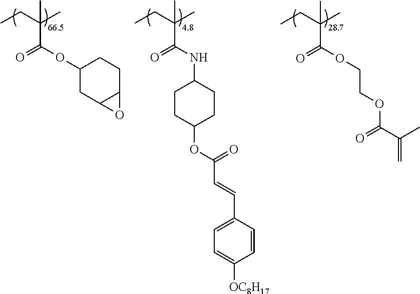
Acid generator PAG-1 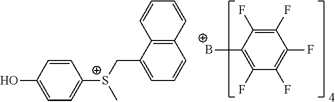
Acid generator CPI -110F

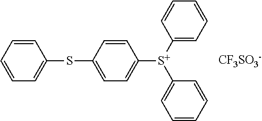

The following composition P2 for forming a light absorption anisotropic layer was continuously coated on the obtained photo-alignment layer PA1 with a wire bar to form a coating film P2.

Next, the coating film P2 was heated at 140° C. for 30 seconds, and then the coating film P2 was cooled to room temperature (23° C.).

Next, the obtained coating film P2 was heated at 90° C. for 60 seconds and cooled again to room temperature.

Then, a light absorption anisotropic layer P2 was prepared on the photo-alignment layer PA1 by irradiating with a light emitting diode (LED) lamp (central wavelength: 365 nm) for 2 seconds under an irradiation condition of an illuminance of 200 mW/cm².

The film thickness of the light absorption anisotropic layer P2 was 0.4 μm.

Composition P2 for forming a light absorption anisotropic layer

| | | |
|---|---|---|
| Dichroic coloring agent D-4 shown below | 0.36 | parts by mass |
| Dichroic coloring agent D-5 shown below | 0.53 | parts by mass |
| Dichroic coloring agent D-6 shown below | 0.31 | parts by mass |
| High molecular weight liquid crystal compound P-1 shown below | 3.58 | parts by mass |
| Polymerization initiator | 0.050 | parts by mass |
| IRGACURE OXE-02 (manufactured by BASF SE) | | |
| Surfactant F-1 shown below | 0.026 | parts by mass |
| Cyclopentanone | 45.00 | parts by mass |
| Tetrahydrafuran | 45.00 | parts by mass |
| Benzyl alcohol | 5.00 | parts by mass |

Dichroic coloring agent D-4 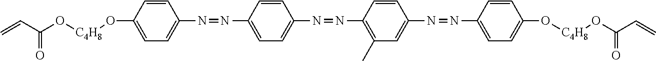
Dichroic coloring agent D-5 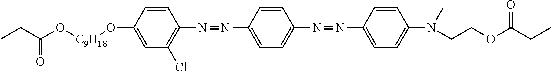
Dichroic coloring agent D-6 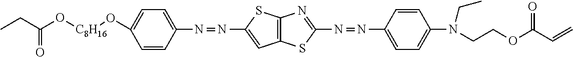
High molecular weight liquid crystal compound P-1 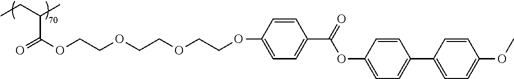 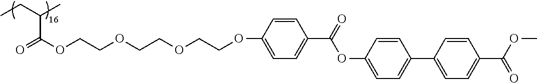 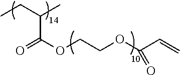
Surfactant F-1

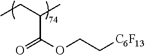

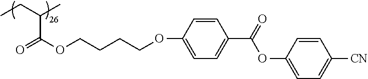

The following composition N1 for forming a cured layer was continuously coated on the obtained light absorption anisotropic layer P2 with a wire bar to form a coating film.

Next, the coating film was dried at room temperature, and then irradiated for 15 seconds under an irradiation condition of an illuminance of 28 mW/cm² using a high-pressure mercury lamp to prepare a cured layer N1 on the light absorption anisotropic layer P2.

The film thickness of the cured layer N1 was 0.05 μm.

Composition N1 for forming a cured layer

| | | |
|---|---|---|
| Mixture L1 of rod-like liquid crystal compounds shown below | 2.61 | parts by mass |
| Modified trimethylolpropane triacrylate shown below | 0.11 | parts by mass |
| Photopolymerization initiator I-1 shown below | 0.05 | parts by mass |
| Surfactant F-3 shown below | 0.21 | parts by mass |
| Methyl isobutyl ketone | 297 | parts by mass |

Mixture L1 of rod-like liquid crystal compounds (The numerical value in the following formulae represents % by mass, and R represents a group bonded through an oxygen atom.) 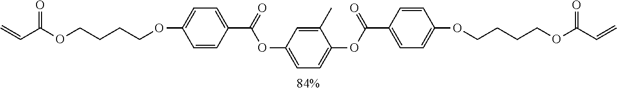 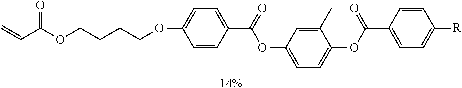 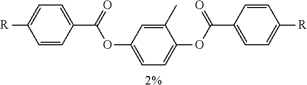 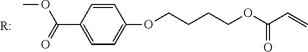
Modified trimethylolpropane triacrylate 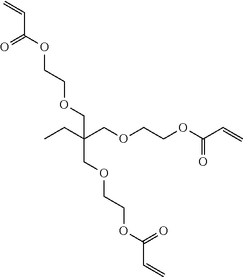 [SMILES: C=CC(=O)OCCOCC(CC)(COCCOC(=O)C=C)COCCOC(=O)C=C]
Photopolymerization initiator I-1 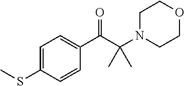 [SMILES: CSc1ccc(C(=O)C(C)(C)N2CCOCC2)cc1]
Surfactant F-3

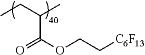

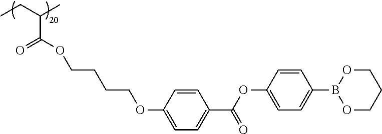

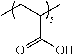

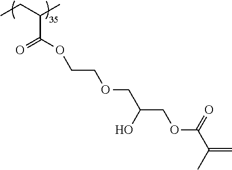

The following composition B1 for forming an oxygen blocking layer was continuously coated on the cured layer N1 with a wire bar. This was followed by drying with hot air at 100° C. for 2 minutes to form an oxygen blocking layer having a thickness of 1.0 μm on the cured layer N1 to prepare a polarizing film 5 including a light absorption anisotropic layer P2.

The luminosity corrected single body transmittance of the polarizer was 49%.

Composition B1 for forming an oxygen blocking layer

| | | |
|---|---|---|
| Modified polyvinyl alcohol shown below | 3.80 | parts by mass |
| Initiator Irg2959 | 0.20 | parts by mass |
| Water | 70 | parts by mass |
| Methanol | 30 | parts by mass |

Modified polyvinyl alcohol

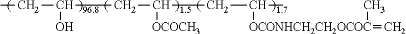

<Preparation of Polarizer 6 with Protective Film on One Surface Thereof>

A polarizer having a thickness of 9 μm was obtained according to the same procedure as in the section of <Preparation of polarizer 2 with protective film on one surface thereof>.

Next, a corona-treated methacrylic resin (PMMA) film (thickness: 25 μm, equilibrium moisture content at 25° C. and 80% RH: 1.3%) was bonded to one surface of the above-mentioned polarizer with the following UV adhesive to prepare a polarizer 6 with a protective film on one surface thereof.

(Preparation of UV Adhesive)

The following UV adhesive composition was prepared.

UV adhesive composition

| | | |
|---|---|---|
| CEL2021P (manufactured by Daicel Corporation) | 70 | parts by mass |
| 1,4-Butanediol diglycidyl ether | 20 | parts by mass |
| 2-Ethylhexyl glycidyl ether | 10 | parts by mass |
| CPI-100P | 2.25 | parts by mass |

CPI-100P

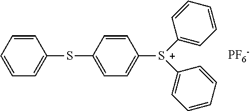

### Preparation Example 1

The following composition was put into a mixing tank and stirred to prepare a cellulose acetate solution to be used as a core layer cellulose acylate dope.

Core layer cellulose acylate dope

| | | |
|---|---|---|
| Cellulose acetate having an acetyl substitution | 100 | parts by mass |
| degree of 2.88 | | |
| Polyester compound B described in Examples of | 12 | parts by mass |
| JP2015-227955A | | |
| Compound G shown below | 2 | parts by mass |
| Methylene chloride (first solvent) | 430 | parts by mass |
| Methanol (second solvent) | 64 | parts by mass |

Compound G

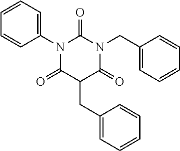 [SMILES: O=C1C(Cc2ccccc2)C(=O)N(c2ccccc2)C(=O)N1Cc1ccccc1]

10 parts by mass of the following matte agent solution were added to 90 parts by mass of the core layer cellulose acylate dope to prepare a cellulose acetate solution to be used as an outer layer cellulose acylate dope.

Matte agent solution

| | | |
|---|---|---|
| Silica particles having an average particle size of | 2 | parts by mass |
| 20 nm (AEROSIL R972, manufactured by Nippon | | |
| Aerosil Co., Ltd.) | | |
| Methylene chloride (first solvent) | 76 | parts by mass |
| Methanol (second solvent) | 11 | parts by mass |
| Core layer cellulose acylate dope described above | 1 | part by mass |

After filtering the core layer cellulose acylate dope and the outer layer cellulose acylate dope through a filter paper having an average pore size of 34 μm and a sintered metal filter having an average pore size of 10 m, the core layer cellulose acylate dope and the outer layer cellulose acylate dope on both sides thereof were simultaneously cast in three layers on a drum at 20° C. from a casting port (band casting machine). The film was peeled off from the drum with a solvent content of about 20% by mass, both ends of the film in a width direction were fixed with tenter clips, and the film was dried while being stretched in a transverse direction at a stretching ratio of 1.1 times. Then, the obtained film was transported between rolls of a heat treatment apparatus to be further dried to prepare a cellulose acylate film 1 having a thickness of 20 μm. In addition, the Re(550) of the obtained cellulose acylate film 1 was 0 nm. The equilibrium moisture content at 25° C. and 80% RH was 3.4%.

Next, with reference to the description of Example 3 of JP2012-155308A, a coating liquid 1 for a photo-alignment film was prepared and coated on the cellulose acylate film 1 with a wire bar. Then, the obtained cellulose acylate film 1 was dried with hot air at 60° C. for 60 seconds to prepare a coating film 1 having a thickness of 300 nm.

Subsequently, a composition A1 for forming a positive A plate having the following composition was prepared.

Composition of composition A1 for forming a positive A plate

| | | |
|---|---|---|
| Polymerizable liquid crystal compound X-1 shown below | 16.00 | parts by mass |
| Specific liquid crystal compound L-1 shown below | 42.00 | parts by mass |
| Specific liquid crystal compound L-2 shown below | 42.00 | parts by mass |
| Polymerization initiator S-1 shown below | 0.50 | parts by mass |
| Polymerizable compound B-1 shown below | 2.00 | parts by mass |
| Leveling agent (compound T-1 shown below) | 0.20 | parts by mass |
| Methyl ethyl ketone (solvent) | 230.00 | parts by mass |
| Cyclopentanone (solvent) | 70.00 | parts by mass |

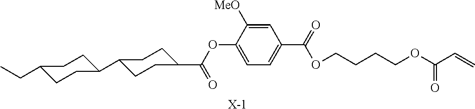

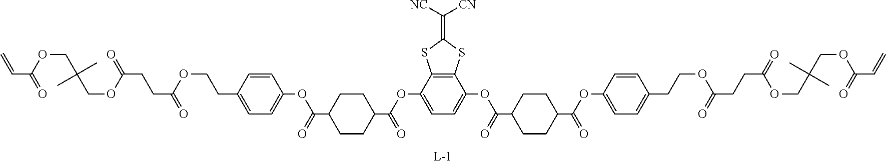 [SMILES: C=CC(=O)OCC(C)(C)COC(=O)CCC(=O)OCCc1ccc(OC(=O)C2CCC(C(=O)Oc3ccc(OC(=O)C4CCC(C(=O)Oc5ccc(CCOC(=O)CCC(=O)OCC(C)(C)COC(=O)C=C)cc5)CC4)c4c3SC(=C(C#N)C#N)S4)CC2)cc1]

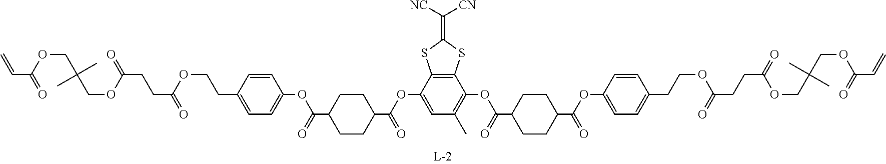 [SMILES: C=CC(=O)OCC(C)(C)COC(=O)CCC(=O)OCCc1ccc(OC(=O)C2CCC(C(=O)Oc3cc(C)c(OC(=O)C4CCC(C(=O)Oc5ccc(CCOC(=O)CCC(=O)OCC(C)(C)COC(=O)C=C)cc5)CC4)c4c3SC(=C(C#N)C#N)S4)CC2)cc1]

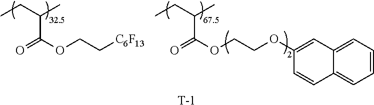

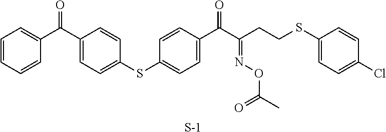

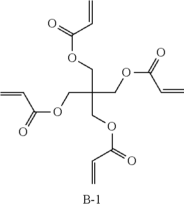

The prepared coating film 1 was irradiated with ultraviolet rays in the atmosphere using an ultra-high pressure mercury lamp. At this time, a wire grid polarizer (ProFlux PPL02, manufactured by Moxtek, Inc.) was set so as to be parallel to the surface of the coating film 1 which was then exposed to light for photo-alignment treatment to obtain a photo-alignment film 1.

At this time, the illuminance of ultraviolet rays was set to 10 mJ/cm² in an UV-A region (ultraviolet A wave, integration of wavelengths of 320 to 380 nm).

Next, the composition A1 for forming a positive A plate was coated on the photo-alignment film 1 using a bar coater. The obtained coating film was heat-aged at a film surface temperature of 100° C. for 20 seconds, cooled to 90° C., and then irradiated with ultraviolet rays of 300 mJ/cm² using an air-cooled metal halide lamp (manufactured by Eye Graphics Co., Ltd.) under air to immobilize a nematic alignment state to form a positive A plate A1 (corresponding to an optically anisotropic layer), thereby preparing an optical film 1 containing the positive A plate A1 (layer configuration: cellulose acylate film 1/photo-alignment film 1/positive A plate A1).

The formed positive A plate A1 had a film thickness of 2.5 μm. The positive A plate A1 had a Re(550) of 145 nm, a Rth(550) of 73 nm, a Re(550)/Re(450) of 1.13, a Re(650)/Re(550) of 1.01 and a tilt angle of an optical axis of 0°, and the liquid crystal compound had a homogeneous alignment.

Next, the surface of the optical film 1 on the cellulose acylate film 1 side was corona-treated, and then bonded to the polarizer surface of the polarizer 1 with a protective film on one surface thereof using a PVA adhesive to obtain a circularly polarizing plate 1 (layer configuration: polarizer protective film 1/polarizer 1/cellulose acylate film 1/photo-alignment film 1/positive A plate A1). At that time, the angle formed by the absorption axis of the polarizer and the slow axis of the positive A plate A1 was 45°.

(Preparation of Pressure Sensitive Adhesive)

A film with a pressure sensitive adhesive described below was obtained with reference to the description of Example 1 of JP2017-134414A.

Specifically, first, the following components were mixed at 55° C. in a nitrogen atmosphere to obtain an acrylic resin.

Butyl acrylate: 70 parts by mass

Methyl acrylate: 20 parts by mass

Acrylic acid: 1.0 parts by mass

Azobisisobutyronitrile: 0.2 parts by mass

Ethyl acetate: 80 parts by mass

CORONATE L (a 75% by mass ethyl acetate solution of a trimethylolpropane adduct of tolylene diisocyanate, the number of isocyanate groups in one molecule: 3, manufactured by Nippon Polyurethane Industry Co., Ltd.) (0.5 parts by mass) and a silane coupling agent X-12-981 (manufactured by Shin-Etsu Silicone Co., Ltd.) (0.5 parts by mass) in addition to the obtained acrylic resin (100 parts by mass) were mixed, and ethyl acetate was added such that the total concentration of solid contents was finally 10% by mass to prepare a composition for forming a pressure sensitive adhesive.

The obtained composition for forming a pressure sensitive adhesive was coated on the release-treated surface of a polyethylene terephthalate film subjected to a release treatment (manufactured by Lintec Corporation) using an applicator such that the thickness after drying was 15 μm, followed by drying at 100° C. for 1 minute to obtain a film with a pressure sensitive adhesive.

Coming Eagle XG glass was used as a glass substrate A (thickness: 1.1 mm).

In a case where the moisture permeability of the glass substrate A was measured using a water vapor transmission rate measuring device (AQUATRAN2 (registered trademark), manufactured by MOCON, Inc.) in an atmosphere of 40° C. and 90% RH, it was less than 1.0×10⁻³ g/m²·day.

Using the film with a pressure sensitive adhesive, the glass substrate A was bonded to the polarizer protective film surface of the circularly polarizing plate 1 to prepare a circularly polarizing plate 1 with a cover glass (layer configuration: glass substrate A/polarizer protective film 1/polarizer 1/cellulose acylate film 1/photo-alignment film 1/positive A plate A1). Specifically, the pressure sensitive adhesive of the film with a pressure sensitive adhesive was bonded to the surface of the polarizer protective film 1 of the circularly polarizing plate 1, the release-treated polyethylene terephthalate film in the film with a pressure sensitive adhesive was peeled off, and then the glass substrate A was further bonded to the pressure sensitive adhesive.

### Preparation Example 2

In the same manner as in Preparation Example 1, the surface of the optical film 1 on the cellulose acylate film 1 side was subjected to a corona treatment, and then bonded to the polarizer surface of the polarizer 2 with a protective film on one surface thereof using a PVA adhesive to obtain a circularly polarizing plate 2.

Further, a circularly polarizing plate 2 with a cover glass was prepared in the same manner as in Preparation Example 1.

### Preparation Example 3

In the same manner as in Preparation Example 1, the surface of the optical film 1 on the cellulose acylate film 1 side was subjected to a corona treatment, and then bonded to the polarizer surface of the polarizer 3 with a protective film on one surface thereof using a PVA adhesive to obtain a circularly polarizing plate 3.

Further, a circularly polarizing plate 3 with a cover glass was prepared in the same manner as in Preparation Example 1.

### Preparation Example 4

An optical film 1H was prepared in the same manner as in the optical film 1 of Preparation Example 1, except that the coating liquid 1 for a photo-alignment film was changed to a coating liquid 2 for a photo-alignment film described below.

(Coating liquid 2 for forming a photo-alignment film)

| | | |
|---|---|---|
| Polymer PA-1 shown below | 100.00 | parts by mass |
| Acid generator PAG-1 shown below | 1.00 | parts by mass |
| Isopropyl alcohol | 16.50 | parts by mass |
| Butyl acetate | 1072.00 | parts by mass |
| Methyl ethyl ketone | 268.00 | parts by mass |

Polymer PA-1 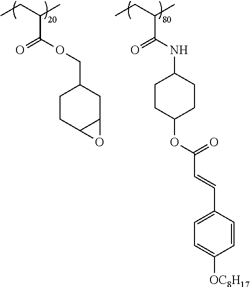
Acid generator PAG-1 (structural formula shown below)

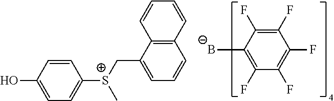

The surface of the polarizing film 4 on the protective layer side was bonded to the glass substrate A using the pressure sensitive adhesive. Next, the cellulose triacetate film TJ40 of the polarizing film 4 and the photo-alignment layer E1 were peeled off, and then the surface of the optically anisotropic layer of the optical film 1H was bonded to the peeled surface of the light absorption anisotropic layer using the UV adhesive.

Finally, the cellulose acylate film 1 and the photo-alignment layer 2 were peeled off to prepare a circularly polarizing plate 4 with a cover glass.

### Preparation Example 5

The surface of the polarizing film 5 on the oxygen blocking layer B1 side was bonded to the glass substrate A using the pressure sensitive adhesive. Next, only the cellulose triacetate film TJ40 of the polarizing film 5 was peeled off, and then the surface of the optically anisotropic layer of the optical film 1H was bonded to the peeled surface of the photo-alignment layer PA1 using the UV adhesive.

Finally, the cellulose acylate film 1 and the photo-alignment layer 2 were peeled off to prepare a circularly polarizing plate 5 with a cover glass.

### Preparation Example 6

An optical film 1C was prepared in the same manner as in the optical film 1 of Preparation Example 1, except that the cellulose acylate film 1 was changed to an unstretched cycloolefin film (norbornene resin, thickness: 25 μm, equilibrium moisture content at 25° C. and 80% RH: 0.05%) whose surface on the coating side was subjected to a corona treatment.

Next, the surface of the optical film 1C on the unstretched cycloolefin film side was subjected to a corona treatment, and then bonded to the polarizer surface of the polarizer 2 with a protective film on one surface thereof using a UV adhesive to obtain a circularly polarizing plate 6. At that time, the angle formed by the absorption axis of the polarizer and the slow axis of the positive A plate A1 was 45°.

Further, a circularly polarizing plate 6 with a cover glass was prepared in the same manner as in Preparation Example 1.

### Preparation Example 7

An optical film 1M was prepared in the same manner as in the optical film 1 of Preparation Example 1, except that the cellulose acylate film 1 was changed to a methacrylic resin (PMMA) film (thickness: 25 μm, equilibrium moisture content at 25° C. and 80% RH: 1.3%) whose surface on the coating side was subjected to a corona treatment.

Next, the surface of the optical film 1M on the methacrylic resin (PMMA) film side was subjected to a corona treatment, and then bonded to the polarizer surface of the polarizer 6 with a protective film on one surface thereof using a UV adhesive to obtain a circularly polarizing plate 7. At that time, the angle formed by the absorption axis of the polarizer and the slow axis of the positive A plate A1 was 45°.

Further, a circularly polarizing plate 7 with a cover glass was prepared in the same manner as in Preparation Example 1.

### Preparation Examples 8 to 31

Polarizing plates 8 to 31 were prepared according to the same procedure as in Preparation Examples 1 to 4, except that a composition for forming a positive A plate shown in Table 3 which will be given later was used instead of the composition A1 for forming a positive A plate and the polarizer 1 was changed to a polarizer shown in Table 3 which will be given later.

The compositions of the compositions A2 to A12 for forming a positive A plate shown in Table 3 which will be given later are shown below.

(Preparation of Composition A2 for Forming Positive a Plate)

A composition A2 for forming a positive A plate was prepared in the same manner as in the composition A1 for forming a positive A plate, except that 100 parts by mass of the following specific liquid crystal compound L-6 were used instead of the polymerizable liquid crystal compound X-1, the specific liquid crystal compound L-1, and the specific liquid crystal compound L-2, in the composition A1 for forming a positive A plate.

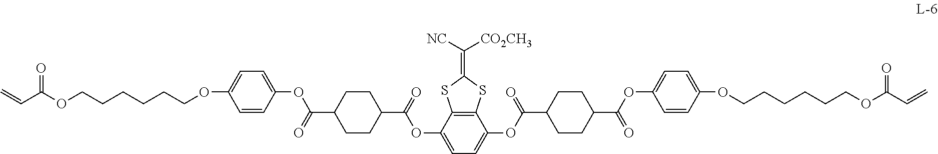 [SMILES: C=CC(=O)OCCCCCCOc1ccc(OC(=O)C2CCC(C(=O)Oc3ccc(OC(=O)C4CCC(C(=O)Oc5ccc(OCCCCCCOC(=O)C=C)cc5)CC4)c4c3SC(=C(C#N)C(=O)OC)S4)CC2)cc1]

(Preparation of Composition A3 for Forming Positive a Plate)

A composition A3 for forming a positive A plate was prepared in the same manner as in the composition A1 for forming a positive A plate, except that 100 parts by mass of the following specific liquid crystal compound L-9 were used instead of the polymerizable liquid crystal compound X-1, the specific liquid crystal compound L-1, and the specific liquid crystal compound L-2, in the composition A1 for forming a positive A plate.

Specific Liquid Crystal Compound L-9

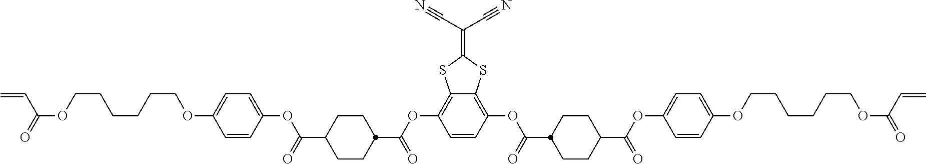

(Preparation of Composition A4 for Forming Positive a Plate)

A composition A4 for forming a positive A plate having the following composition was prepared.

Composition of the composition A4 for fbrming a positive A plate

| | | |
|---|---|---|
| Specific liquid crystal compound L-17 shown below | 70.00 | parts by mass |
| Specific liquid crystal compound L-5 shown below | 30.00 | parts by mass |
| Polymerization initiator OXE-03 (manufactured by BASF Japan Ltd.) | 4.00 | parts by mass |
| ADEKA ARKLS NCI-831 (manufactured by ADEKA Corporation) | 5.00 | parts by mass |
| Leveling agent (compound T-1 described above) | 0.10 | parts by mass |
| Antioxidant BHT (manufactured by Tokyo Chemical Industry Co., Ltd.) | 0.90 | parts by mass |
| Methyl ethyl ketone (solvent) | 60.00 | parts by mass |
| Cyclopentanone (solvent) | 240.00 | parts by mass |

Liquid crystal compound L-17

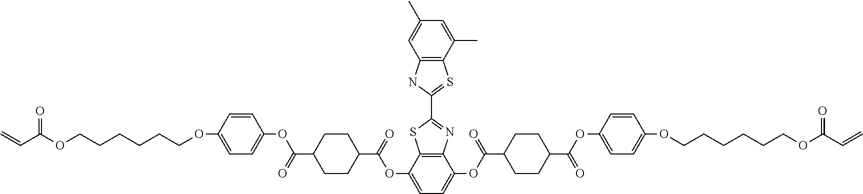

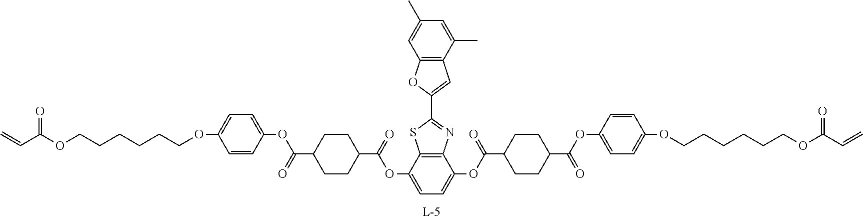 [SMILES: C=CC(=O)OCCCCCCOc1ccc(OC(=O)C2CCC(C(=O)Oc3ccc(OC(=O)C4CCC(C(=O)Oc5ccc(OCCCCCCOC(=O)C=C)cc5)CC4)c4sc(-c5cc6c(C)cc(C)cc6o5)nc34)CC2)cc1]

(Preparation of Composition A5 for Forming Positive a Plate)

A composition A5 for forming a positive A plate was prepared in the same manner as in the composition A4 for forming a positive A plate, except that 100 parts by mass of the following specific liquid crystal compound L-7 were used instead of the specific liquid crystal compounds L-17 and L-5, in the composition A4 for forming a positive A plate.

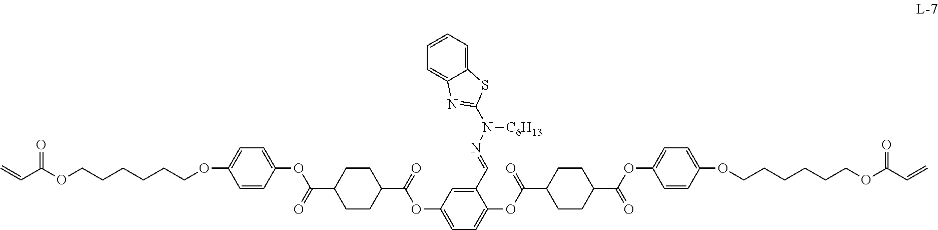

(Preparation of Composition A6 for Forming Positive a Plate)

A composition A6 for forming a positive A plate was prepared in the same manner as in the composition A4 for forming a positive A plate, except that 100 parts by mass of the following specific liquid crystal compound L-8 were used instead of the specific liquid crystal compounds L-17 and L-5, in the composition A4 for forming a positive A plate.

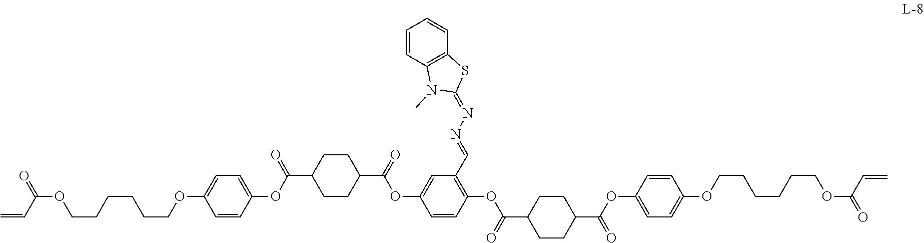 [SMILES: C=CC(=O)OCCCCCCOc1ccc(OC(=O)C2CCC(C(=O)Oc3ccc(OC(=O)C4CCC(C(=O)Oc5ccc(OCCCCCCOC(=O)C=C)cc5)CC4)c(/C=N/N=c4/sc5ccccc5n4C)c3)CC2)cc1]

(Preparation of Composition A7 for Forming Positive a Plate)

A composition A7 for forming a positive A plate was prepared in the same manner as in the composition A4 for forming a positive A plate, except that 100 parts by mass of the following specific liquid crystal compound L-10 were used instead of the specific liquid crystal compounds L-17 and L-5, in the composition A4 for forming a positive A plate.

Specific Liquid Crystal Compound L-10

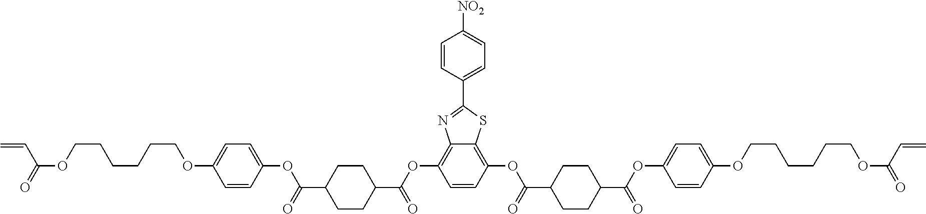 [SMILES: C=CC(=O)OCCCCCCOc1ccc(OC(=O)C2CCC(C(=O)Oc3ccc(OC(=O)C4CCC(C(=O)Oc5ccc(OCCCCCCOC(=O)C=C)cc5)CC4)c4sc(-c5ccc([N+](=O)[O-])cc5)nc34)CC2)cc1]

(Preparation of Composition A8 for Forming Positive a Plate)

A composition A8 for forming a positive A plate was prepared in the same manner as in the composition A4 for forming a positive A plate, except that 100 parts by mass of the following specific liquid crystal compound L-11 were used instead of the specific liquid crystal compounds L-17 and L-5, in the composition A4 for forming a positive A plate.

Specific Liquid Crystal Compound L-11

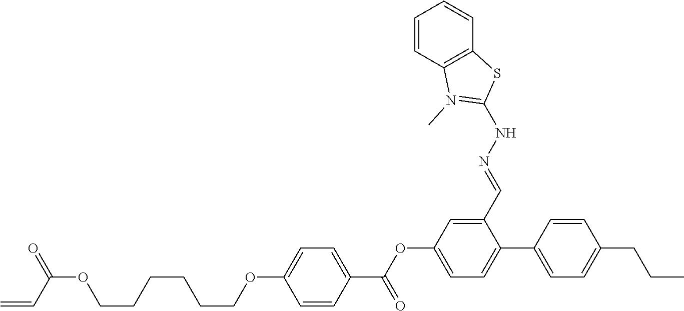

(Preparation of Composition A9 for Forming Positive A Plate)

A composition A9 for forming a positive A plate was prepared in the same manner as in the composition A4 for forming a positive A plate, except that 100 parts by mass of the following specific liquid crystal compound L-12 were used instead of the specific liquid crystal compounds L-17 and L-5, in the composition A4 for forming a positive plate.

Specific Liquid Crystal Compound L-12

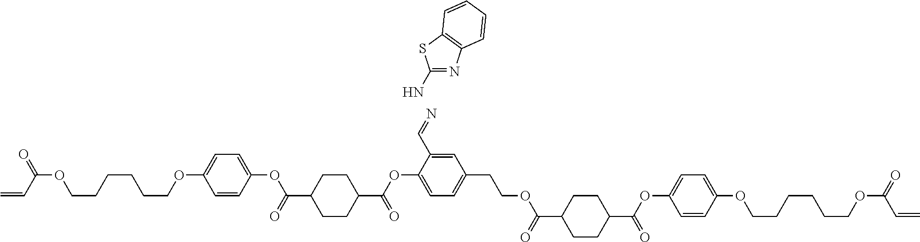

(Preparation of Composition A10 for Forming Positive A Plate)

A composition A10 for forming a positive A plate was prepared in the same manner as in the composition A4 for forming a positive A plate, except that 100 parts by mass of the following specific liquid crystal compound L-13 were used instead of the specific liquid crystal compounds L-17 and L-5, in the composition A4 for forming a positive A plate.

Specific Liquid Crystal Compound L-13

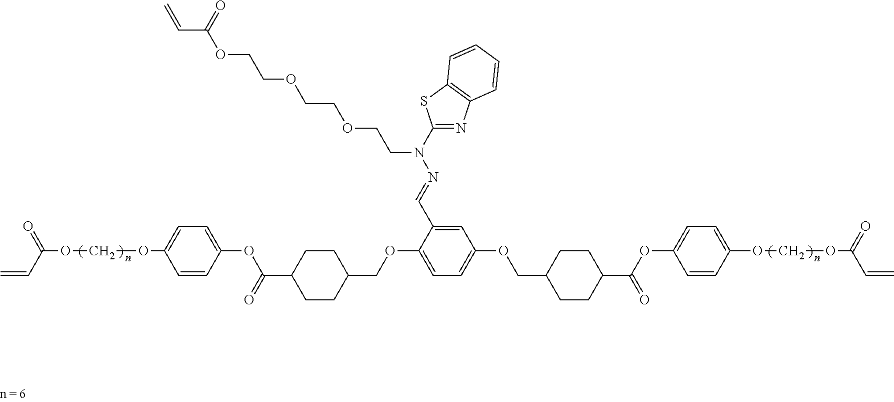

(Preparation of Composition A11 for Forming Positive A Plate)

A composition A11 for forming a positive A plate having the following composition was prepared.

Composition of the composition A11 for forming a positive A plate

| | | |
|---|---|---|
| Specific liquid crystal compound L-14 shown below | 35.00 | parts by mass |
| Polymerizable liquid crystal compound X-1 described above | 15.00 | parts by mass |
| Polymerizable liquid crystal compound X-2 shown below | 35.00 | parts by mass |
| Polymerizable liquid crystal compound X-3 shown below | 15.00 | parts by mass |
| Polymerization initiator OXE-03 (manufactured by BASF Japan Ltd.) | 5.00 | parts by mass |
| ADEKA ARKLS NC1-831 (manufactured by ADEKA Corporation) | 4.00 | parts by mass |
| Acid anhydride K-1 described above | 4.00 | parts by mass |
| Leveling agent (compound T-1 described above) | 0.10 | parts by mass |
| Antioxidant BHT (manufactured by Tokyo Chemical Industry Co., Ltd.) | 0.90 | parts by mass |
| Methyl ethyl ketone (solvent) | 60.00 | parts by mass |
| Cyclopentanone (solvent) | 240.00 | parts by mass |

Specific liquid crystal compound L-14 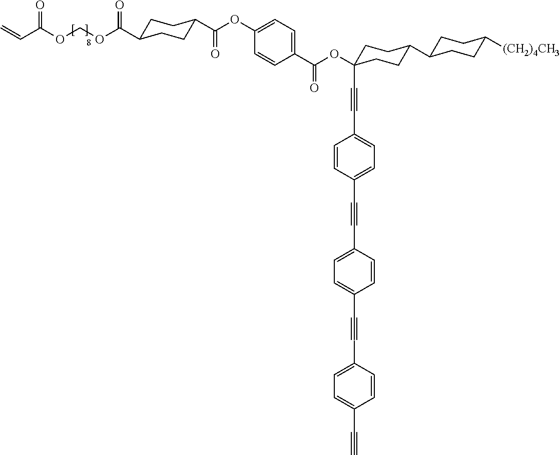
Polymerizable liquid crystal compound X-2 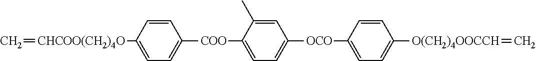
Polymerizable liquid crystal compound X-3

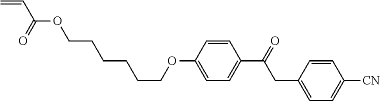 [SMILES: C=CC(=O)OCCCCCCOc1ccc(C(=O)Cc2ccc(C#N)cc2)cc1]

(Preparation of Composition A12 for Forming Positive A Plate)

A composition A12 for forming a positive A plate having the following composition was prepared.

Composition of the composition A12 for forming a positive A plate

| | | |
|---|---|---|
| Specific liquid crystal compound L-15 shown below | 42.00 | parts by mass |
| Specific liquid crystal compound L-16 shown below | 42.00 | parts by mass |
| Polymerizable liquid crystal compound X-1 described above | 5.00 | parts by mass |
| Polymerizable liquid crystal compound X-5 shown below | 11.00 | parts by mass |
| Polymerization initiator S-1 described above | 0.50 | parts by mass |
| Acid anhydride K-1 described above | 4.00 | parts by mass |
| Polymerizable compound B-1 described above | 2.00 | parts by mass |
| Leveling agent (compound T-1 described above) | 0.23 | parts by mass |
| Methyl ethyl ketone (solvent) | 50.00 | parts by mass |
| Cyclopentanone (solvent) | 250.00 | parts by mass |

Specific liquid crystal compound L-15 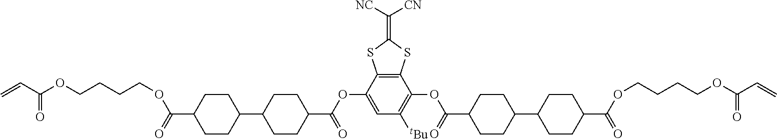 [SMILES: C=CC(=O)OCCCCOC(=O)C1CCC(C2CCC(C(=O)Oc3cc(C(C)(C)C)c(OC(=O)C4CCC(C5CCC(C(=O)OCCCCOC(=O)C=C)CC5)CC4)c4c3SC(=C(C#N)C#N)S4)CC2)CC1]
Specific liquid crystal compound L-16 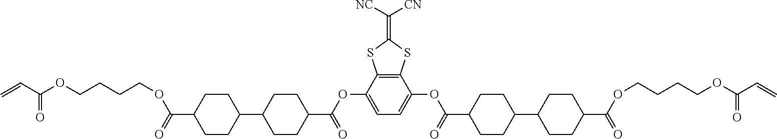 [SMILES: C=CC(=O)OCCCCOC(=O)C1CCC(C2CCC(C(=O)Oc3ccc(OC(=O)C4CCC(C5CCC(C(=O)OCCCCOC(=O)C=C)CC5)CC4)c4c3SC(=C(C#N)C#N)S4)CC2)CC1]
Polymerizable liquid crystal compound X-5

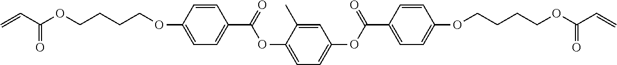 [SMILES: C=CC(=O)OCCCCOc1ccc(C(=O)Oc2ccc(OC(=O)c3ccc(OCCCCOC(=O)C=C)cc3)c(C)c2)cc1]

<Preparation of Silicon Nitride Layer>

The glass substrate A was set in a substrate holder in a vacuum chamber of a CVD apparatus, and the vacuum chamber was closed. Next, the inside of the vacuum chamber was exhausted, and in a case where the pressure reached 0.1 Pa, the raw material gases were introduced. The flow rate of silane gas was 100 cc/min, the flow rate of ammonia gas was 300 cc/min, and the flow rate of hydrogen gas was 1,000 cc/min.

In a case where the pressure in the vacuum chamber stabilized at 100 Pa, a plasma excitation power of 2,000 W was supplied to the electrodes from a high frequency power supply of 13.5 MHz to form a gas barrier film containing silicon nitride as a main component on the surface of the glass substrate to obtain a glass substrate with a silicon nitride layer.

The film thickness of the gas barrier film was 50 nm. The film thickness was controlled by an experiment carried out in advance. In addition, during the film formation, the substrate temperature was adjusted to 70° C. or lower by a temperature adjusting unit built in the substrate holder.

The peak intensity of an Si—N bond located at 800 to 900 cm⁻¹ and the peak intensity of an N—H bond located at 3300 to 3400 cm⁻¹ in the ATR (total reflection type infrared absorption method) mode of FT-IR were measured for the prepared gas barrier film, using an infrared spectroscope (a device in which ATR-PRO410-S is attached to FT-IR 6100, manufactured by JASCO Corporation). From this measurement result, N—H/Si—N, which is an intensity ratio of the peak intensity of an N—H bond to the peak intensity of an Si—N bond, was calculated. As a result, the N—H/Si—N was 0.11.

A silicon nitride layer was formed on a 100 μm PET film (moisture permeability: 3 g/m²·day) under the same conditions, and the moisture permeability in an atmosphere of 40° C. and 90% RH was measured using a water vapor transmission rate measuring device (AQUATRAN2 (registered trademark), manufactured by MOCON, Inc.). As a result, the moisture permeability was less than 0.9×10⁻¹ g/m²·day. That is, the moisture permeability of only the silicon nitride layer in an atmosphere of 40° C. and 90% RH was less than 1×10⁻¹ g/m²·day.

<Evaluation of Durability>

The positive A plate side of each of the circularly polarizing plates 1 to 31 with a cover glass was bonded to the silicon nitride layer on the glass substrate with a silicon nitride layer using the film with a pressure sensitive adhesive, and a thermal durability test at 70° C. for 500 hours was carried out.

There was only a pressure-sensitive adhesive layer between the circularly polarizing plate and the silicon nitride layer, and the moisture permeability was 100 g/m²·day or more.

The values of in-plane retardation Re(450) and Re(550) at wavelengths of 450 nm and 550 nm were measured using an AxoScan (OPMF-1, manufactured by Axometrics, Inc.).

In a case where H=Re(450)/Re(550), the evaluation was carried out as follows using ΔH (%)=|H1−H0|/H0×100 as an indicator, assuming that H before the thermal durability test is defined as H0, and H after the thermal durability test is defined as H1. The results are shown in Table 1 below.

AA: ΔH is less than 1%

A: ΔH is 1% or more and less than 3%

B: ΔH is 3% or more and less than 7%

C: ΔH is 7% or more

In Table 3, the column of “Type” in the column of “Optically anisotropic layer” represents the type of the composition for forming a positive A plate used.

The column of “Type” in the column of “Polarizer” represents the type of the polarizer used.

The column of “PVA polarizer film thickness” represents the film thickness of the polyvinyl alcohol polarizer.

TABLE 3

| | Type of | Optically anisotropic layer (positive A plate) | | | | Polarizer | | | Thermal | |
|---|---|---|---|---|---|---|---|---|---|---|
| | circularly | | Specific liquid | Re(550)/ | Re(650)/ | | Polarizer | PVA polarizer | durability | |
| | polarizing plate | Layer | crystal compound | Re(450) | Re(550) | Type | protective film | thickness μm | evaluation | Remarks |
| Preparation Example 1 | 1 | A1 | L-1/L-2 | 1.13 | 1.01 | 1 | TAC/TAC | 20 | C | Comparative |
| Preparation Example 2 | 2 | A1 | L-1/L-2 | 1.13 | 1.01 | 2 | TAC/TAC | 9 | B | Inventive |
| Preparation Example 3 | 3 | A1 | L-1/L-2 | 1.13 | 1.01 | 3 | TAC/TAC | 4 | A | Inventive |
| Preparation Example 4 | 4 | A1 | L-1/L-2 | 1.13 | 1.01 | 4 | — | 0 | AA | Inventive |
| Preparation Example 5 | 5 | A1 | L-1/L-2 | 1.13 | 1.01 | 5 | — | 0 | AA | Inventive |
| Preparation Example 6 | 6 | A1 | L-1/L-2 | 1.13 | 1.01 | 2 | COP/TAC | 9 | A | Inventive |
| Preparation Example 7 | 7 | A1 | L-1/L-2 | 1.13 | 1.01 | 6 | PMMA/PMMA | 9 | A | Inventive |
| Preparation Example 8 | 8 | A2 | L-6 | 1.19 | 1.02 | 3 | TAC/TAC | 4 | A | Inventive |
| Preparation Example 9 | 9 | A3 | L-9 | 1.2 | 1.02 | 3 | TAC/TAC | 4 | A | Inventive |
| Preparation Example 10 | 10 | A4 | L-5/L-17 | 1.18 | 1.03 | 2 | TAC/TAC | 9 | A | Inventive |
| Preparation Example 11 | 11 | A4 | L-5/L-17 | 1.18 | 1.03 | 4 | — | 0 | AA | Inventive |
| Preparation Example 12 | 12 | A5 | L-7 | 1.2 | 1.05 | 3 | TAC/TAC | 4 | A | Inventive |
| Preparation Example 13 | 13 | A5 | L-8 | 1.14 | 1.02 | 3 | TAC/TAC | 4 | A | Inventive |
| Preparation Example 14 | 14 | A7 | L-10 | 1.13 | 1.02 | 2 | TAC/TAC | 9 | A | Inventive |
| Preparation Example 15 | 15 | A8 | L-11 | 1.22 | 1.02 | 3 | TAC/TAC | 4 | A | Inventive |
| Preparation Example 16 | 16 | A9 | L-12 | 1.22 | 1.02 | 3 | TAC/TAC | 4 | A | Inventive |
| Preparation Example 17 | 17 | A10 | L-13 | 1.19 | 1.02 | 3 | TAC/TAC | 4 | A | Inventive |
| Preparation Example 18 | 18 | A11 | L-14 | 1.06 | 1.04 | 3 | TAC/TAC | 4 | A | Inventive |
| Preparation Example 19 | 19 | A12 | L-15/L-16 | 1.22 | 1.02 | 3 | TAC/TAC | 4 | A | Inventive |
| Preparation Example 20 | 20 | A12 | L-15/L-16 | 1.22 | 1.02 | 4 | — | 0 | AA | Inventive |
| Preparation Example 21 | 21 | A2 | L-6 | 1.19 | 1.02 | 1 | TAC/TAC | 20 | C | Comparative |
| Preparation Example 22 | 22 | A3 | L-9 | 1.2 | 1.02 | 1 | TAC/TAC | 20 | C | Comparative |
| Preparation Example 23 | 23 | A4 | L-5/L-17 | 1.18 | 1.03 | 1 | TAC/TAC | 20 | C | Comparative |
| Preparation Example 24 | 24 | A5 | L-7 | 1.2 | 1.05 | 1 | TAC/TAC | 20 | C | Comparative |
| Preparation Example 25 | 25 | A6 | L-8 | 1.14 | 1.02 | 1 | TAC/TAC | 20 | C | Comparative |
| Preparation Example 26 | 26 | A7 | L-10 | 1.13 | 1.02 | 1 | TAC/TAC | 20 | C | Comparative |
| Preparation Example 27 | 27 | A8 | L-11 | 1.22 | 1.02 | 1 | TAC/TAC | 20 | C | Comparative |
| Preparation Example 28 | 28 | A9 | L-12 | 1.22 | 1.02 | 1 | TAC/TAC | 20 | C | Comparative |
| Preparation Example 29 | 29 | A10 | L-13 | 1.19 | 1.02 | 1 | TAC/TAC | 20 | C | Comparative |
| Preparation Example 30 | 30 | A11 | L-14 | 1.06 | 1.04 | 1 | TAC/TAC | 20 | C | Comparative |
| Preparation Example 31 | 31 | A11 | L-15/L-16 | 1.22 | 1.02 | 1 | TAC/TAC | 20 | C | Comparative |

From the results shown in Table 3 above, it was found that all of Preparation Examples of the present invention exhibited good thermal durability.

Above all, from the comparison of Preparation Example 2 with Preparation Example 3, it was confirmed that the effect was more excellent in a case where the PVA polarizer film thickness was 5 μm or less. The polarizer in Preparation Examples 4 and 5 is not a conventional PVA polarizer but is a polarizer formed of a dichroic organic coloring agent.

In addition, from the comparison of Preparation Example 2 with Preparation Examples 6 and 7, it was confirmed that the effect was more excellent in a case of using PMMA or COP, which is a resin having an equilibrium moisture content of 2% or less at 25° C. and 80% RH, for the polarizer protective film.

### Preparation Example 32

(Formation of Positive C Plate Film 1)

The following composition C-1 was continuously coated on a TG40 (manufactured by Fujifilm Corporation) support as a temporary support for formation. The coating film formed on the temporary support for formation was heated to 60° C. under a heating atmosphere and irradiated with ultraviolet rays (300 mJ/cm²) at 70° C. and an oxygen concentration of 100 ppm under a nitrogen purge to form a positive C plate film 1 including a retardation film (positive C plate 1) in which the alignment of the liquid crystal compound was fixed. The thickness of the retardation film was 0.4 μm.

(Composition C-1)

| | | |
|---|---|---|
| Rod-like liquid crystal compound (M-1) shown below | 83 | parts by mass |
| Rod-like liquid crystal compound (M-2) shown below | 15 | parts by mass |
| Rod-like liquid crystal compound (M-3) shown below | 2 | parts by mass |
| Urethane monomer (EBECRYL 1290, manufactured by Daicel-Allnex Ltd.) shown below | 3.3 | parts by mass |
| Polymerization initiator (IRGACURE OXE01, manufactured by BASF SE) shown below | 4 | parts by mass |
| Fluorine-based polymer (M-4) shown below | 3 | parts by mass |
| Fluorine-based polymer (M-5) shown below | 0.3 | parts by mass |
| Opium compound S01 shown below | 1.5 | parts by mass |
| Toluene | 552 | parts by mass |
| Methyl ethyl ketone (MEK) | 138 | parts by mass |

Rod-like liquid crystal compound (M-1) 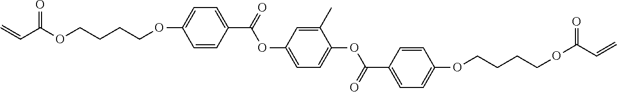 [SMILES: C=CC(=O)OCCCCOc1ccc(C(=O)Oc2ccc(OC(=O)c3ccc(OCCCCOC(=O)C=C)cc3)c(C)c2)cc1]
Rod-like liquid crystal compound (M-2) 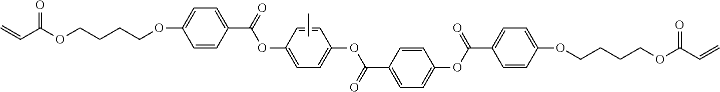
Rod-like liquid crystal compound (M-3) 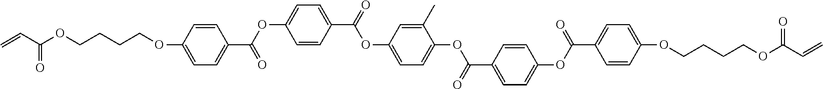 [SMILES: C=CC(=O)OCCCCOc1ccc(C(=O)Oc2ccc(C(=O)Oc3ccc(OC(=O)c4ccc(OC(=O)c5ccc(OCCCCOC(=O)C=C)cc5)cc4)c(C)c3)cc2)cc1]
Urethane monomer 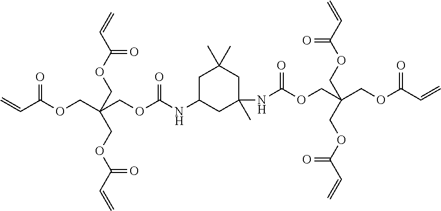 [SMILES: C=CC(=O)OCC(COC(=O)C=C)(COC(=O)C=C)COC(=O)NC1CC(C)(C)CC(C)(NC(=O)OCC(COC(=O)C=C)(COC(=O)C=C)COC(=O)C=C)C1]
Polymerization initiator 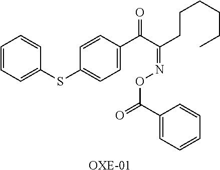 [SMILES: CCCCCC/C(=N/OC(=O)c1ccccc1)C(=O)c1ccc(Sc2ccccc2)cc1 ; "OXE-01"]
Fluorine-based polymer (M-4) 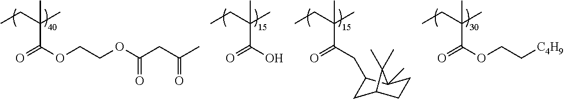
Fluorine-based polymer (M-5) 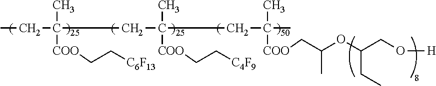
Onium salt compound S01

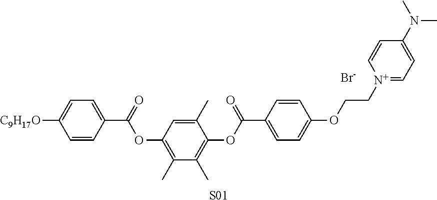

The positive A plate A1 side surface of the circularly polarizing plate 2 with a cover glass and the retardation film side surface of the positive C plate film 1 prepared above were both subjected to a corona treatment and bonded using the above-mentioned UV adhesive. After that, the temporary support TG40 for formation in the positive C plate film 1 was peeled off to prepare a circularly polarizing plate 2C with a cover glass in which the positive C plate film 1 was laminated on the positive A plate A1 of the circularly polarizing plate 2 with a cover glass through a UW adhesive.

### Preparation Example 33 to 50

In the same manner as in Preparation Example 33, circularly polarizing plates 3C to 20C with a cover glass were prepared by replacing the circularly polarizing plate 2 with a cover glass with each of circularly polarizing plates 3 to 20 with a cover glass.

<Evaluation>

Similar to the circularly polarizing plates 1 to 31 with a cover glass, the circularly polarizing plates 2C to 20C with a cover glass were also subjected to the same thermal durability evaluation, and it was confirmed that the circularly polarizing plates 2C to 20C with a cover glass showed good thermal durability equal to or higher than the evaluation standard B.

<Preparation of Organic EL Display Device>

The FlexPai (manufactured by Royole Corporation) equipped with an organic EL display panel (organic EL display element) was disassembled, and a circularly polarizing plate was peeled off from the organic EL display device.

Next, each of the circularly polarizing plates 2 to 20 with a cover glass prepared above was bonded to the isolated organic EL display panel (whose outermost surface is a silicon nitride layer) such that the positive A plate side was on the panel side to prepare organic EL display devices.

In addition, in the same procedure, each of the circularly polarizing plates 2C to 20C with a cover glass prepared above was bonded to the isolated organic EL display panel (whose outermost surface is a silicon nitride layer) such that the positive C plate 1 side was on the panel side to prepare organic EL display devices.

The prepared organic EL display devices were evaluated in the same manner as in the case where Pure Ace WR (manufactured by Teijin Limited) was used as a V/4 plate. As a result, it was confirmed that the same effect was exhibited in both the cases where the circularly polarizing plates 2 to 20 with a cover glass having the positive A plate were used, and the cases where the circularly polarizing plates 2C to 20C with a cover glass including an optical laminate of the positive A plate and the positive C plate C1 were used.

4MG, 5MG, 11MG, and 20MG were prepared in which the cover glass was replaced with a glass substrate (D263, manufactured by SCHOTT AG) of 50 μm from the glass substrate A of 1.1 mm for the circularly polarizing plates 4C, 5C, 11C, and 20C with a cover glass.

In addition, 4AR, 5AR, 11AR, and 20AR were prepared in which the cover glass was replaced with an AR film (AR100; 91 μm, manufactured by Dexerials Corporation) having a multilayer sputtered metal oxide film from the glass substrate A of 1.1 mm.

These were each mounted on an organic EL display device in the same manner as above, and confirmed to be foldable.

### EXPLANATION OF REFERENCES

10, 20, 30: organic EL display device
11: low moisture permeability substrate 1 (cover glass)
12: polarizer protective film
13: polarizer
14: polarizer protective film
15: positive A plate
16: positive C plate
17: low moisture permeability substrate 2 (silicon nitride layer)
18: organic EL display element

What is claimed is:

1. An organic electroluminescent display device comprising, in order from a visual recognition side, at least:
a circularly polarizing plate; and
an organic electroluminescent display element having a pair of electrodes and an organic light emitting layer sandwiched therebetween,
wherein the circularly polarizing plate has a polarizer and an optically anisotropic layer,
the polarizer is a polarizer having a thickness of 10 μm or less and containing a polyvinyl alcohol-based resin, or a polarizer having a dichroic organic coloring agent,
the optically anisotropic layer is a layer formed of a composition containing a polymerizable liquid crystal compound exhibiting reverse wavelength dispersibility,
a silicon nitride layer is included between the circularly polarizing plate and the organic electroluminescent display element, and
the circularly polarizing plate is disposed between two low moisture permeability substrates, the low moisture permeability substrates have a moisture permeability of 1 g/m²·day or less, and one of the low moisture permeability substrates is the silicon nitride layer.

2. The organic electroluminescent display device according to claim 1,
wherein the polarizer is a polarizer having a thickness of 5 μm or less and containing a polyvinyl alcohol-based resin.

3. The organic electroluminescent display device according to claim 1,
wherein a moisture permeability of a layer existing between the circularly polarizing plate and the silicon nitride layer is 100 g/m²·day or more.

4. The organic electroluminescent display device according to claim 1,
wherein a thickness of the layer existing between the circularly polarizing plate and the silicon nitride layer is less than 40 μm.

5. The organic electroluminescent display device according to claim 1,
wherein the polymerizable liquid crystal compound contains a polymerizable liquid crystal compound having a partial structure represented by Formula (II),
*-D₁-Ar-D₂-* (II)
in Formula (II),
D¹ and D² each independently represent a single bond, —O—, —CO—, —CO—O—, —C(═S)O—, —CR¹R²—, —CR¹R²—CR³R⁴—, —O—CR¹R²—, —CR¹R²—O—CR³R⁴—, —CO—O—CR¹R²—, —O—CO—CR¹R²—, —CR¹R²—CR³R⁴—O—CO—, —CR¹R²—O—CO—CR³R⁴—, —CR¹R²—CO—O—CR³R⁴—, —NR¹—CR²R³—, or —CO—NR¹—,
R¹, R², R³, and R⁴ each independently represent a hydrogen atom, a fluorine atom, or an alkyl group having 1 to 4 carbon atoms, and
Ar represents any aromatic ring selected from the group consisting of groups represented by Formulae (Ar-1) to (Ar-7), 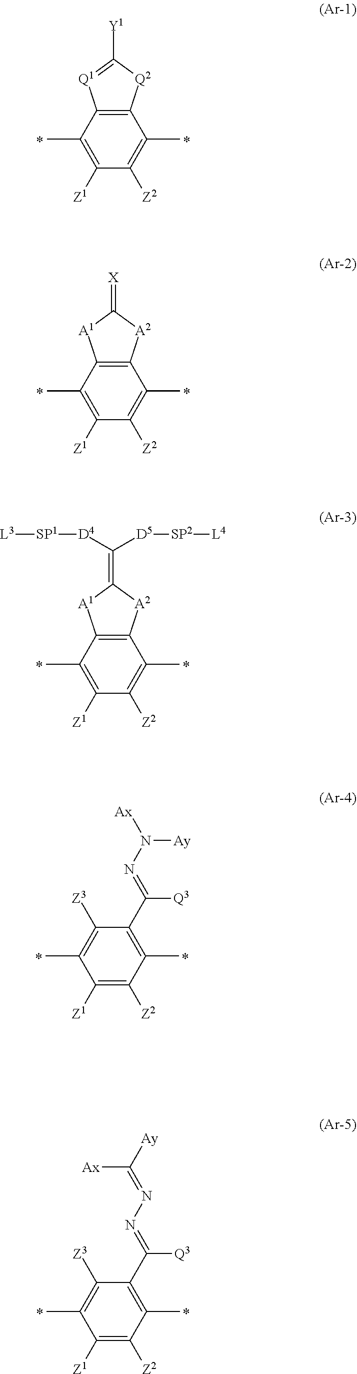 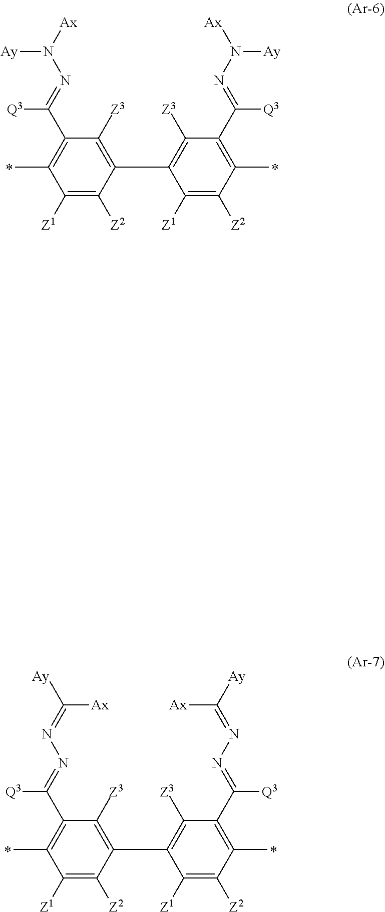
in Formulae (Ar-1) to (Ar-7),
represents a bonding position with D¹ or D²,
Q¹ represents N or CH,
Q² represents —S—, —O—, or —N(R⁷)—, and R⁷ represents a hydrogen atom or an alkyl group having 1 to 6 carbon atoms,
Y¹ represents an aromatic hydrocarbon group having 6 to 12 carbon atoms or an aromatic heterocyclic group having 3 to 12 carbon atoms, which may have a substituent,
Z¹, Z², and Z³ each independently represent a hydrogen atom, a monovalent aliphatic hydrocarbon group having 1 to 20 carbon atoms, a monovalent alicyclic hydrocarbon group having 3 to 20 carbon atoms, a monovalent aromatic hydrocarbon group having 6 to 20 carbon atoms, a halogen atom, a cyano group, a nitro group, —OR⁸, —NR⁹R¹⁰, or —SR¹¹, R⁸ to R¹¹ each independently represent a hydrogen atom or an alkyl group having 1 to 6 carbon atoms, and Z¹ and Z² may be bonded to each other to form an aromatic ring,
A¹ and A² each independently represent a group selected from the group consisting of —O—, —N(R¹²)—, —S—, and —CO—, and R¹² represents a hydrogen atom or a substituent,
X represents a non-metal atom of Groups 14 to 16 to which a hydrogen atom or a substituent may be bonded,
D⁴ and D⁵ each independently represent a single bond or —CO—, —O—, —S—, —C(═S)—, —CR^{1a}R^{2a}—, —CR^{3a}═CR^{4a}—, —NR^{5a}—, or a divalent linking group consisting of two or more combinations of these groups, and R^{1a} to R^{5a} each independently represent a hydrogen atom, a fluorine atom, or an alkyl group having 1 to 4 carbon atoms,
SP¹ and SP² each independently represent a single bond, a linear or branched alkylene group having 1 to 12 carbon atoms, or a divalent linking group in which one or more of —CH₂-constituting a linear or branched alkylene group having 1 to 12 carbon atoms are substituted with —O—, —S—, —NH—, —N(Q)-, or —CO—, and Q represents a substituent,
L³ and L⁴ each independently represent a monovalent organic group,
Ax represents an organic group having 2 to 30 carbon atoms which has at least one aromatic ring selected from the group consisting of an aromatic hydrocarbon ring and an aromatic heterocyclic ring,
Ay represents a hydrogen atom, an alkyl group having 1 to 12 carbon atoms which may have a substituent, or an organic group having 2 to 30 carbon atoms which has at least one aromatic ring selected from the group consisting of an aromatic hydrocarbon ring and an aromatic heterocyclic ring,
the aromatic rings in Ax and Ay may have a substituent, and Ax and Ay may be bonded to each other to form a ring, and
Q³ represents a hydrogen atom or an alkyl group having 1 to 6 carbon atoms which may have a substituent.

6. The organic electroluminescent display device according to claim 1,
wherein Re(450), which is an in-plane retardation value of the optically anisotropic layer measured at a wavelength of 450 nm, Re(550), which is an in-plane retardation value of the optically anisotropic layer measured at a wavelength of 550 nm, and Re(650), which is an in-plane retardation value of the optically anisotropic layer measured at a wavelength of 650 nm, satisfy a relationship of Re(450)≤Re(550)≤Re(650).

7. The organic electroluminescent display device according to claim 1,
wherein the optically anisotropic layer is a positive A plate.

8. The organic electroluminescent display device according to claim 1,
wherein the optically anisotropic layer is a λ/4 plate.

9. The organic electroluminescent display device according to claim 1,
wherein an angle formed by a slow axis of the optically anisotropic layer and an absorption axis of the polarizer is 45°±10°.

10. The organic electroluminescent display device according to claim 1,
wherein the polarizer is formed of a composition containing a dichroic organic coloring agent and a polymerizable liquid crystal compound, and the polymerizable liquid crystal compound is in amount of 50% by mass or more of a solid content mass of the composition.

11. The organic electroluminescent display device according to claim 1,
wherein a luminosity corrected single body transmittance of the polarizer is 47% or more.

12. The organic electroluminescent display device according to claim 1,
wherein a polarizer protective film is provided between the polarizer and the optically anisotropic layer, and
an equilibrium moisture content of the polarizer protective film at 25° C. and 80% RH is 2% or less.

13. The organic electroluminescent display device according to claim 12,
wherein the polarizer protective film contains a norbornene-based resin.

14. The organic electroluminescent display device according to claim 1,
wherein the other one of the low moisture permeability substrates is a glass substrate.

15. The organic electroluminescent display device according to claim 1,
wherein the other one of the low moisture permeability substrates is a glass substrate having a thickness of 100 μm or less.

16. The organic electroluminescent display device according to claim 1,
wherein the other one of the low moisture permeability substrates is a metal oxide film having a thickness of 1 μm or less.

17. The organic electroluminescent display device according to claim 2,
wherein a moisture permeability of a layer existing between the circularly polarizing plate and the silicon nitride layer is 100 g/m²·day or more.

18. The organic electroluminescent display device according to claim 2,
wherein a thickness of the layer existing between the circularly polarizing plate and the silicon nitride layer is less than 40 μm.

19. The organic electroluminescent display device according to claim 2,
wherein the polymerizable liquid crystal compound contains a polymerizable liquid crystal compound having a partial structure represented by Formula (II),
*-D₁-Ar-D₂-* (II)
in Formula (II),
D¹ and D² each independently represent a single bond, —O—, —CO—, —CO—O—, —C(═S)O—, —CR¹R²—, —CR¹R²—CR³R⁴—, —O—CR¹R²—, —CR¹R²—O—CR³R⁴—, —CO—O—CR¹R²—, —O—CO—CR¹R²—, —CR¹R²—CR³R⁴—O—CO—, —CR¹R²—O—CO—CR³R⁴—, —CR¹R²—CO—O—CR³R⁴—, —NR¹—CR²R³—, or —CO—NR¹—,
R¹, R², R³, and R⁴ each independently represent a hydrogen atom, a fluorine atom, or an alkyl group having 1 to 4 carbon atoms, and
Ar represents any aromatic ring selected from the group consisting of groups represented by Formulae (Ar-1) to (Ar-7), 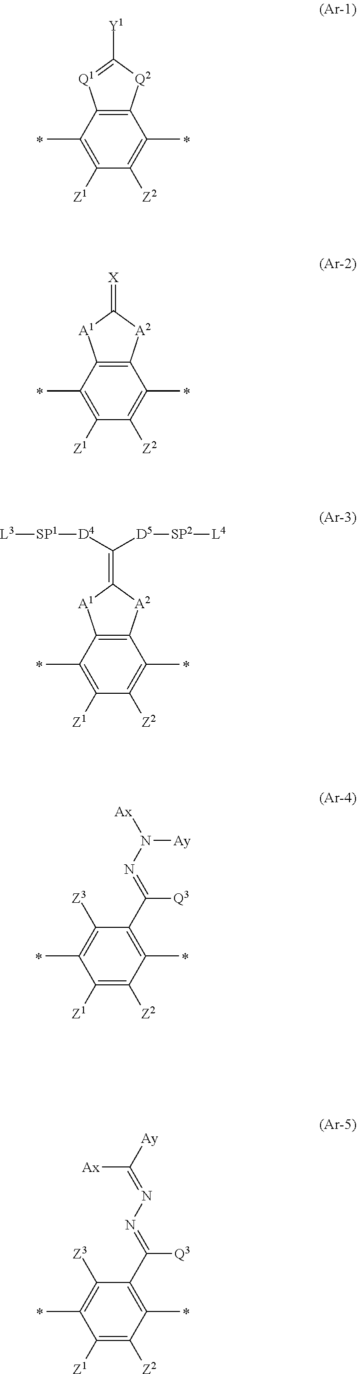 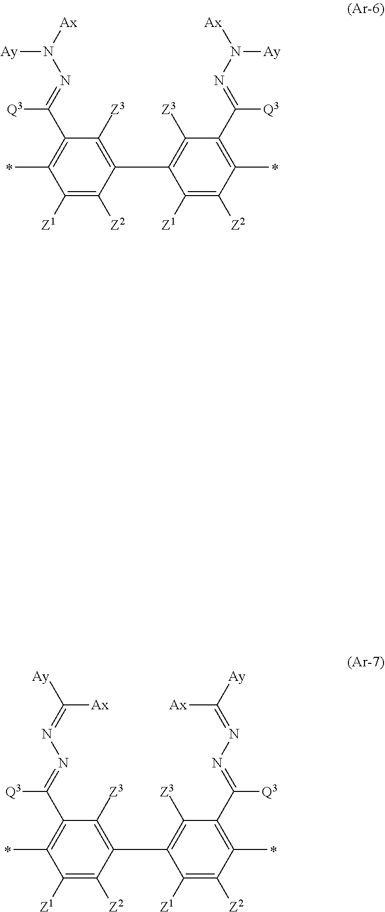
in Formulae (Ar-1) to (Ar-7),
represents a bonding position with D¹ or D²,
Q¹ represents N or CH,
Q² represents —S—, —O—, or —N(R⁷)—, and R⁷ represents a hydrogen atom or an alkyl group having 1 to 6 carbon atoms,
Y¹ represents an aromatic hydrocarbon group having 6 to 12 carbon atoms or an aromatic heterocyclic group having 3 to 12 carbon atoms, which may have a substituent,
Z¹, Z², and Z³ each independently represent a hydrogen atom, a monovalent aliphatic hydrocarbon group having 1 to 20 carbon atoms, a monovalent alicyclic hydrocarbon group having 3 to 20 carbon atoms, a monovalent aromatic hydrocarbon group having 6 to 20 carbon atoms, a halogen atom, a cyano group, a nitro group, —OR⁸, —NR⁹R¹⁰, or —SR¹¹, R⁸ to R¹¹ each independently represent a hydrogen atom or an alkyl group having 1 to 6 carbon atoms, and Z¹ and Z² may be bonded to each other to form an aromatic ring,
A¹ and A² each independently represent a group selected from the group consisting of —O—, —N(R¹²)—, —S—, and —CO—, and R¹² represents a hydrogen atom or a substituent,
X represents a non-metal atom of Groups 14 to 16 to which a hydrogen atom or a substituent may be bonded,
D⁴ and D⁵ each independently represent a single bond or —CO—, —O—, —S—, —C(═S)—, —CR^{1a}R^{2a}—, —CR^{3a}═CR^{4a}—, —NR^{5a}—, or a divalent linking group consisting of two or more combinations of these groups, and R^{1a} to R^{5a} each independently represent a hydrogen atom, a fluorine atom, or an alkyl group having 1 to 4 carbon atoms,
SP¹ and SP² each independently represent a single bond, a linear or branched alkylene group having 1 to 12 carbon atoms, or a divalent linking group in which one or more of —CH₂-constituting a linear or branched alkylene group having 1 to 12 carbon atoms are substituted with —O—, —S—, —NH—, —N(Q)-, or —CO—, and Q represents a substituent,
L³ and L⁴ each independently represent a monovalent organic group,
Ax represents an organic group having 2 to 30 carbon atoms which has at least one aromatic ring selected from the group consisting of an aromatic hydrocarbon ring and an aromatic heterocyclic ring,
Ay represents a hydrogen atom, an alkyl group having 1 to 12 carbon atoms which may have a substituent, or an organic group having 2 to 30 carbon atoms which has at least one aromatic ring selected from the group consisting of an aromatic hydrocarbon ring and an aromatic heterocyclic ring,
the aromatic rings in Ax and Ay may have a substituent, and Ax and Ay may be bonded to each other to form a ring, and
Q³ represents a hydrogen atom or an alkyl group having 1 to 6 carbon atoms which may have a substituent.

20. The organic electroluminescent display device according to claim 2,
wherein Re(450), which is an in-plane retardation value of the optically anisotropic layer measured at a wavelength of 450 nm, Re(550), which is an in-plane retardation value of the optically anisotropic layer measured at a wavelength of 550 nm, and Re(650), which is an in-plane retardation value of the optically anisotropic layer measured at a wavelength of 650 nm, satisfy a relationship of Re(450)≤Re(550)≤Re(650).
